(19) United States
(12) Patent Application Publication
(10) Pub. No.: US 2013/0264562 A1
(43) Pub. Date: Oct. 10, 2013

(54) POLYMER COMPOUND AND ORGANIC EL DEVICE USING SAME

(71) Applicants: Makoto Anryu, Tsukuba-shi (JP); Daisuke Fukushima, Tsukuba-shi (JP)

(72) Inventors: Makoto Anryu, Tsukuba-shi (JP); Daisuke Fukushima, Tsukuba-shi (JP)

(73) Assignee: SUMITOMO CHEMICAL COMPANY, LIMITED, Chuo-ku, Tokyo (JP)

(21) Appl. No.: 13/993,179

(22) PCT Filed: Dec. 21, 2011
(86) PCT No.: PCT/JP2011/079598

§ 371 Date: Jun. 11, 2013

(30) Foreign Application Priority Data
Dec. 21, 2010 (JP) 2010-285059

(51) Int. Cl. H01L 51/00

(52) U.S. Cl. CPC H01L 51/0043
USPC 257/40; 528/8; 528/397

(57) ABSTRACT

A polymer compound having a constitutional sequence represented by the following formula (1) as a main chain:

—[—(Y)ₙ—Z—]ₘ— (1)
in the formula, Y represents a divalent group, in which two hydrogen atoms are removed from a structure represented by the following formula (Y-1) or (Y-2),
Z represents a divalent group, in which two hydrogen atoms are removed from a structure represented by the following formula (Z-1), (Z-2), (Z-3), (Z-4), (Z-5), (Z-6), (Z-7), or (Z-8),
m represents an integer of 4 to 10,000, and n represents an integer of 1 to 3,
plural Y's, Z's, and n's each may be the same as or different from each other.

### TECHNICAL FIELD

The present invention relates to a polymer compound and an organic electroluminescence device using the same.

### BACKGROUND ART

In recent years, an organic electroluminescence display device using an organic electroluminescence device has been attracting attention as a next-generation display device (hereinafter, “organic EL device”). This organic EL device has organic layers such as a light emitting layer and a charge transport layer. The organic EL device may be made of a low molecular weight organic material or a polymeric organic material. The use of the polymeric organic material as a principal material is advantageous when producing a large organic EL display device or the like because a homogenous film can be easily formed when a coating method such as ink jet printing, spin coating or the like is used. As such, the use of the polymeric organic material for an organic EL device is suggested until now (Patent Document 1 and Patent Document 2).

### CITATION LIST

### Patent Literature

Patent Document 1: JP 2008-56090 A
Patent Document 2: WO 99/54385 A

### SUMMARY OF INVENTION

### Technical Problem

However, when a conventional polymeric organic material, particularly a material emitting light in blue, is used to produce an organic EL device, it cannot be said that the organic EL device has an adequate luminous life time.

Thus, it is an object of the present invention to provide an organic EL device having excellent luminous life time, and a surface light source device and a display device using it, and a polymer compound that can be used for an organic layer of the device.

### Solution to Problem

Specifically, the invention provides a polymer compound that has a constitutional sequence represented by the following formula (1) as a main chain

—[—(Y)ₙ—Z—]ₘ— (1)

in the formula, Y represents a divalent group in which two hydrogen atoms are removed from a structure represented by the following formula (Y-1), or (Y-2). Z represents a divalent group in which two hydrogen atoms are removed from a structure represented by the following formula (Z-1), (Z-2), (Z-3), (Z-4), (Z-5), (Z-6), (Z-7), or (Z-8). m represents an integer of 4 to 10,000, and n represents an integer of 1 to 3. Plural Y's, Z's, and n's each may be the same as or different from each other.

A hydrogen atom included in Y and Z may be substituted by R′, and R′ each independently represents a functional group selected from a group consisting of a carboxyl group, a nitro group, a cyano group, an alkyl group, an alkoxy group, an alkylthio group, an aryl group, an aryloxy group, an arylthio group, an alkenyl group, an alkynyl group, an amino group, a silyl group, an acyl group, an acyloxy group, an imine residue, an amide compound residue, an acid imide residue, a monovalent heterocyclic group, and a monovalent heterocyclic thio group, or a halogen atom. When there are plural R′'s, they may be the same as or different from each other, and plural R′'s may be bonded to each other to form a ring structure. The hydrogen atom included in the functional group may be further substituted by a substituent.

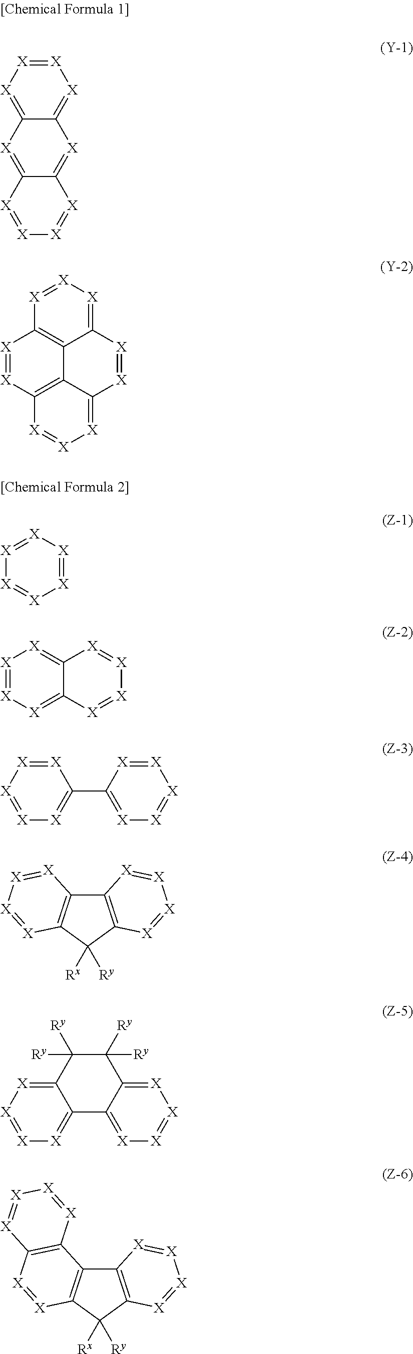

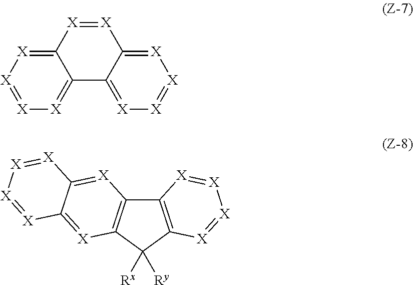

In the formula, X represents —CH═ or —N═. Plural X's may be the same or different from each other, with the proviso that the number of —N═ as X is 0 to 2.

R^{x} is an aryl group, and R^{y} represents a functional group selected from a group consisting of an alkyl group, a carboxyl group, a nitro group, a cyano group, an aryl group, an aryloxy group, an arylthio group, an alkenyl group, an alkynyl group, an amino group, a silyl group, an acyl group, an acyloxy group, an imine residue, an amide compound residue, an acid imide residue, a monovalent heterocyclic group, and a monovalent heterocyclic thio group, or a hydrogen atom or a halogen atom. Plural R^{y}'s may be the same as or different from each other, and may be bonded to each other to form a ring structure. The hydrogen atom included in the functional group may be further substituted by a substituent.

The organic EL device obtained from the polymer compound has an excellent luminous life time.

In the polymer compound, Y is preferably a divalent group represented by the following formula (Y-3), (Y-4), (Y-5), or (Y-6), more preferably a divalent group represented by the following formula (Y-3), (Y-4), or (Y-5), still more preferably a divalent group represented by the following formula (Y-3), or (Y-5), and particularly preferably a divalent group represented by the following formula (Y-3).

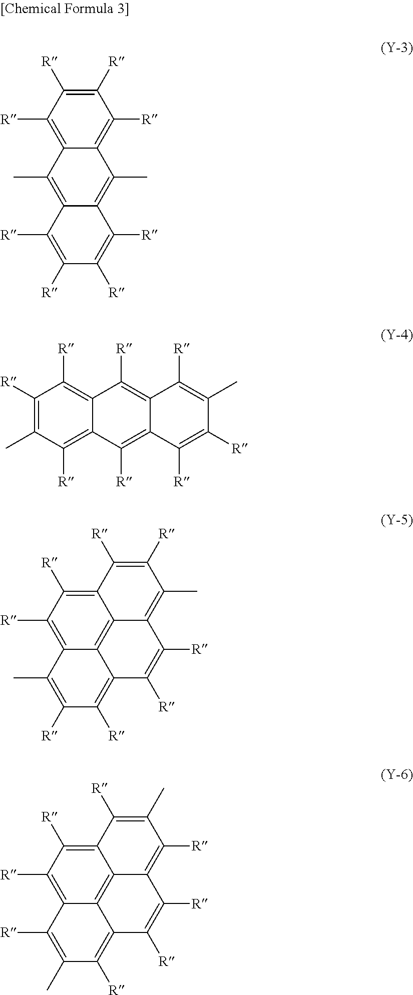

In the formula, R″ represents a hydrogen atom, an alkyl group, an aryl group, or a monovalent heterocyclic group. Plural R″'s may be the same as or different from each other.

In the polymer compound, Z is preferably a divalent group represented by the following formula (Z-9), (Z-10), (Z-11), (Z-12), (Z-13), (Z-14), (Z-15), (Z-16), (Z-17), (Z-18), (Z-19), or (Z-20), more preferably a divalent group represented by the following formula (Z-9), (Z-11), (Z-13), (Z-15), (Z-16), (Z-17), or (Z-19), still more preferably a divalent group represented by the following formula (Z-9), (Z-11), (Z-15), (Z-16), (Z-17), or (Z-19), particularly preferably a divalent group represented by the following formula (Z-11), (Z-15), or (Z-17), more particularly preferably a divalent group represented by the following formula (Z-15).

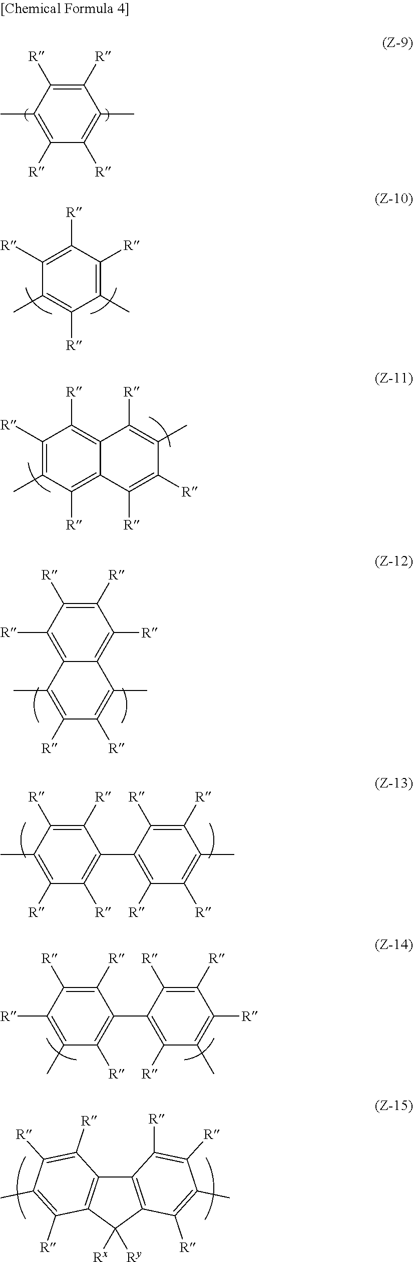

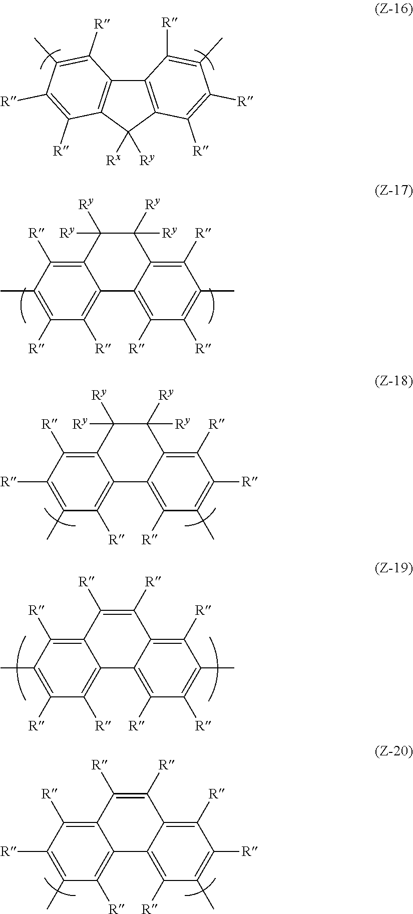

In the formula, R″ represents a hydrogen atom, an alkyl group, an aryl group, or a monovalent heterocyclic group. Plural R″'s may be the same as or different from each other. R^{x} and R^{y} has the same meaning as defined above.

In the polymer compound, the group represented by Y and the group represented by Z are introduced by condensation polymerization and an arbitrary additional group which is different from the group represented by Y and the group represented by Z may be introduced by condensation polymerization, and when mole numbers of Y, Z, and the arbitrary additional group in the polymer compound are N_{Y}, N_{Z} and N_{M}, respectively, it is preferable that N_{Y}, N_{Z} and N_{M} satisfy the following equation (2)

30≦N_{Y}×100/(N_{Y}+N_{Z}+N_{M})≦75 (2)

Also provided by the invention is an organic EL device comprising a pair of electrodes and an organic layer provided between a pair of the electrodes, in which the organic layer contains the polymer compound described above.

Also provided by the invention is a surface light source device and a display device having the organic EL device described above.

### Advantageous Effects of Invention

By using the polymer compound of the invention, luminous life time of an organic EL device to be obtained can be improved. Further, according to the invention, an organic EL device, a surface light source device, and a display device having excellent luminous life time, and a polymer compound which can be used for an organic layer of the device can be provided.

### DESCRIPTION OF EMBODIMENTS

Hereinafter, preferred embodiments of the present invention will be described in detail. In the description below, a tert-butyl group is described as “t-Bu”, and a phenyl group is described as “Ph” in some cases.

### Explanation of Terminology

Hereinafter, terms that are used in common in the present description will be described with reference to specific examples as required.

The term “constitutional unit” indicates an atom or a group of atoms that are present in a molecular chain of the polymer compound.

The term “constitutional sequence” indicates a molecular chain containing one or more types of constitutional units in constant order.

Examples of a halogen atom include a fluorine atom, a chlorine atom, a bromine atom and an iodine atom.

The term “Cₚ˜C_{q}” (p and q are positive integers satisfying p<q) means that the number of carbon atoms of a partial substructure corresponding to a functional group name described just after the term is p to q. That is, the term means that when an organic group described just after “Cₚ˜C_{q}” is an organic group named in combination of plural functional group names (e.g., a Cₚ˜C_{q} alkoxyphenyl group), the number of carbon atoms of a partial substructure corresponding to a functional group name (e.g., alkoxy) described just after “Cₚ˜C_{q}” among the plural functional group names is p to q. For example, a “C₁˜C₁₂ alkyl group” means an alkyl group having 1 to 12 carbon atoms, and a “C₁˜C₁₂ alkoxyphenyl group” means a phenyl group having an “alkoxy group having 1 to 12 carbon atoms”.

An alkyl group may have a substituent, and may be any of a linear alkyl group, a branched alkyl group and a cyclic alkyl group (cycloalkyl group). As the alkyl group, a linear alkyl group and a cyclic alkyl group are preferable, and an unsubstituted alkyl group and an alkyl group substituted by a halogen atom or the like are preferable.

Examples of the substituents include a carboxyl group, a nitro group, a cyano group, an alkyl group, an alkoxy group, an alkylthio group, an aryl group, an aryloxy group, an arylthio group, an alkenyl group, an alkynyl group, an amino group, a silyl group, an acyl group, an acyloxy group, an imine residue, an amide compound residue, an acid imide residue, a monovalent heterocyclic group, a monovalent heterocyclic thio group, and a halogen atom, and some or all of hydrogen atoms included in these groups may be substituted by fluorine atoms. Further, when the substituents have a hydrocarbon chain, the number of carbon atoms in the substituent is preferably 1 to 20 (hereinafter, when a “substituent” is mentioned, these are provided as examples thereof unless otherwise specified).

The number of carbon atoms of the alkyl group is preferably 1 to 20, more preferably 1 to 15, and still more preferably 1 to 12 for a linear alkyl group and a branched alkyl group. For a cyclic alkyl group, it is preferably 3 to 20, more preferably 3 to 15, and still more preferably 3 to 12. Examples of the alkyl group which may have a substituent include a methyl group, an ethyl group, a propyl group, an isopropyl group, a butyl group, an isobutyl group, a sec-butyl group, a tert-butyl group, a pentyl group, an isoamyl group, a hexyl group, a cyclohexyl group, a 2-ethyl hexyl group, a heptyl group, an octyl group, a 3,7-dimethyloctyl group, a nonyl group, a decyl group, a dodecyl group, an aryl alkyl group, a trifluoromethyl group, a pentafluoroethyl group, a perfluorobutyl group, a perfluorohexyl group, and a perfluorooctyl group.

An aryl alkyl group may have a substituent, and is preferably an unsubstituted aryl alkyl group or an aryl alkyl group substituted by a halogen atom, an alkoxy group, or the like. The number of carbon atoms of the aryl alkyl group is preferably 7 to 60, more preferably 7 to 48, and still more preferably 7 to 30. Examples of the aryl alkyl group that may have a substituent include a phenyl˜C₁˜C₁₂ alkyl group, a C₁˜C₁₂ alkoxyphenyl˜C₁˜C₁₂ alkyl group, a C₁˜C₁₂ alkylphenyl˜C₁˜C₁₂ alkyl group, a 1-naphthyl˜C₁˜C₁₂ alkyl group, and a 2-naphthyl˜C₁˜C₁₂ alkyl group.

An alkoxy group may have a substituent, and may be any of a linear alkoxy group, a branched alkoxy group and a cyclic alkoxy group (cycloalkoxy group). As the alkoxy group, a linear alkoxy group or a cyclic alkoxy group are preferable, and an unsubstituted alkoxy group and an alkoxy group substituted by a halogen atom, an alkoxy group, or the like are preferable.

The number of carbon atoms of the alkoxy group is preferably 1 to 20, more preferably 1 to 15, and still more preferably 1 to 12 for a linear alkoxy group and a branched alkoxy group. The number of carbon atoms of the cyclic alkoxy group is preferably 3 to 20, more preferably 3 to 15, and still more preferably 3 to 12. Examples of the alkoxy group which may have a substituent include a methoxy group, an ethoxy group, a propyloxy group, an isopropyloxy group, a butoxy group, an isobutoxy group, a sec-butoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a dodecyloxy group, an aryl alkoxy group, a trifluoromethoxy group, a pentafluoroethoxy group, a perfluorobutoxy group, a perfluorohexyloxy group, a perfluorooctyloxy group, a methoxymethyloxy group, and a 2-methoxyethyloxy group.

An aryl alkoxy group may have a substituent, and is preferably an unsubstituted aryl alkoxy group or an aryl alkoxy group substituted by a halogen atom, an alkoxy group, or the like. The number of carbon atoms of the aryl alkoxy group is preferably 7 to 60, more preferably 7 to 48, and still more preferably 7 to 30. Examples of the aryl alkoxy group that may have a substituent include a phenyl˜C₁˜C₁₂ alkoxy group, a C₁˜C₁₂ alkoxyphenyl˜C₁˜C₁₂ alkoxy group, a C₁˜C₁₂ alkylphenyl˜C₁˜C₁₂ alkoxy group, a 1-naphthyl—C₁˜C₁₂ alkoxy group, and a 2-naphthyl—C₁˜C₁₂ alkoxy group.

An alkylthio group may have a substituent, and may be any of a linear alkylthio group, a branched alkylthio group and a cyclic alkylthio group (cycloalkylthio group). As the alkylthio group, a linear alkylthio group or a cyclic alkylthio group are preferable, and an unsubstituted alkylthio group or an alkylthio group substituted by a halogen atom or the like are preferable.

The number of carbon atoms of the alkylthio group is preferably 1 to 20, more preferably 1 to 15, and still more preferably 1 to 12 for the linear alkylthio group and the branched alkylthio group. The number of carbon atoms of the cyclic alkylthio group is preferably 3 to 20, more preferably 3 to 15, and still more preferably 3 to 12. Examples of the alkylthio group which may have a substituent include a methylthio group, an ethylthio group, a propylthio group, an isopropylthio group, a butylthio group, an isobutylthio group, a sec-butylthio group, a tert-butylthio group, a pentylthio group, a hexylthio group, a cyclohexylthio group, a heptylthio group, an octylthio group, a 2-ethylhexylthio group, a nonylthio group, a decylthio group, an aryl alkylthio group, a 3,7-dimethyloctylthio group, a dodecylthio group, and a trifluoromethylthio group.

An aryl alkylthio group may have a substituent, and is preferably an unsubstituted aryl alkylthio group or an aryl alkylthio group substituted by a halogen atom, an alkoxy group, or the like. The number of carbon atoms of the aryl alkylthio group is preferably 7 to 60, more preferably 7 to 48, and still more preferably 7 to 30. Examples of the aryl alkylthio group that may have a substituent include a phenyl˜C₁˜C₁₂ alkylthio group, a C₁˜C₁₂ alkoxyphenyl˜C₁·C₁₂ alkylthio group, a C₁˜C₁₂ alkylphenyl˜C₁˜C₁₂ alkylthio group, a 1-naphthyl-C₁˜C₁₂ alkylthio group, and a 2-naphthyl-C₁˜C₁₂ alkylthio group.

An aryl group is a group of atoms left after removing one of hydrogen atoms bound to carbon atoms constituting an aromatic ring from an aromatic hydrocarbon, and may have a substituent. As the aryl group, an aryl group consisting of an aromatic ring only, an unsubstituted aryl group or an aryl group substituted by a halogen atom, an alkoxy group, or the like are preferable. Examples of the aryl group include a group having a benzene ring, a group having a fused ring, and a group with two or more of benzene rings and/or fused rings bound via single bond or a divalent organic group (e.g., an alkylene group such as a vinylene group).

The number of carbon atoms of the aryl group is preferably 6 to 60, more preferably 6 to 48, and still more preferably 6 to 30. Examples of the aryl group that may have a substituent include a phenyl group, a C₁˜C₁₂ alkoxyphenyl group, a C₁˜C₁₂ alkylphenyl group, a 1-naphthyl group, a 2-naphthyl group, a 1-anthracenyl group, a 2-anthracenyl group, a 9-anthracenyl group, a 2-fluorenyl group, a pentafluorophenyl group, a biphenylyl group, a C₁˜C₁₂ alkoxybiphenylyl group, and a C₁˜C₁₂ alkylbiphenylyl group. Of those, a phenyl group, a C₁˜C₁₂ alkoxyphenyl group, a C₁˜C₁₂ alkylphenyl group, a biphenylyl group, a C₁˜C₁₂ alkoxybiphenylyl group or a C₁˜C₁₂ alkylbiphenylyl group are preferable.

Examples of the C₁˜C₁₂ alkoxyphenyl group include a methoxyphenyl group, an ethoxyphenyl group, a propyloxyphenyl group, an isopropyloxyphenyl group, a butyloxyphenyl group, an isobutyloxyphenyl group, a tert-butyloxyphenyl group, a pentyloxyphenyl group, a hexyloxyphenyl group, or an octyloxyphenyl group.

Examples of the C₁˜C₁₂ alkylphenyl group include a methylphenyl group, an ethylphenyl group, a dimethylphenyl group, a propylphenyl group, a mesityl group, an isopropylphenyl group, a butylphenyl group, an isobutylphenyl group, a tert-butylphenyl group, a pentylphenyl group, an isoamylphenyl group, a hexylphenyl group, a heptylphenyl group, an octylphenyl group, a nonylphenyl group, a decylphenyl group, and a dodecylphenyl group.

An aryloxy group may have a substituent, and is preferably an unsubstituted aryloxy group or an aryloxy group substituted by a halogen atom, an alkoxy group, or the like.

The number of carbon atoms of the aryloxy group is preferably 6 to 60, more preferably 6 to 48, and still more preferably 6 to 30. Examples of the aryloxy group that may have a substituent include a phenoxy group, a C₁˜C₁₂ alkoxyphenoxy group, a C₁˜C₁₂ alkylphenoxy group, a 1-naphthyloxy group, a 2-naphthyloxy group, and a pentafluorophenyloxy group. A C₁˜C₁₂ alkoxyphenoxy group, or a C₁˜C₁₂ alkylphenoxy group is preferable.

Examples of the C₁˜C₁₂ alkoxyphenoxy group include a methoxyphenoxy group, an ethoxyphenoxy group, a propyloxyphenoxy group, an isopropyloxyphenoxy group, a butyloxyphenoxy group, an isobutyloxyphenoxy group, a tert-butyloxyphenoxy group, a pentyloxyphenoxy group, a hexyloxyphenoxy group, and an octyloxyphenoxy group.

Examples of the C₁˜C₁₂ alkylphenoxy group include a methylphenoxy group, an ethylphenoxy group, a dimethylphenoxy group, a propylphenoxy group, a 1,3,5-trimethylphenoxy group, a methylethylphenoxy group, an isopropylphenoxy group, a butylphenoxy group, an isobutylphenoxy group, a sec-butylphenoxy group, a tert-butylphenoxy group, a pentylphenoxy group, an isoamylphenoxy group, a hexylphenoxy group, a heptylphenoxy group, an octylphenoxy group, a nonylphenoxy group, a decylphenoxy group, and a dodecylphenoxy group.

An arylthio group may have a substituent, and is preferably an unsubstituted arylthio group or an arylthio group substituted by a halogen atom, an alkoxy group, or the like. The number of carbon atoms of the arylthio group is preferably 6 to 60, more preferably 6 to 48, and still more preferably 6 to 30. Examples of the arylthio group that may have a substituent include a phenylthio group, a C₁˜C₁₂ alkoxyphenylthio group, a C₁˜C₁₂ alkylphenylthio group, a 1-naphthylthio group, a 2-naphthylthio group, and a pentafluorophenylthio group.

An alkenyl group may have a substituent, and may be any of a linear alkenyl group, a branched alkenyl group and a cyclic alkenyl group. The number of carbon atoms of the alkenyl group is preferably 2 to 20, more preferably 2 to 15, and still more preferably 2 to 10. Examples of the alkenyl group that may have a substituent include a vinyl group, a 1-propenyl group, a 2-propenyl group, a 1-butenyl group, a 2-butenyl group, a 1-pentenyl group, a 2-pentenyl group, a 1-hexenyl group, a 2-hexenyl group, a 1-octenyl group, and an aryl alkenyl group.

An aryl alkenyl group may have a substituent, and is preferably an unsubstituted aryl alkenyl group or an aryl alkenyl group substituted by a halogen atom, an alkoxy group, or the like. The number of carbon atoms of the aryl alkenyl group is preferably 8 to 60, more preferably 8 to 48, and still more preferably 8 to 30. Examples of the aryl alkenyl group that may have a substituent include a phenyl˜C₂˜C₁₂ alkenyl group, a C₁˜C₁₂ alkoxyphenyl-C₂˜C₁₂ alkenyl group, a C₁˜C₁₂ alkylphenyl-C₂˜C₁₂ alkenyl group, a 1-naphthyl-C₂˜C₁₂ alkenyl group, and a 2-naphthyl-C₂˜C₁₂ alkenyl group. Of those, a C₁˜C₁₂ alkoxyphenyl-C₂˜C₁₂ alkenyl group, or a C₁˜C₁₂ alkylphenyl-C₂˜C₁₂ alkenyl group is preferable.

An alkynyl group may have a substituent, and may be any of a linear alkynyl group, a branched alkynyl group and a cyclic alkynyl group. The number of carbon atoms of the alkynyl group is preferably 2 to 20, more preferably 2 to 15, and still more preferably 2 to 10 for a linear alkynyl group and a branched alkynyl group. For the cyclic alkynyl group, it is preferably 10 to 20, and more preferably 10 to 15. Examples of the alkynyl group include that may have a substituent include an ethynyl group, a 1-propynyl group, a 2-propynyl group, a 1-butynyl group, a 2-butynyl group, a 1-pentynyl group, a 2-pentynyl group, a 1-hexynyl group, a 2-hexynyl group, a 1-octynyl group, and an aryl alkynyl group.

An aryl alkynyl group may have a substituent, and is preferably an unsubstituted aryl alkynyl group or an aryl alkynyl group substituted by a halogen atom, an alkoxy group, or the like. The number of carbon atoms of the aryl alkynyl group is preferably 8 to 60, more preferably 8 to 48, and still more preferably 8 to 30. Examples of the aryl alkynyl group that may have a substituent include a phenyl-C₂˜C₁₂ alkynyl group, a C₁˜C₁₂ alkoxyphenyl-C₂˜C₁₂ alkynyl group, a C₁˜C₁₂ alkylphenyl-C₂˜C₁₂ alkynyl group, a 1-naphthyl-C₂˜C₁₂ alkynyl group, and a 2-naphthyl-C₂˜C₁₂ alkynyl group. Of those, a C₁˜C₁₂ alkoxyphenyl˜C₂˜C₁₂ alkynyl group, or a C₁˜C₁₂ alkylphenyl˜C₂˜C₁₂ alkynyl group is preferable.

A monovalent heterocyclic group is a group of atoms left after removing one of hydrogen atoms bound to an atom constituting a heterocycle from a heterocyclic compound, and may have a substituent. As the monovalent heterocyclic group, an unsubstituted monovalent heterocyclic group or a monovalent aromatic heterocyclic group substituted by a substituent such as an alkyl group or the like are preferable. The number of carbon atoms of the monovalent heterocyclic group is preferably 4 to 60, more preferably 4 to 30, and still more preferably 4 to 20 without including the number of carbon atoms of the substituent. The heterocyclic compound refers to an organic compound having a ring structure and containing not only carbon atoms but also heteroatoms, such as an oxygen atom, a sulfur atom, a nitrogen atom, a phosphorus atom, a boron atom, a silicon atom, a selenium atom, a tellurium atom, and an arsenic atom, as elements constituting the ring. Examples of the monovalent heterocyclic group that may have a substituent include a thienyl group, a C₁˜C₁₂ alkylthienyl group, a pyrrolyl group, a furyl group, a pyridyl group, a C₁˜C₁₂ alkylpyridyl group, a pyridazinyl group, a pyrimidinyl group, a pyrazinyl group, a triazinyl group, a pyrrolidyl group, a piperidyl group, a quinolyl group, and an isoquinolyl group. Of those, a thienyl group, a C₁˜C₁₂ alkylthienyl group, a pyridyl group, or a C₁˜C₁₂ alkylpyridyl group is preferable.

A monovalent heterocyclic thio group is a group with the hydrogen atom of a mercapto group having been substituted by a monovalent heterocyclic group, and may have a substituent. Examples of the monovalent heterocyclic thio group include, for example, a pyridylthio group, a pyridazinylthio group, a pyrimidinylthio group, a pyrazinylthio group, and a triazinylthio group.

An amino group may have a substituent, and is preferably an unsubstituted amino group or an amino group substituted by one or two substituents selected from an alkyl group, an aryl group, and a monovalent heterocyclic group (hereinafter, referred to as a “substituted amino group”). The substituent may further have a substituent (hereinafter, a substituent possessed by a substituent included in a functional group is referred to as a “secondary substituent” in some cases).

The number of carbon atoms of the substituted amino group is preferably 1 to 60, more preferably 2 to 48, and still more preferably 2 to 40 without including the number of carbon atoms of the secondary substituent. Examples of the substituted amino group that may have a secondary substituent include a methyl amino group, a dimethyl amino group, an ethyl amino group, a diethyl amino group, a propyl amino group, a dipropyl amino group, an isopropyl amino group, a diisopropyl amino group, a butyl amino group, an isobutyl amino group, a sec-butyl amino group, a tert-butyl amino group, a pentyl amino group, a hexyl amino group, a heptyl amino group, an octyl amino group, a 2-ethylhexyl amino group, a nonyl amino group, a decyl amino group, a 3,7-dimethyloctyl amino group, a dodecyl amino group, a cyclopentyl amino group, a dicyclopentyl amino group, a cyclohexyl amino group, a dicyclohexyl amino group, a ditrifluoromethyl amino group, a phenyl amino group, a diphenyl amino group, a C₁˜C₁₂ alkoxyphenyl amino group, a bis(C₁˜C₁₂ alkoxyphenyl)amino group, a C₁˜C₁₂ alkylphenyl amino group, a bis(C₁˜C₁₂ alkylphenyl)amino group, a 1-naphthyl amino group, a 2-naphthyl amino group, a pentafluorophenyl amino group, a pyridyl amino group, a pyridazinyl amino group, a pyrimidinyl amino group, a pyrazinyl amino group, a triazinyl amino group, a phenyl-C₁˜C₁₂ alkyl amino group, a C₁˜C₁₂ alkoxyphenyl-C₁˜C₁₂ alkyl amino group, a di(C₁˜C₁₂ alkoxyphenyl-C₁˜C₁₂ alkyl)amino group, a C₁˜C₁₂ alkylphenyl-C₁˜C₁₂ alkyl amino group, a di(C₁˜C₁₂ alkylphenyl-C₁˜C₁₂ alkyl)amino group, a 1-naphthyl-C₁˜C₁₂ alkyl amino group, and a 2-naphthyl-C₁˜C₁₂ alkyl amino group.

A silyl group may have a substituent, and is preferably an unsubstituted silyl group or a silyl group substituted by 1 to 3 substituents selected from an alkyl group, an aryl group, and a monovalent heterocyclic group (hereinafter, referred to as a “substituted silyl group”). The substituent may have a secondary substituent.

The number of carbon atoms of the substituted silyl group is preferably 1 to 60, more preferably 3 to 48, and still more preferably 3 to 40 without including the number of carbon atoms of the secondary substituent. Examples of the substituted silyl group that may have a secondary substituent include a trimethylsilyl group, a triethylsilyl group, a tripropylsilyl group, a tri-isopropylsilyl group, a dimethyl-isopropylsilyl group, a diethyl-isopropylsilyl group, a tert-butyldimethylsilyl group, a pentyldimethylsilyl group, a hexyldimethylsilyl group, a heptyldimethylsilyl group, an octyldimethylsilyl group, a 2-ethylhexyl-dimethylsilyl group, a nonyldimethylsilyl group, a decyldimethylsilyl group, a 3,7-dimethyloctyl-dimethylsilyl group, a dodecyldimethylsilyl group, a phenyl˜C₁˜C₁₂ alkylsilyl group, a C₁˜C₁₂ alkoxyphenyl˜C₁˜C₁₂ alkylsilyl group, a C₁˜C₁₂ alkylphenyl-C₁˜C₁₂ alkylsilyl group, a 1-naphthyl-C₁˜C₁₂ alkylsilyl group, a 2-naphthyl˜C₁˜C₁₂ alkylsilyl group, a phenyl-C₁˜C₁₂ alkyldimethylsilyl group, a triphenylsilyl group, a tri-p-xylylsilyl group, a tribenzylsilyl group, a diphenylmethylsilyl group, a tert-butyldiphenylsilyl group, and a dimethylphenylsilyl group.

An acyl group may have a substituent, and is preferably an unsubstituted acyl group or an acyl group substituted by a halogen atom or the like. The number of carbon atoms of the acyl group is preferably 2 to 20, more preferably 2 to 18, and still more preferably 2 to 16. Examples of the acyl group include an acetyl group, a propionyl group, a butylyl group, an isobutylyl group, a pivaloyl group, a benzoyl group, a trifluoroacetyl group, and a pentafluorobenzoyl group.

An acyloxy group may have a substituent, and is preferably an unsubstituted acyloxy group or an acyloxy group substituted by a halogen atom or the like. The number of carbon atoms of the acyloxy group is preferably 2 to 20, more preferably 2 to 18, and still more preferably 2 to 16. Examples of the acyloxy group include an acetoxy group, a propionyloxy group, a butylyloxy group, an isobutylyloxy group, a pivaloyloxy group, a benzoyloxy group, a trifluoroacetyloxy group, and a pentafluorobenzoyloxy group.

An imine residue means a residue left after removing, from an imine compound having a structure represented by at least one of the formula: H—CR^{X1}═N—R^{Y1} or the formula: H—N═C(R^{Y1})₂, one of the hydrogen atoms in the formula. In the formula, R^{X1} represents a hydrogen atom, an alkyl group, an aryl group, an aryl alkenyl group, or an aryl alkynyl group, and R^{Y1} represents a hydrogen atom, an alkyl group, an aryl group, an aryl alkenyl group, or an aryl alkynyl group. When two R^{Y1} are present, they may be same or different, and two R^{Y1} may be bound together and integrated to form a ring as a divalent group, for example, an alkylene group having 2 to 18 carbon atoms, such as an ethylene group, a trimethylene group, a tetramethylene group, a pentamethylene group, a hexamethylene group, or the like. Examples of the imine compound include compounds in which a hydrogen atom bound to aldimine, ketimine or a nitrogen atom in aldimine has been substituted by an alkyl group, an aryl group, an aryl alkenyl group, an aryl alkynyl group, and the like. The number of carbon atoms of the imine residue is preferably 2 to 20, more preferably 2 to 18, and still more preferably 2 to 16. Specific examples of the imine residue include groups represented by the following structural formula.

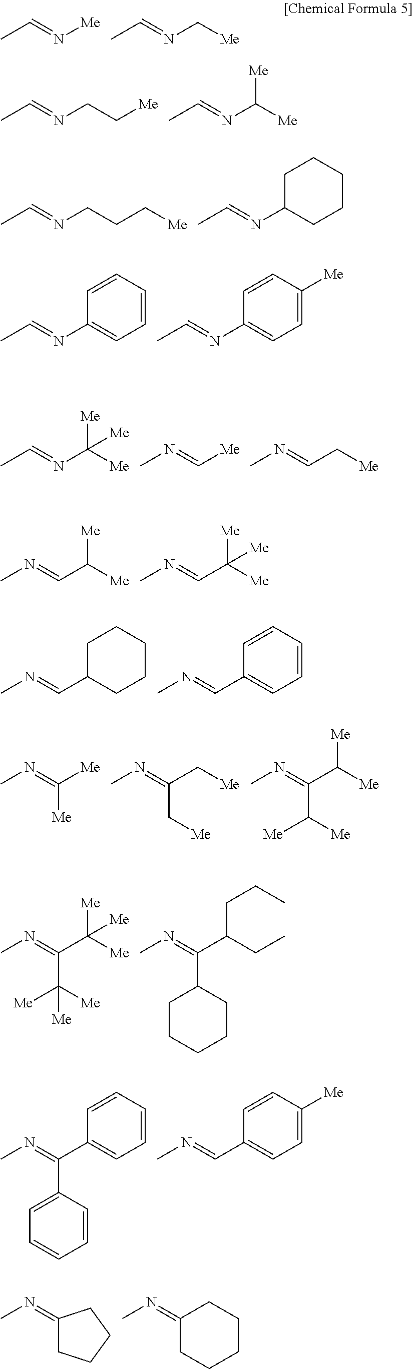

An amide compound residue means a residue left after removing, from an amide compound having a structure represented by at least one of the formula: H—NR^{X2}—COR^{Y2} or the formula: H—CO—N(R^{Y2})₂, one of the hydrogen atoms in the formula. In the formula, R^{X2} and R^{Y2} each independently represent a hydrogen atom, an alkyl group that may have a substituent, an aryl group that may have a substituent. The number of carbon atoms of the amide compound residue is preferably 2 to 20, more preferably 2 to 18, and still more preferably 2 to 16. Examples of the amide compound residue include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group, and a dipentafluorobenzamide group.

An acid imide residue means a residue left after removing, from an acid imide having a structure represented by the formula: R^{X3}—CO—NH—CO—R^{Y3}, one of the hydrogen atoms in the formula. In the formula, R^{X3} and R^{Y3} each independently represent an alkyl group that may have a substituent, an aryl group that may have a substituent, or a ring structure which is formed by binding of R^{X3} and R^{Y3} to each other. The number of carbon atoms of the acid imide residue is preferably 4 to 20, more preferably 4 to 18, and still more preferably 4 to 16. Specific examples of the acid imide residue include the following groups.

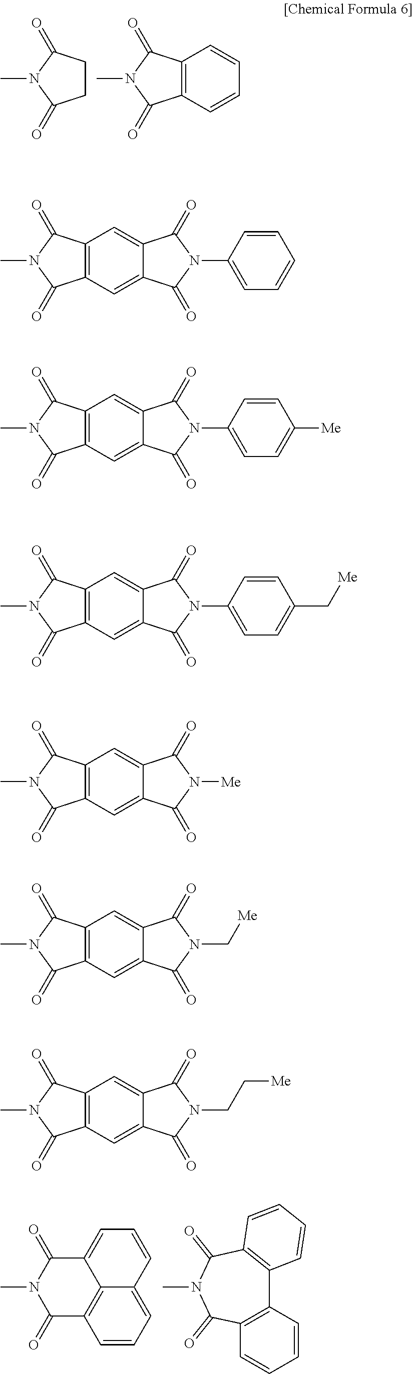

An arylene group means a group of atoms constituted by removing 2 hydrogen atoms bound to the aromatic ring-constituting carbon atoms from an aromatic hydrocarbon, and include those having an independent benzene ring or fused ring, and may have a substituent. Without including the number of carbon atoms of a substituent, the number of carbon atoms of the arylene group is preferably 6 to 60, more preferably 6 to 48, still more preferably 6 to 30, and particularly preferably 6 to 18. The number of carbon atoms does not include the number of carbon atoms of a substituent. Examples of the arylene group include phenylene groups, such as a 1,4-phenylene group, a 1,3-phenylene group, and a 1,2-phenylene group; naphthalenediyl groups, such as a 1,4-naphthalenediyl group, a 1,5-naphthalenediyl group, and a 2,6-naphthalenediyl group; anthracenediyl groups, such as a 1,4-anthracenediyl group, a 1,5-anthracenediyl group, a 2,6-anthracenediyl group, and a 9,10-anthracenediyl group; phenanthrenediyl groups, such as a 2,7-phenanthrenediyl group; naphthacenediyl groups, such as a 1,7-naphthacenediyl group, a 2,8-naphthacenediyl group, and a 5,12-naphthacenediyl group; fluorenediyl groups, such as a 2,7-fluorenediyl group, and a 3,6-fluorenediyl group; pyrenediyl groups, such as a 1,6-pyrenediyl group, a 1,8-pyrenediyl group, a 2,7-pyrenediyl group, and a 4,9-pyrenediyl group; perylenediyl groups, such as a 3,9-perylenediyl group, a 3,10-perylenediyl group. Among them, preferable are a phenylene group that may have a substituent and a fluorenediyl group that may have a substituent.

A divalent heterocyclic group refers to a group of atoms left after removing two of hydrogen atoms which binds to the carbon atom or hetero atom constituting the heterocycle from a heterocyclic compound, and may have a substituent. As the divalent heterocyclic group, an unsubstituted divalent heterocyclic group or a divalent heterocyclic group substituted by an alkyl group or the like are preferable.

The number of carbon atoms of the divalent heterocyclic group is preferably 4 to 60, more preferably 4 to 30, and still more preferably 4 to 12 without including the number of carbon atoms of the substituent. Examples of the divalent heterocyclic group include pyridinediyl groups, such as a 2,5-pyridinediyl group, and a 2,6-pyridinediyl group; thiophenediyl groups, such as a 2,5-thiophenediyl group; furandiyl groups, such as a 2,5-furandiyl group; quinolinediyl groups, such as a 2,6-quinolinediyl group; isoquinolinediyl groups, such as a 1,4-isoquinolinediyl group, a 1,5-isoquinolinediyl group; quinoxalinediyl groups, such as a 5,8-quinoxalinediyl group; 2,1,3-benzothiadiazole groups, such as a 2,1,3-benzothiadiazole-4,7-diyl group; benzothiazolediyl groups, such as a 4,7-benzothiazolediyl group; carbazolediyl groups, such as a 2,7-carbazolediyl group, a 3,6-carbazolediyl group; phenoxazinediyl groups, such as a 3,7-phenoxazinediyl group; phenothiazinediyl groups, such as a 3,7-phenothiazinediyl group; dibenzosilolediyl groups, such as a 2,7-dibenzosilolediyl group. Among them, preferable are a 2,1,3-benzothiadiazole-4,7-diyl group that may have a substituent, a phenoxazinediyl group that may have a substituent, a phenothiazinediyl group that may have a substituent. As the divalent heterocyclic group, a divalent group of an aromatic heterocycle is preferable.

<Polymer Compound>

The polymer compound includes a constitutional sequence represented by the above formula (1) as a main chain.

In the constitutional sequence represented by the formula (1), for a case in which n≧2 and plural Y's are a divalent group in which two hydrogen atoms are removed from a structure represented by the formula (Y-1), plural the structures represented by the formula (Y-1) may be the same as or different from each other, preferably the same.

In the constitutional sequence represented by the formula (1), for a case in which n≧2 and plural Y's are a divalent group in which two hydrogen atoms are removed from a structure represented by the formula (Y-1), the plural structures represented by the formula (Y-1) may consist of only a structure in which all X are —CH═, may consist of both a structure in which all X are —CH═ and a structure in which one or two of X are —N═ and remaining X are —CH═, or may consist of only a structure in which one or two of X are —N═ and remaining X are —CH═, and preferably consists of only a structure in which all X are —CH═.

Further, when the hydrogen atom contained in Y and Z is substituted by R′, R′ is preferably a functional group selected from a group consisting of an alkyl group, an alkoxy group, an aryl group, an amino group, and a monovalent heterocyclic group, or a halogen atom. More preferably, R′ is a functional group selected from a group consisting of an alkyl group, an aryl group, and a monovalent heterocyclic group, or a halogen atom, still more preferably an alkyl group or an aryl group, particularly preferably an alkyl group. Further, when there are plural R's, they may be the same as or different from each other, and plural R′'s may bind to each other to form a ring structure. When R′ forms a ring structure, it is preferably a ring structure having no unsaturated bond. Examples of R′ which can form such structure include an alkyl group, an alkoxy group, an alkylthio group, an amino group, and a silyl group.

In the constitutional sequence represented by the formula (1), for a case in which n≧2 and plural Y's are a divalent group in which two hydrogen atoms are removed from a structure represented by the formula (Y-2), the plural structures represented by the formula (Y-2) may be the same as or different from each other, preferably the same.

In the constitutional sequence represented by the formula (1), for a case in which n≧2 and plural Y's are a divalent group in which two hydrogen atoms are removed from a structure represented by the formula (Y-2), the plural structures represented by the formula (Y-2) may consist of only a structure in which all X are —CH═, may consist of both a structure in which all X are —CH═ and a structure in which one or two of X are —N═ and remaining X are —CH═, or may consist of only a structure in which one or two of X are —N═ and remaining X are —CH═, preferably consists only of a structure in which all X are —CH═.

For a case in which the hydrogen atom contained in Y and Z is substituted by R′, a preferred scope of R′ is the same as those described above.

With regard to the constitutional sequence represented by the formula (1), each of the structure represented by [—(Y)ₙ—Z-], that is present in the number of m, may be the same as or different from each other. For example, for a case in which m=4, and n=1, 2, 1, 2 in an order starting from the left structure, the constitutional sequence is represented by [—Y⁰¹—Z⁰¹—]—[—Y⁰²—Y⁰³—Z⁰²—]—[—Y⁰⁴—Z⁰³—]—[—Y⁰⁵—Y⁰⁶—Z⁰⁴—]. In this regard, Y⁰¹, Y⁰², Y⁰³, Y⁰⁴, Y⁰⁵ and Y⁰⁶ may be the same as or different from each other and Z⁰¹, Z⁰², Z⁰³ and Z⁰⁴ may be the same as or different from each other. It is similar even when m and n have a combination of other integers.

Since the polymer compound has the constitutional sequence represented by the formula (1), luminous life time can be improved when it is used as a light emitting layer of an organic EL device.

In the formula (1), R^{y} is preferably an alkyl group, an alkoxy group, an aryl group, an aryloxy group, an arylthio group, or a monovalent heterocyclic group, more preferably an alkyl group or an aryl group, still more preferably an alkyl group.

In the formula (1), m represents an integer of 4 to 10000. m is preferably an integer of 8 to 10000, more preferably an integer of 30 to 10000, still more preferably an integer of 50 to 5000. In the formula (1), plural n's represent an integer of 1 to 3, preferably represents the same integer. More preferably, plural n's are all 1 or all 2.

In the formula (1), plural Y are the same as or different from each other, and preferably a divalent group represented by the formula (Y-3), (Y-4), (Y-5), or (Y-6).

In the formula (Y-3), (Y-4), (Y-5) and (Y-6), R″ is preferably a hydrogen atom, an alkyl group, or an aryl group, more preferably a hydrogen atom or an alkyl group, particularly preferably a hydrogen atom.

Preferred examples of the structure of Y in the formula (1) include the following groups.

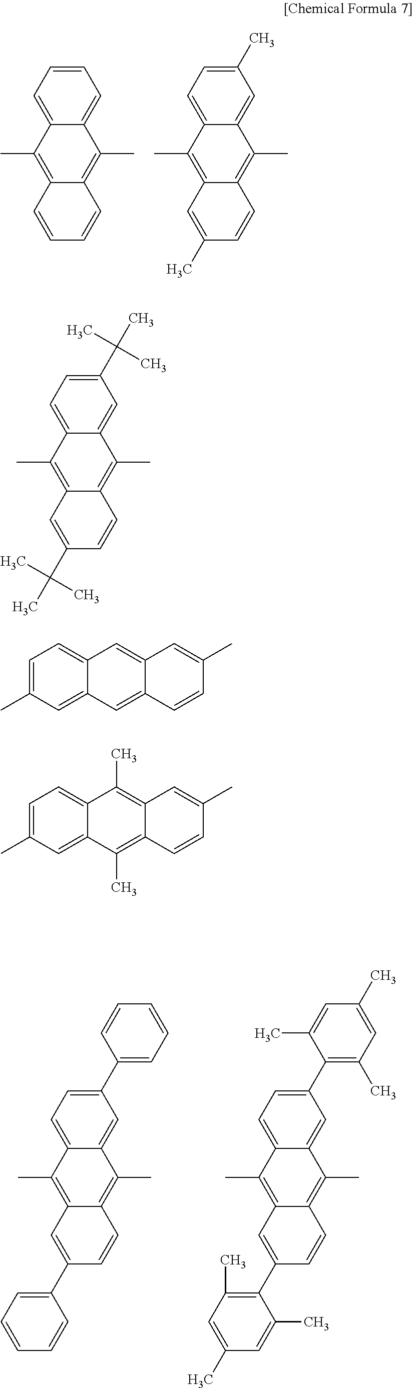

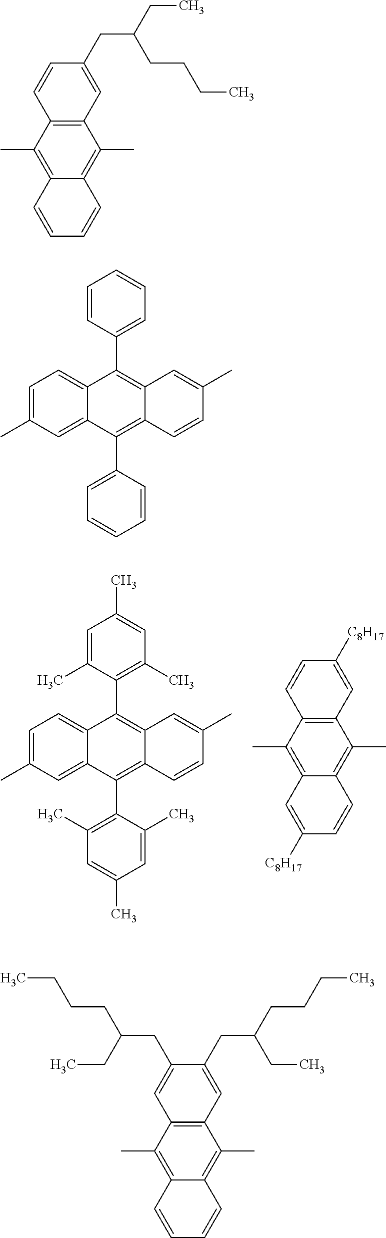

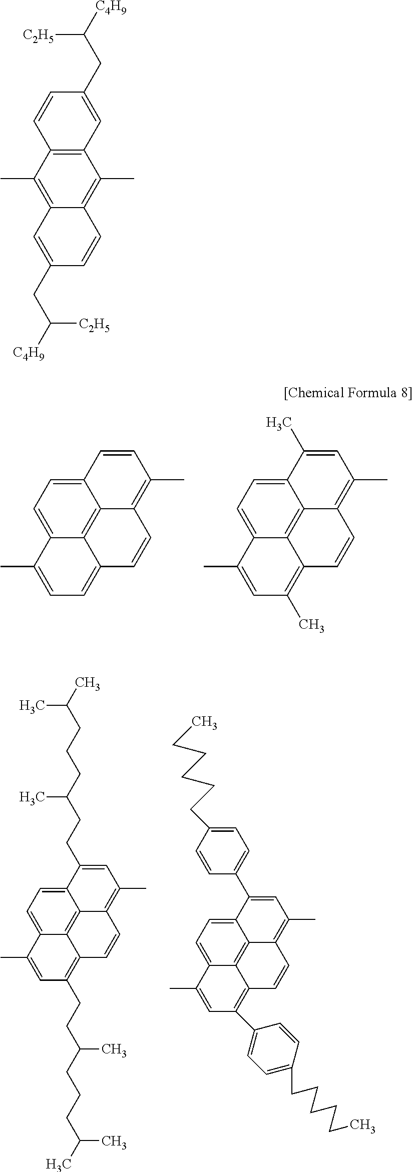

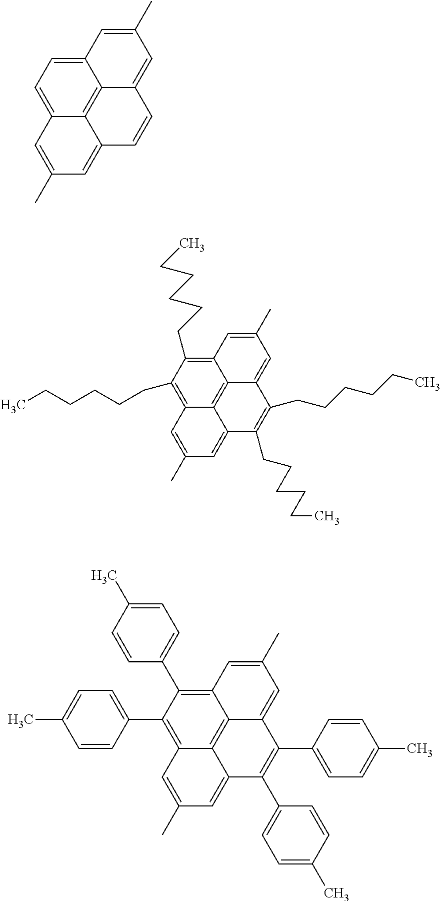

In the constitutional sequence represented by the formula (1), Z represents a divalent group in which two hydrogen atoms are removed from a structure represented by the formula (Z-1), (Z-2), (Z-3), (Z-4), (Z-5), (Z-6), (Z-7), or (Z-8). Plural Z's may consist of any one group of the divalent group in which two hydrogen atoms are removed from a structure represented by the formula (Z-1), (Z-2), (Z-3), (Z-4), (Z-5), (Z-6), (Z-7) and (Z-8) only, or may consist of the plural groups, preferably, and they may consist of only any one group only.

In the constitutional sequence represented by the formula (1), for a case in which two or more among plural Z's are any one of a divalent group in which two hydrogen atoms are removed from a structure represented by the formula (Z-1), (Z-2), (Z-3), (Z-4), (Z-5), (Z-6), (Z-7) and (Z-8), the structures represented by the formula (Z-1), (Z-2), (Z-3), (Z-4), (Z-5), (Z-6), (Z-7) and (Z-8) may be the same as or different from each other, preferably the same as. For a case in which plural among Z are any one of a divalent group in which two hydrogen atoms are removed from a structure represented by the formula (Z-1), (Z-2), (Z-3), (Z-4), (Z-5), (Z-6), (Z-7) and (Z-8), the plural structures represented by the formula (Z-1), (Z-2), (Z-3), (Z-4), (Z-5), (Z-6), (Z-7) and (Z-8) may consist of only a structure in which all X are —CH═, may consist of both a structure in which all X are —CH═ and a structure in which one or two of X are —N═ and remaining Xs are —CH═, or may consist of only a structure in which one or two of X are —N═ and remaining X are —CH═, preferably consists only of a structure in which all X are —CH═.

Z in the formula (1) is preferably a divalent group represented by the formula (Z-9), (Z-10), (Z-11), (Z-12), (Z-13), (Z-14), (Z-15), (Z-16), (Z-17), (Z-18), (Z-19), or (Z-20). Plural Z's may be the same as or different from each other.

Of those, Z is preferably a divalent group represented by the formula (Z-9), (Z-11), (Z-13), (Z-15), (Z-16), (Z-17), or (Z-19), more preferably a divalent group represented by the formula (Z-9), (Z-11), (Z-15), (Z-16), (Z-17), or (Z-19), still more preferably a divalent group represented by the formula (Z-11) or (Z-15) or (Z-17), particularly preferably a divalent group represented by the formula (Z-15).

Examples of the preferred structure of Z in the formula (1) include the following structures.

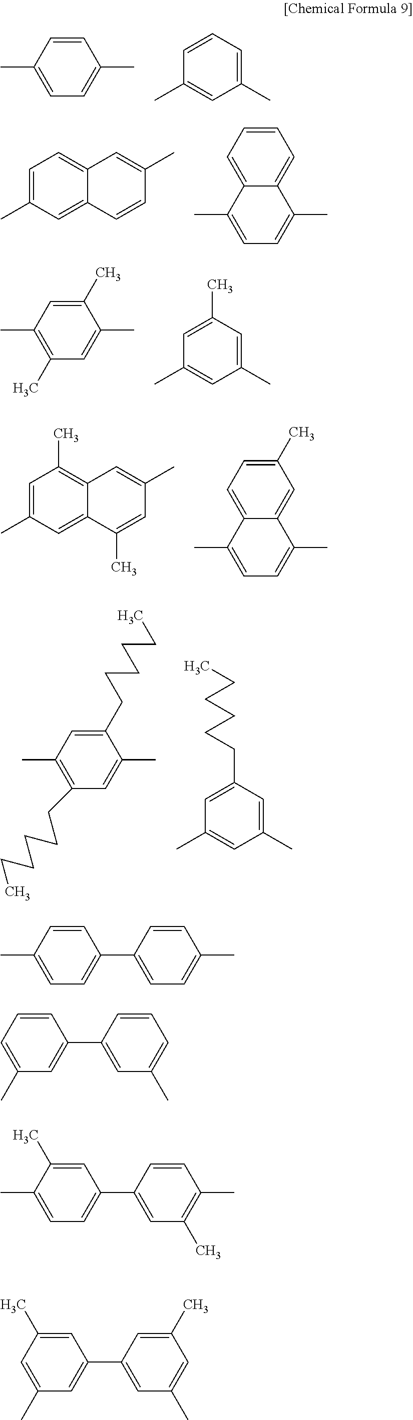

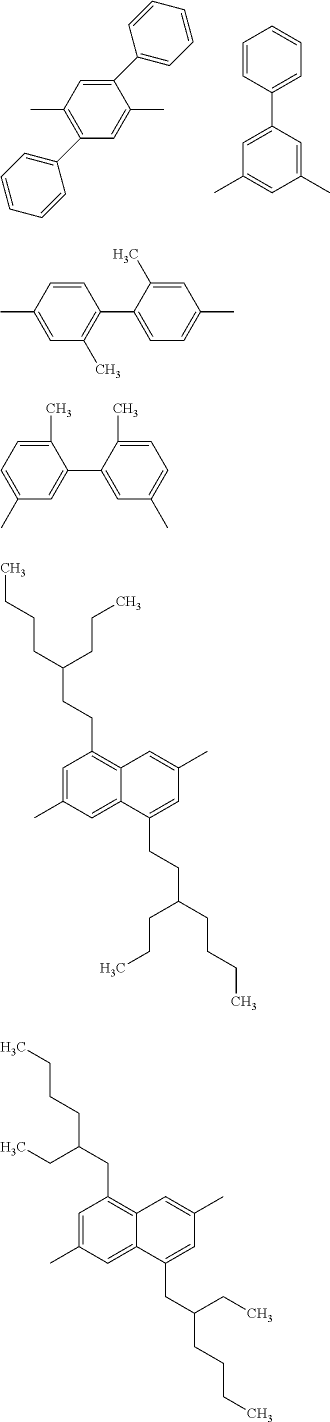

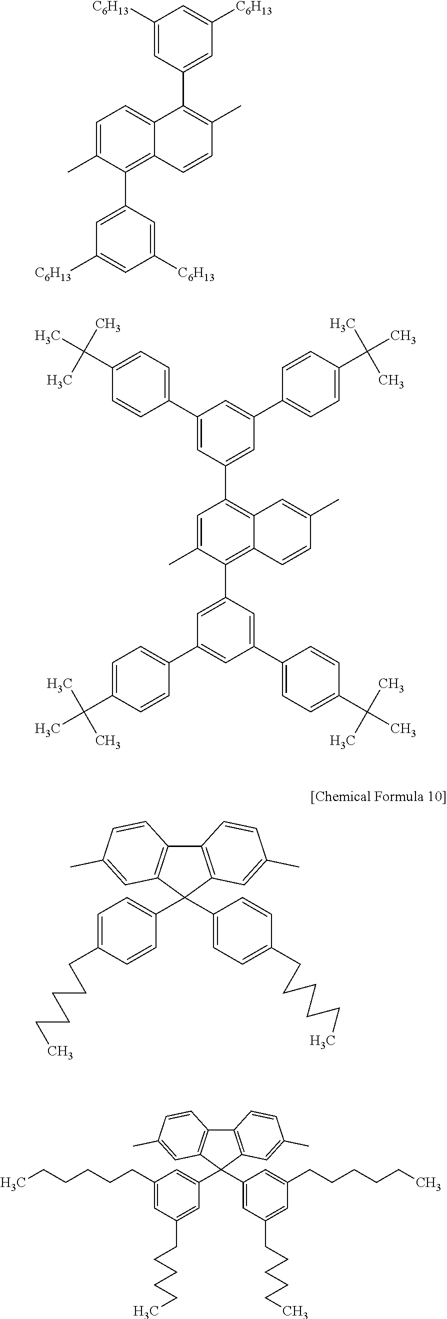

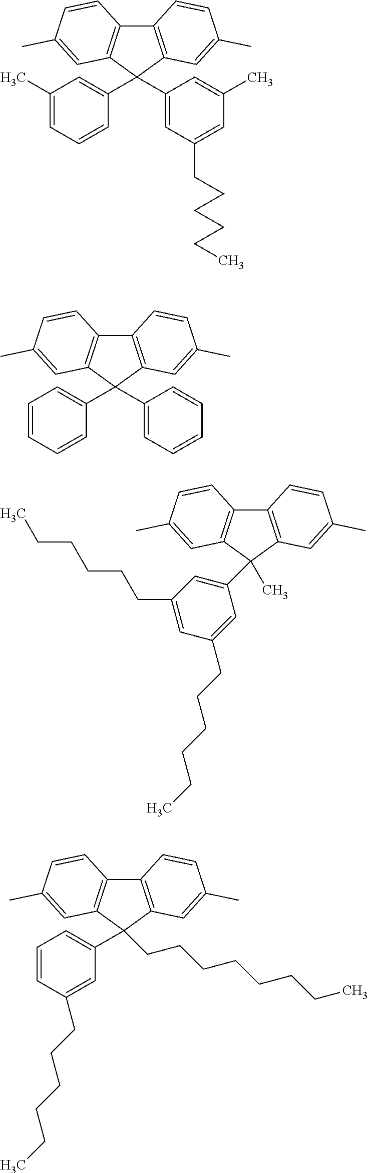

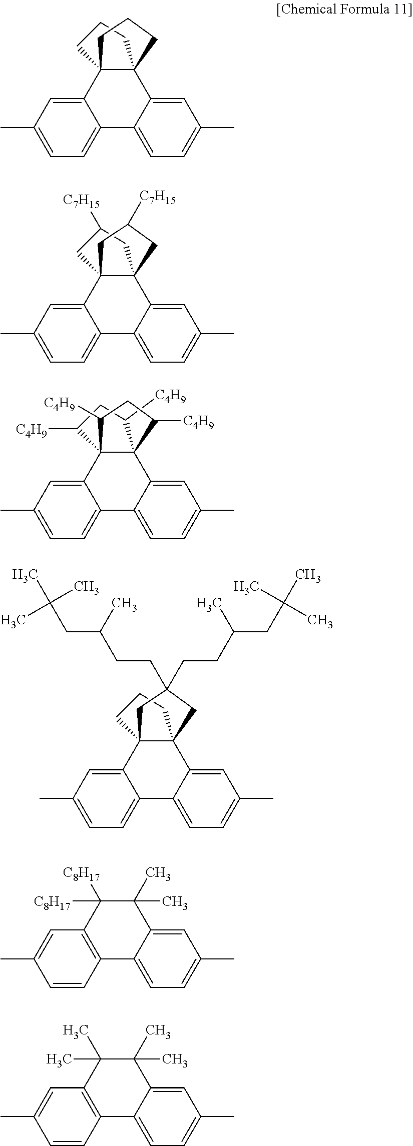

Examples of a combination of Y and Z in the formula (1) include a combination of a divalent group represented by the formula (Y-3) and a divalent group represented by the formula (Z-9) (hereinafter, simply referred to as “(Y-3) and (Z-9)”), (Y-3) and (Z-11), (Y-3) and (Z-13), (Y-3) and (Z-15), (Y-3) and (Z-16), (Y-3) and (Z-17), (Y-3) and (Z-19), (Y-4) and (Z-9), (Y-4) and (Z-11), (Y-4) and (Z-13), (Y-4) and (Z-15), (Y-4) and (Z-16), (Y-4) and (Z-17), (Y-4) and (Z-19), (Y-5) and (Z-9), (Y-5) and (Z-11), (Y-5) and (Z-13), (Y-5) and (Z-15), (Y-5) and (Z-16), (Y-5) and (Z-17), (Y-5) and (Z-19), (Y-6) and (Z-9), (Y-6) and (Z-11), (Y-6) and (Z-13), (Y-6) and (Z-15), (Y-6) and (Z-16), (Y-6) and (Z-17), or (Y-6) and (Z-19), it is preferably (Y-3) and (Z-9), (Y-3) and (Z-11), (Y-3) and (Z-13), (Y-3) and (Z-15), (Y-3) and (Z-16), (Y-3) and (Z-17), (Y-3) and (Z-19), (Y-4) and (Z-9), (Y-4) and (Z-11), (Y-4) and (Z-13), (Y-4) and (Z-15), (Y-4) and (Z-16), (Y-4) and (Z-17), (Y-4) and (Z-19), (Y-5) and (Z-9), (Y-5) and (Z-11), (Y-5) and (Z-13), (Y-5) and (Z-15), (Y-5) and (Z-16), (Y-5) and (Z-17), or (Y-5) and (Z-19), it is more preferably (Y-3) and (Z-9), (Y-3) and (Z-11), (Y-3) and (Z-15), (Y-3) and (Z-16), (Y-3) and (Z-17), (Y-3) and (Z-19), (Y-4) and (Z-9), (Y-4) and (Z-11), (Y-4) and (Z-15), (Y-4) and (Z-16), (Y-4) and (Z-17), (Y-4) and (Z-19), (Y-5) and (Z-9), (Y-5) and (Z-11), (Y-5) and (Z-15), (Y-5) and (Z-16), (Y-5) and (Z-17), or (Y-5) and (Z-19), it is still more preferably (Y-3) and (Z-11), (Y-3) and (Z-15), (Y-3) and (Z-16), (Y-3) and (Z-17), (Y-4) and (Z-11), (Y-4) and (Z-15), (Y-4) and (Z-16), (Y-4) and (Z-17), (Y-5) and (Z-11), (Y-5) and (Z-15), (Y-5) and (Z-16), or (Y-5) and (Z-17). It is particularly preferably (Y-3) and (Z-11), (Y-3) and (Z-15), (Y-3) and (Z-17), (Y-4) and (Z-11), (Y-4) and (Z-15), (Y-4) and (Z-17), (Y-5) and (Z-11), (Y-5) and (Z-15), or (Y-5) and (Z-17).

Preferred Examples of the structure represented by [—(Y)ₙ—Z—] in the constitutional sequence represented by the formula (1) include the followings.

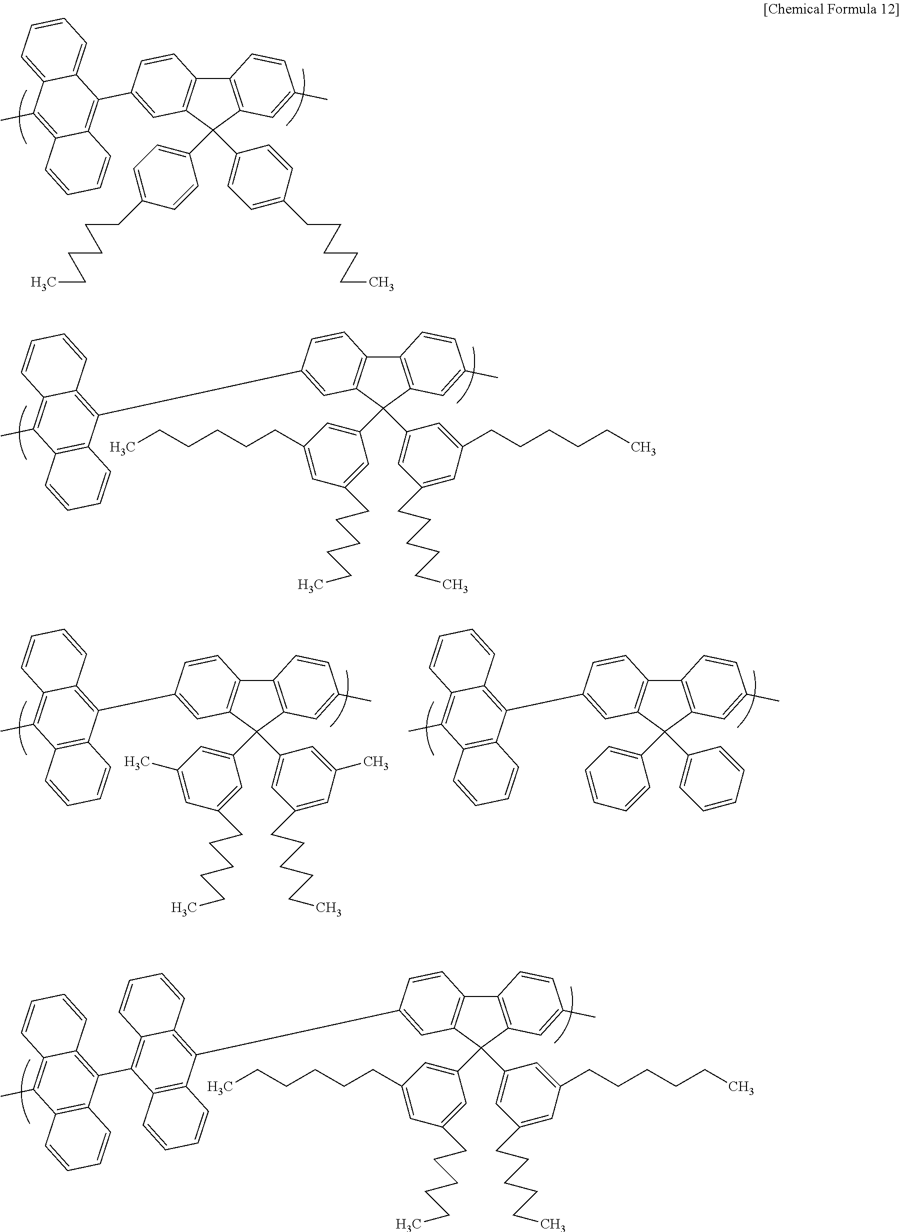

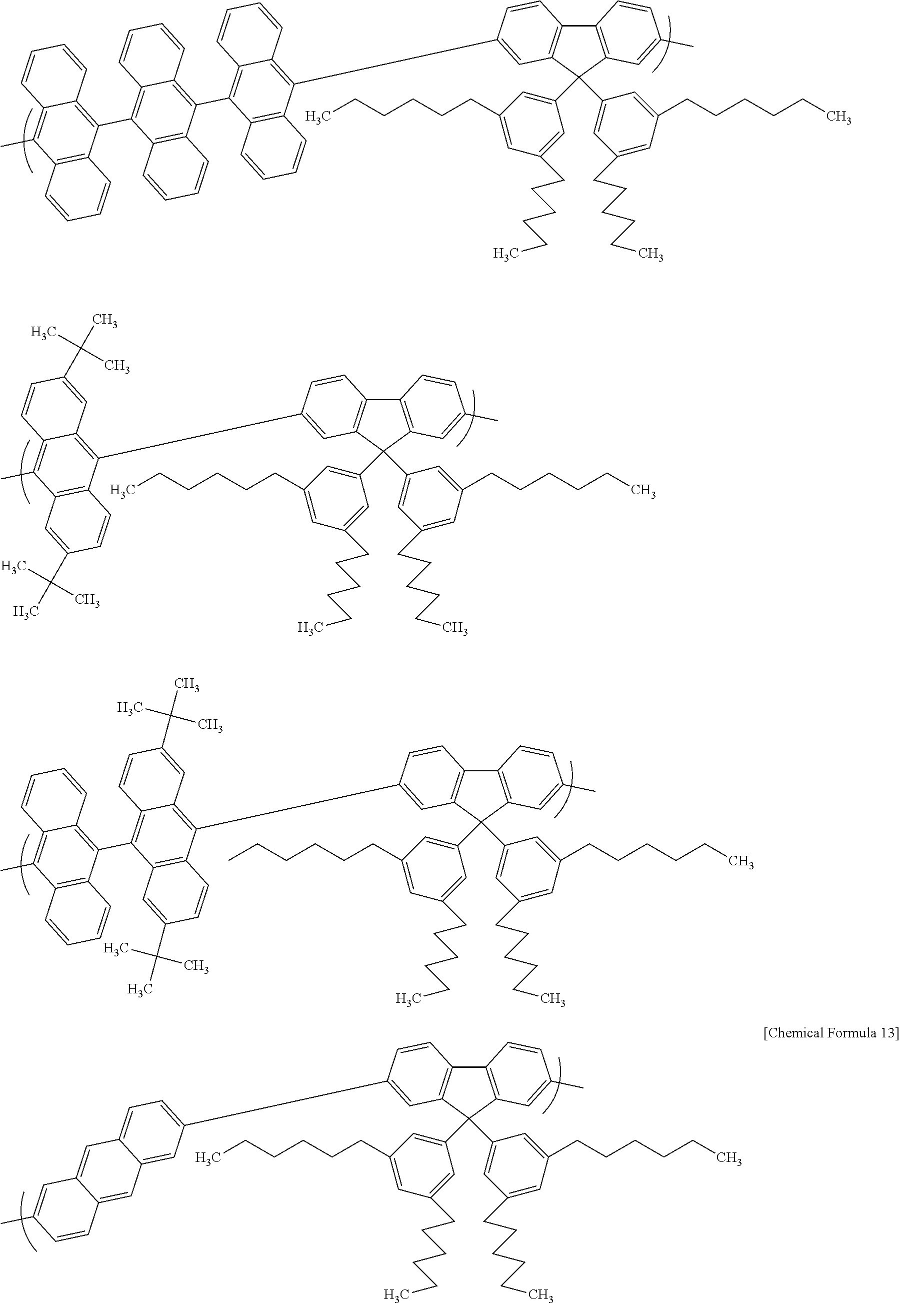

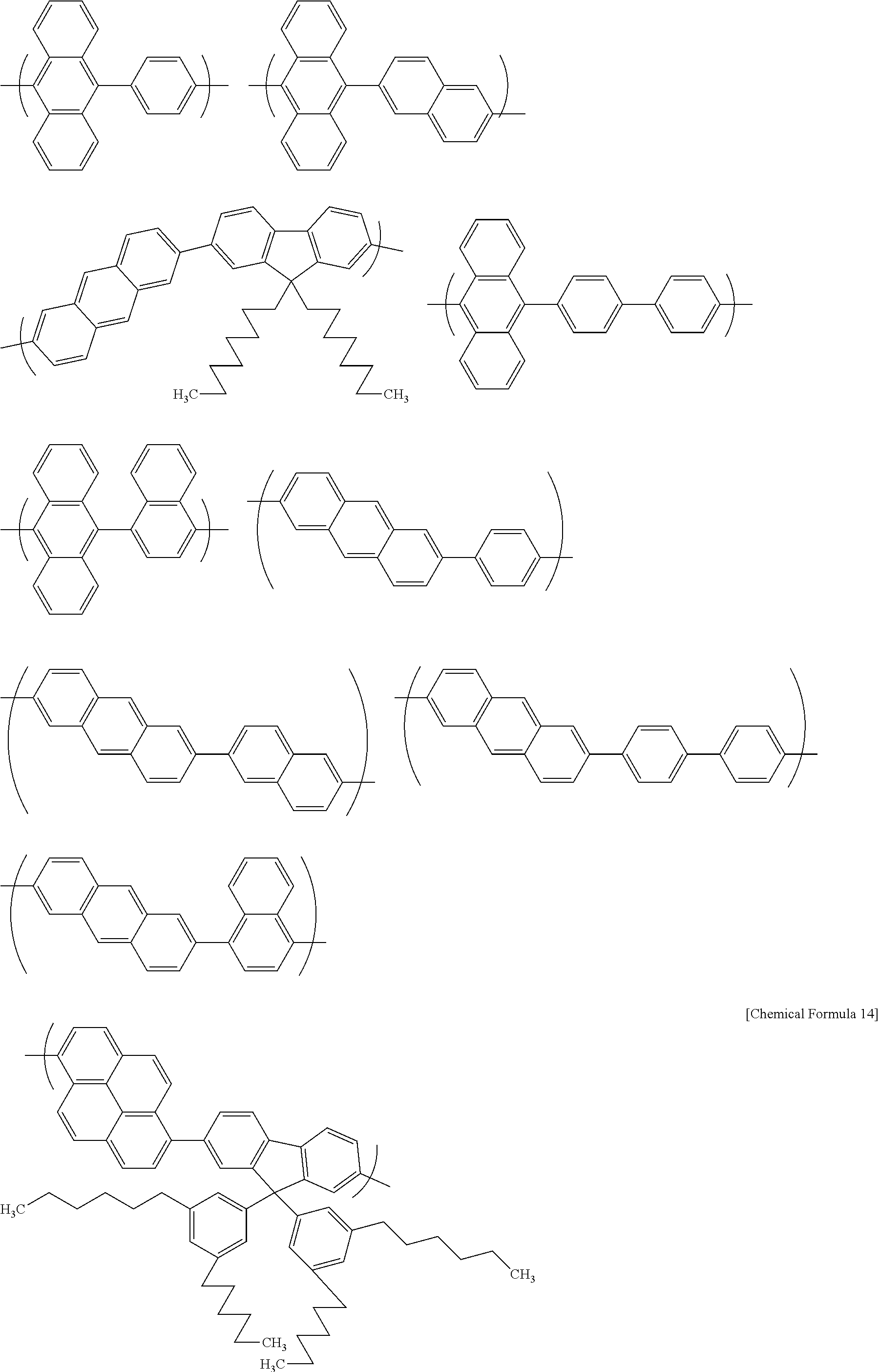

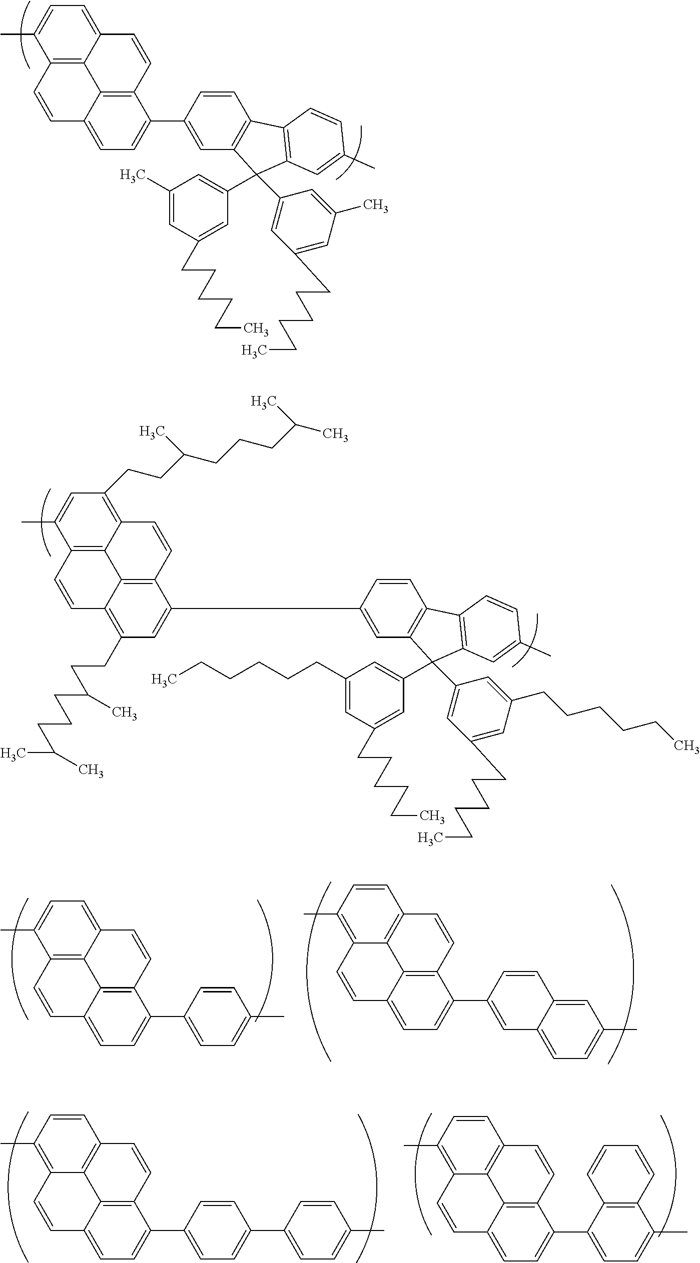

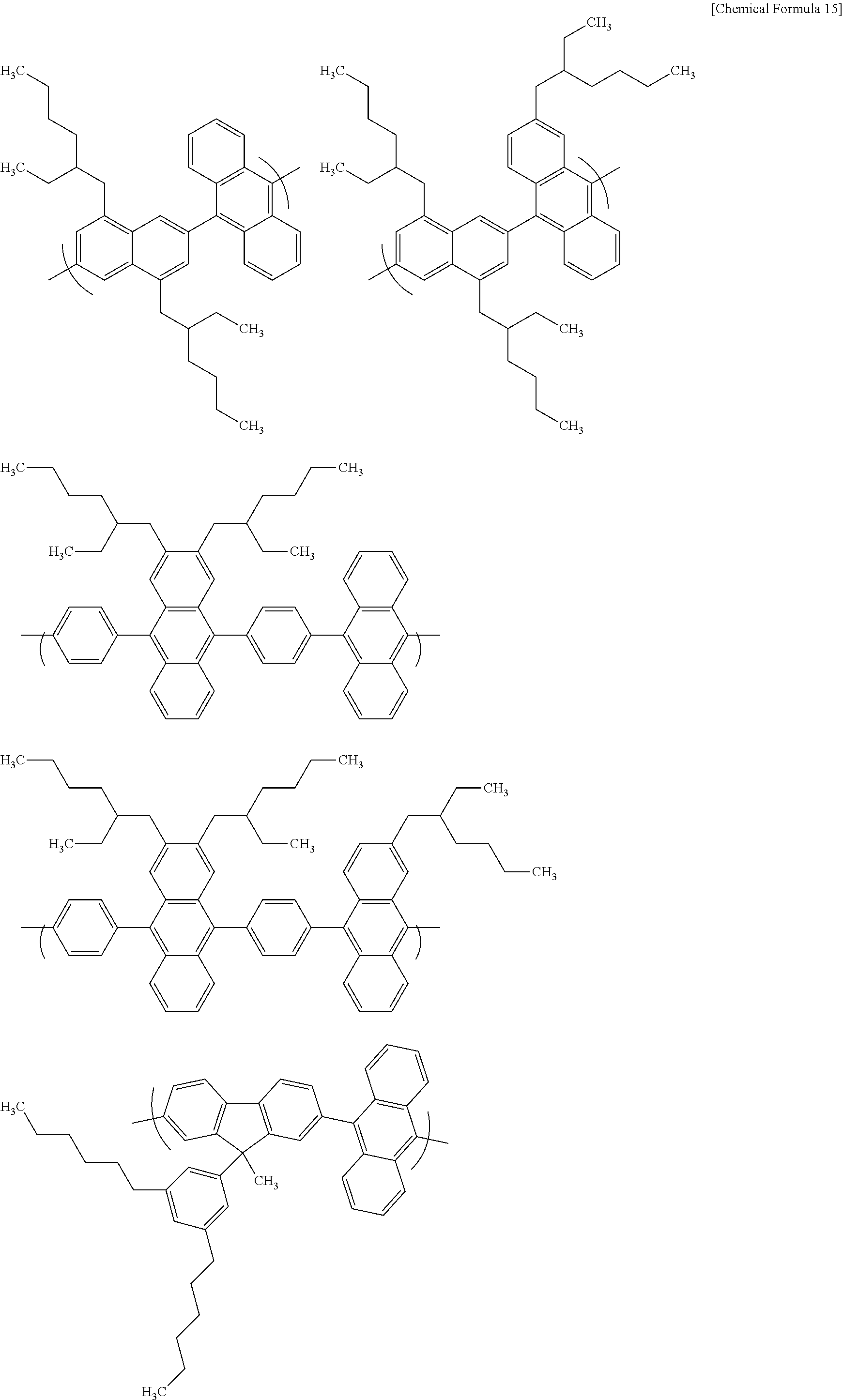

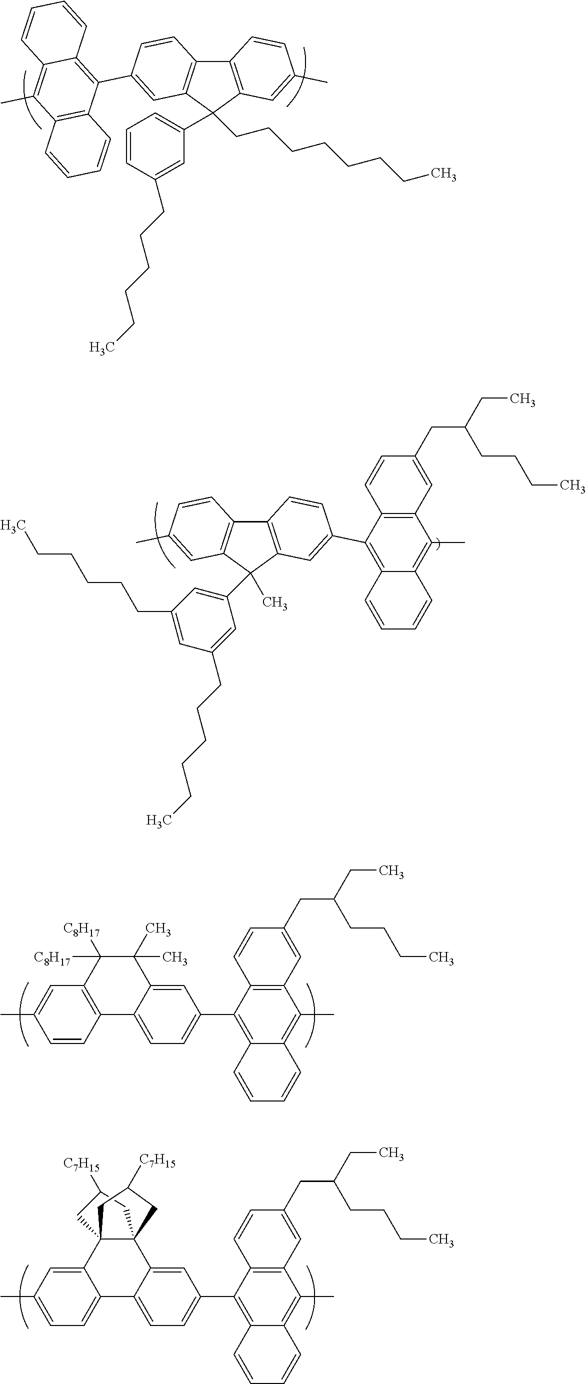

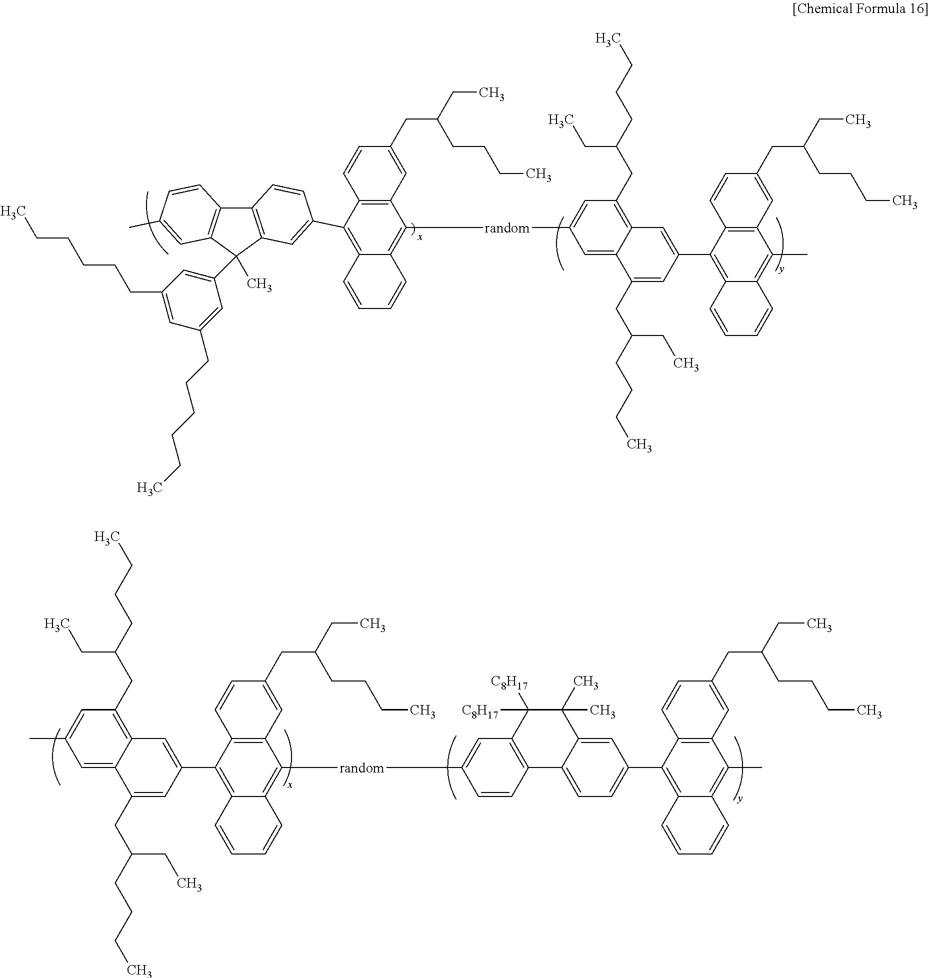

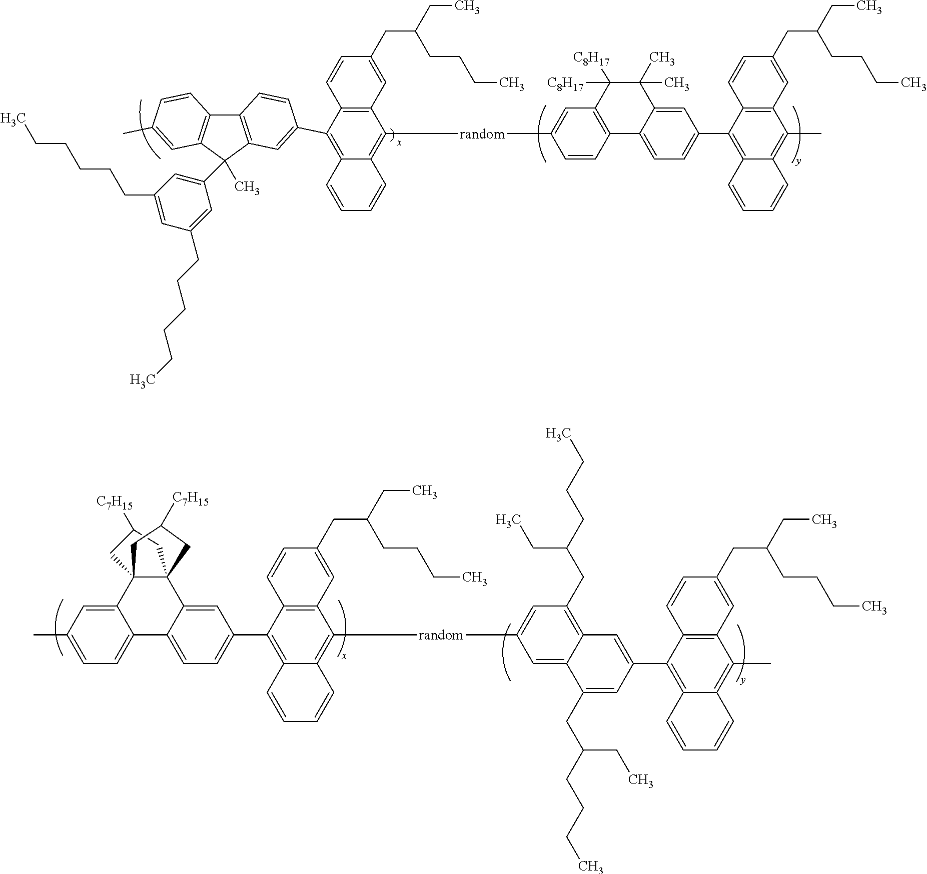

in the formula, x and y represent copolymerization ratio, and are the numbers satisfying x+y=1.

The constitutional sequence represented by the formula (1) may be a structure in which total m of the structures represented by the above formula [—(Y)ₙ—Z—] are sequentially linked to each other with one kind or combined two or more kinds.

The polymer compound that has a constitutional sequence represented by the formula (1) as a main chain has a polystyrene equivalent number average molecular weight of preferably 1×10³ to 1×10⁷, and more preferably 1×10⁴ to 5×10⁶. In addition, the polymer compound has a polystyrene equivalent weight average molecular weight of preferably 1×10⁴ to 5×10⁷, and more preferably 5×10⁴ to 1×10⁷.

Resistance to charge transfer tends to decrease and the property of forming a film by coating tends to be improved when the number average molecular weight and the weight average molecular weight are higher than the lower limits described above, and the property of forming a film by coating tends to be improved when the number average molecular weight and the weight average molecular weight are lower than the upper limits described above.

Hereinafter, preferred method for producing the polymer compound according to the present embodiment is explained in detail. The polymer compound according to the present embodiment can be produced by a condensation polymerization, for example.

Examples of the condensation polymerization include, for example, a method of polymerization by the Suzuki reaction (Chemical Review (Chem. Rev.), vol. 95, p. 2457 (1995), a method of polymerization by the Grignard reaction (Kyoritsu Shuppan Co., Ltd., Polymer Functional Material Series vol. 2, Synthesis and Reaction of Polymer (2), p. 432 to 433), or a method of polymerization by the Yamamoto Polymerization method (Progressive polymer science (Prog. Polym. Sci.), vol. 17, p. 1153 to 1205, 1992).

The polymer compound is preferably the one synthesized by the condensation polymerization, and more preferably the one synthesized by the method of polymerization by the Suzuki reaction.

In particular, when a polymer compound containing a constitutional sequence represented by the formula (1) is to be polymerized, a method of synthesizing the constitutional unit of [—(Y)ₙ—Z—]ₘ as a single unit and incorporating it to a main chain of the polymer, and, a method of polymerizing a polymer containing the constitutional sequence based on a polymerization method which allows sequence control, such as a method of polymerization by the Suzuki reaction, and or the like can be mentioned. Of those, a method of polymerization by the Suzuki reaction is preferable. However, as long as it is a polymer containing a constitutional sequence, the synthetic method is not limited.

Hereinafter, a method of polymerization by the Suzuki reaction is explained.

In the polymer compound, groups represented by Y and Z and a constitutional sequence represented by the formula (1) can be introduced by condensation polymerization between a compound represented by the following formula (M1) and a compound represented by the following formula (M2) or between a compound represented by the following formula (M3) and a compound represented by the following formula (M4). In the polymer compound, arbitrary additional group which is different from the groups represented by Y and Z may be introduced by condensation polymerization.

A-Y-A (M1)

in the formula, Y has the same meaning as defined above, A represents a halogen atom, and two A's may be the same as or different to each other.

B′—Z—B′ (M2)

in the formula, Z has the same meaning as defined above, B′ represents a boric acid ester residue, a boric acid residue (—B(OH)₂), a group represented by the following formula (a-1), a group represented by the following formula (a-2), a group represented by the following formula (a-3), or a group represented by the following formula (a-4), and two B′'s may be the same as or different from each other.

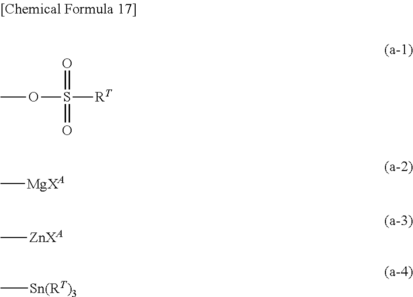

in the formula, R^{T} represents an alkyl group, or an aryl group, and may be substituted. X^{A} represents a halogen atom.

A-Z-A (M3)

in the formula, Z and A has the same meaning as defined above, and two A's may be the same as or different from each other.

B′—Y—B′ (M4)

in the formula, Y and B′ have the same meaning as defined above, and two B′'s may be the same as or different from each other.

Examples of the halogen atom represented by A or X^{A} include a chlorine atom, a bromine atom, and an iodine atom.

Examples of the boric acid ester residue represented by B′ include the group represented by the following formula.

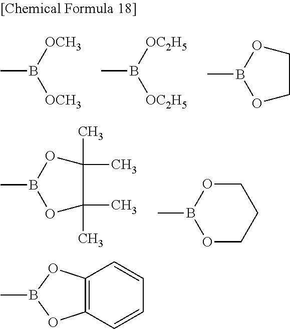

In the formula (a-1), the alkyl group represented by R^{T} is the same as the explanations and examples given in the “Explanation of terminology” described above, the unsubstituted alkyl group is preferably a methyl group, an ethyl group, a n-butyl group, the substituted alkyl group is preferably a trifluoromethyl group, a pentafluoroethyl group.

In the formula (a-1), the aryl group represented by R^{T} is the same as the explanations and examples given in the “Explanation of terminology” described above, and preferably a phenyl group, a 4-methylphenyl group, and a 4-n-butylphenyl group.

Examples of the sulfonate group include a methane sulfonate group, a trifluoromethane sulfonate group, a phenyl sulfonate group, and a 4-methylphenyl sulfonate group.

In the formula (a-4), examples of the unsubstituted alkyl group represented by R^{T} include a methyl group, an ethyl group, an n-butyl group, and examples of the substituted alkyl group include a trifluoromethyl group, a pentafluoroethyl group.

In the formula (a-1), examples of the aryl group represented by R^{T} include a phenyl group, a 4-methylphenyl group, a 4-n-butylphenyl group.

Examples of the groups represented by formula (a-4) include a trimethylstannanyl group, a triethylstannanyl group, a tributylstannanyl group.

The compounds represented by the formula (M1), (M2), (M3) or (M4) may be synthesized and isolated beforehand to be used, or may be prepared in the reaction system and used directly.

B in the formula (M2) and (M4) is preferably a boric acid ester residue or boric acid residue in terms of convenience of synthesis and ease of handling of the compound represented by the formula (M2) and (M4).

Examples of the method of condensation polymerization include a method of reacting a compound represented by the formula (M1), (M2), (M3) or (M4), using an appropriate catalyst and an appropriate base.

Such catalysts include a catalyst consisting of a transition metal complex such as palladium complexes like palladium [tetrakis(triphenylphosphine)], [tris(dibenzylideneacetone)]dipalladium, palladium acetate or the like, nickel complexes like nickel [tetrakis(triphenylphosphine)], [1,3-bis(diphenylphosphino)propane]dichloronickel, [bis(1,4-cyclooctadiene)]nickel, or the like, and, as necessary, a further ligand such as triphenylphosphine, tri(tert-butylphosphine), tricyclohexylphosphine, diphenylphosphinopropane, bipyridyl. The catalyst may be synthesized beforehand to be used, or may be prepared in the reaction system and used directly. These catalysts may be used either alone or in combinations of two or more.

When the aforementioned catalyst is used, the amount of metal atom in the catalyst is preferably 0.00001 to 3 mol equivalents, more preferably 0.00005 to 0.5 mol equivalents, still more preferably 0.0001 to 0.2 mol equivalents, and particularly preferably 0.0001 to 0.01 mol equivalents with respect to the total number of moles of the compound represented by the formula (M1), (M2), (M3) or (M4).

Examples of the bases include inorganic bases such as sodium carbonate, potassium carbonate, cesium carbonate, potassium fluoride, cesium fluoride or tripotassium phosphate, or organic bases such as tetrabutylammonium fluoride, tetrabutylammonium chloride, tetrabutylammonium bromide or tetrabutylammonium hydroxide. These bases may be used either alone or in combinations of two or more.

When the base is used, the amount of use is preferably 0.5 to 20 mol equivalents and more preferably 1 to 10 mol equivalents with respect to the total number of moles of the compound represented by the formula (M1), (M2), (M3) or (M4).

The condensation polymerization is usually conducted in the presence of a solvent such as an organic solvent.

The organic solvent may vary depending on the type of compound represented by the formula (M1), (M2), (M3) or (M4) and on the reaction, and is, for example, toluene, xylene, mesitylene, tetrahydrofuran, 1,4-dioxane, dimethoxyethane, N,N-dimethylacetamide or N,N-dimethyl formamide. In order to inhibit secondary reactions, such solvents are preferably subjected to deoxidizing treatment in advance. These organic solvents may be used either alone or in combinations of two or more.

The amount of organic solvent used is such that the total concentration of the compound represented by the formula (M1), (M2), (M3) or (M4) is usually 0.1 to 90% by mass, preferably 1 to 50% by mass, and more preferably 2 to 30% by mass.

The reaction temperature for the condensation polymerization is preferably −100 to 200° C., more preferably −80 to 150° C. and still more preferably 0 to 120° C.

The reaction time may vary depending on the conditions such as the reaction temperature, but it will usually be at least 1 hour, and is preferably 2 to 500 hours.

In the polymer compound, when mole numbers of Y, Z, and the arbitrary additional group M in the polymer compound are N_{Y}, N_{Z} and N_{M}, respectively, N_{Y}, N_{Z} and N_{M} preferably satisfy the following equation (2-0), more preferably satisfy the following equation (2), still more preferably satisfy the following equation (2-1).

20≦N_{Y}×100/(N_{Y}+N_{Z}+N_{M})≦75 (2-0)

30≦N_{Y}×100/(N_{Y}+N_{Z}+N_{M})≦75 (2)

40≦N_{Y}×100/(N_{Y}+N_{Z}+N_{M})≦75 (2-1)

In this regard, it is preferable that the polymer compound is a copolymer consisting of a constitutional sequence represented by the formula (1) only. When the main chain of the polymer compound is consisting of a constitutional sequence represented by the formula (1) only, there is a tendency that luminous life time is even further improved.

Post-treatment after condensation polymerization may be carried out by a known method, such as adding the reaction solution obtained by condensation polymerization to a lower alcohol such as methanol and filtering and drying the deposited precipitate.

The polymer compound is obtained as described above may be mixed with, for example, a light emitting material described below by a known method to prepare a composition.

When the polymer compound is polymerized by the Suzuki reaction, it is preferable that the monomer type and monomer ratio of the monomers used are appropriately selected.

For example, when dibromide (50 mol %) of Y and diboric acid compound (50 mol %) of Z are prepared as a monomer and synthesized by the Suzuki reaction, an alternating copolymer of Y and Z is yielded, and therefore a polymer consisting only of the following constitutional sequence represented by the formula (1) can be polymerized.

[—Y—Z—]ₘ (1)

Further, for a polymer which is obtained by preparing dibromide of Y, diboric acid compound of Z, and monomer as a third component (referred to as J) and polymerizing them by the Suzuki reaction with molar ratio of 37.5 mol %:50 mol %:12.5 mol % for the dibromide of Y, diboric acid compound of Z, and dibromide of J, there is a possibility that the polymer compound in which m is less than 4 like the following formula (I-1) is yielded:

. . . —Y—Z—Y—Z—Y—Z-J-Z—Y—Z—Y—Z—Y—Z-J-Z . . . (1-1)

Meanwhile, when the dibromide of Y is greater than 37.5 mol % and the dibromide of J is smaller than 12.5 mol %, the polymerization proceeds to yield only a polymer compound having a constitutional sequence with m of 4 or more. For example, even for a case in which the dibromide of Y, the diboric acid compound of Z, and the dibromide of J are polymerized by the Suzuki reaction with molar ratio of 45 mol %:50 mol %:5 mol %, the polymer compound having the constitutional sequence represented by the formula (1) as a main chain can be produced.

According to the present embodiment, when a monomer other than the dibromide of Y and the diboric acid compound of Z is used for polymerization of the polymer compound, it is preferable to select each monomer type and monomer ratio such that the polymer containing the constitutional sequence represented by the formula (1) is necessarily yielded.

As described above, for a case in which the dibromide of J as a third component is present in addition to the dibromide of Y and the diboric acid compound of Z, and when the dibromide of Y, the diboric acid compound of Z, and the dibromide of J are used at ratio of 50-t (mol %):50 (mol %):t (mol %), preferred range of t is 0<t<12.5, more preferably 0<t≦10, and still more preferably 0<t≦5. Herein, t is a number which is larger than 0 but less than 50.

When the polymer compound of the present embodiment containing the constitutional sequence is synthesized by use of the Suzuki reaction, by obtaining in advance the average of constitutional sequence yielded by the ratios of polymerized monomers according to the method described in the following “Polymerization simulation”, it is possible to determine whether or not the polymer compound contains the constitutional sequence.

[Polymerization Simulation]

Polymerization simulation was performed by establishing a program having functions described below.

The number of each of k (k is an integer of 1 or more) types of the monomer units [hereinafter, referred to as “monomer unit A group” having two leaving group A (for example, a boric acid ester residue) is defined as:

M₁, . . . , Mₖ (M₁, . . . , Mₖ are an integer of 1 or more),

and the number of each of v (v is an integer of 1 or more) types of the monomer units [hereinafter, referred to as “monomer unit B group”] having two leaving group B (for example, a bromine atom) is defined as:

N₁, . . . , Nᵥ (N₁, . . . , Nᵥ are an integer of 1 or more).

Then, a program which repeats the following two steps (“Step 1” and “Step 2”) until the ratio (N_{F}/Nₒ) of the number of unreacted leaving group (N_{F}) to the number of leaving group present at initial stage (N₀) decreases to a specific value (hereinafter, referred to as “R value”) is established. Herein, the number of unreacted leaving group indicates the total number of leaving groups which remain after performing the following two steps (“Step 1” and “Step 2”).

[Step 1]

Step for selecting one monomer unit from the monomer unit A group and one monomer unit from the monomer unit B group based on two random numbers.

[Step 2]

Step for registering a bond between two monomer units which have been selected from Step 1 and reducing one at a time the number of leaving group in the selected monomer units.

Regarding an occurrence of random numbers by a calculator, the program described in Hiroshi Haramoto, Makoto Matsumoto, INFORMS Journal on Computing Vol. 20, No. 3, Summer 2008, pp. 385-390) was used.

[Calculation of Average Sequence Length]

The average sequence length was calculated as described below.

First, one monomer unit is selected from each of the monomer unit A group and the monomer unit B group, the same identification symbol P is given to them, and then “Polymerization simulation” was performed. Sequence of the polymer obtained by polymerization was scanned and number of P (hereinafter, referred to as “P sequence length”) constituting the sequence (hereinafter, referred as “P sequence”) of the monomer unit identified as symbol P was recorded. A case in which the monomer unit identified as symbol P is present without forming a sequence (i.e., P is present as a unreacted monomer) and a case in which all the monomer units bound to P are not P are excluded. In other words, a case in which no P sequence is present is excluded. Further, the number obtained by dividing the total P constituting the P sequence (i.e., total of the P sequence length) by the number of P sequence is taken as the average sequence length. The “Polymerization simulation” was independently performed five times for one polymerization condition, and the average sequence length obtained from five runs was averaged to obtain a desired average sequence length.

Specific conditions for calculation are based on the following settings.

(S1) Condition of Polymerization Simulation (General)

With k=1, v=2, R value=0.003, and, M₁=5000, the first type of the monomer unit was given with the identification symbol P for both the monomer unit A group and the monomer unit B group.

(S2) Individual Condition for Polymerization Simulation

Polymerization condition 1: N₁=500, N₂=4500
Polymerization condition 2: N₁=1000, N₂=4000
Polymerization condition 3: N₁=1500, N₂=3500
Polymerization condition 4: N₁=2000, N₂=3000
Polymerization condition 5: N₁=2500, N₂=2500
Polymerization condition 6: N₁=3000, N₂=2000
Polymerization condition 7: N₁=3500, N₂=1500
Polymerization condition 8: N₁=4000, N₂=1000
Polymerization condition 9: N₁=4500, N₂=500

The average sequence lengths obtained by calculation are as follows.

Polymerization condition 1: average sequence length=3.2
Polymerization condition 2: average sequence length=3.5
Polymerization condition 3: average sequence length=3.8
Polymerization condition 4: average sequence length=4.3
Polymerization condition 5: average sequence length=5.0
Polymerization condition 6: average sequence length=5.9
Polymerization condition 7: average sequence length=7.6
Polymerization condition 8: average sequence length=10.7
Polymerization condition 9: average sequence length=19.8

Herein, when M₁ and N₁ each corresponds to Z and (Y)ₙ of the formula (1), in the polymer according to aforementioned polymerization condition, the average value (m′) corresponding to m of the formula (1) is as follows.

Polymerization condition 1: m′=1.6
Polymerization condition 2: m′=1.75
Polymerization condition 3: m′=1.9
Polymerization condition 4: m′=2.15
Polymerization condition 5: m′=2.5
Polymerization condition 6: m′=2.95
Polymerization condition 7: m′=3.8
Polymerization condition 8: m′=5.35
Polymerization condition 9: m′=9.9

With regard to m′ as obtained above, it is preferable that m′≧3.0, it is more preferable that m′≧3.8, it is still more preferable that m′≧5.35, it is particularly preferable that m′≧9.9.

Meanwhile, to see whether or not the polymer compound synthesized based on the description of “Polymerization simulation” satisfies the above formula (1), nuclear magnetic resonance (NMR) spectroscopy can be used, for example.

<Light Emitting Material>

Although the polymer compound according to the present embodiment can form a light emitting layer by itself, it is preferably mixed with a common light emitting material to form a light emitting layer, because an organic electroluminescence device having high durability can be obtained. As such light emitting material, low molecular weight fluorescent materials, high molecular weight fluorescent materials or triplet light emitting materials that are described in “Organic EL Display device” (Shizuo Tokito, Chihaya Adachi, and Hideyuki Murata, The 1st Edition, 1st Issue issued on Aug. 20, 2004, Ohmsha Ltd.) pp. 17 to 48, 83 to 99, or 101 to 120 can be preferably used. Examples of the low molecular weight fluorescent material (low molecular weight fluorescent substances) include perylene or a derivative thereof, pigments such as polymethine based, xanthene based, coumarin based or cyanine based, a metal complex of 8-hydroxyquinoline, or a metal complex of a derivative of 8-hydroxyquinoline, aromatic amine, tetraphenylcyclopentadiene or a derivative thereof, and tetraphenyl butadiene or a derivative thereof. More specifically, those described in Japanese Patent Application Laid-Open Publication No. 57-51781 or Japanese Patent Application Laid-Open Publication No. 59-194393 can be used. Additional examples of the light emitting material include polyfluorene, a copolymer of fluorene derivatives, polyarylene, a copolymer of arylene derivatives, polyarylene vinylene, a copolymer of arylene vinylene derivatives, an aromatic amine, and a (co) polymer of derivatives thereof that are described in International Publication No. 99/13692 pamphlet, International Publication No. 99/48160 pamphlet, German Patent Application Laid-Open Publication No. 2340304, International Publication No. 00/53656 pamphlet, International Publication No. 01/19834 pamphlet, International Publication No. 00/55927 pamphlet, German Patent Application Laid-Open Publication No. 2348316, International Publication No. 00/46321 pamphlet, International Publication No. 00/06665 pamphlet, International Publication No. 99/54943 pamphlet, International Publication No. 99/54385 pamphlet, U.S. Pat. No. 5,777,070, International Publication No. 98/06773 pamphlet, International Publication No. 97/05184 pamphlet, International Publication No. 00/35987 pamphlet, International Publication No. 00/53655 pamphlet, International Publication No. 01/34722 pamphlet, International Publication No. 99/24526 pamphlet, International Publication No. 00/22027 pamphlet, International Publication No. 00/22026 pamphlet, International Publication No. 98/27136 pamphlet, U.S. Pat. No. 5,736,36, International Publication No. 98/21262 pamphlet, U.S. Pat. No. 5,741,921, International Publication No. 97/09394 pamphlet, International Publication No. 96/29356 pamphlet, International Publication No. 96/10617 pamphlet, European Patent Application Laid-Open Publication No. 0707020, International Publication No. 95/07955 pamphlet, Japanese Patent Application Laid-Open Publication No. 2001-181618, Japanese Patent Application Laid-Open Publication No. 2001-123156, Japanese Patent Application Laid-Open Publication No. 2001-3045, Japanese Patent Application Laid-Open Publication No. 2000-351967, Japanese Patent Application Laid-Open Publication No. 2000-303066, Japanese Patent Application Laid-Open Publication No. 2000-299189, Japanese Patent Application Laid-Open Publication No. 2000-252065, Japanese Patent Application Laid-Open Publication No. 2000-136379, Japanese Patent Application Laid-Open Publication No. 2000-104057, Japanese Patent Application Laid-Open Publication No. 2000-80167, Japanese Patent Application Laid-Open Publication No. 10-324870, Japanese Patent Application Laid-Open Publication No. 10-114891, Japanese Patent Application Laid-Open Publication No. 9-111233, or Japanese Patent Application Laid-Open Publication No. 9-45478. The polymer compound which is a light emitting material and includes a constitutional sequence represented by the formula (1) as a main chain is categorized into the polymer compound described above.

The content ratio of the light emitting material is preferably 3 to 30 parts by mass, more preferably 3 to 20 parts by mass, especially preferably 3 to 10 parts by mass based on 100 parts by mass of the polymer compound according to the present embodiment from the viewpoint of the good luminous efficiency.

The polymer compound according to the present embodiment may be prepared as a composition with at least one material selected from the group consisting of hole transport materials and electron transport materials, and it can be used as a light emitting layer and/or a charge transport layer. The hole transport material and the electron transport material principally play a role of adjusting a charge (holes and charges) balance.

Examples of the hole transport material include polyvinylcarbazole and derivatives thereof, polysilane and derivatives thereof, polysiloxane derivatives having an aromatic amine in a side chain or a main chain, pyrazoline derivatives, arylamine derivatives, stilbene derivatives, triphenyldiamine derivatives, polyaniline and derivatives thereof, polythiophene and derivatives thereof, polypyrrole and derivatives thereof, poly(p-phenylenevinylene) and derivatives thereof, poly(2,5-thienylenevinylene) and derivatives thereof. Further examples include those hole transport materials described in Japanese Patent Application Laid-Open Publication No. 63-70257, Japanese Patent Application Laid-Open Publication No. 63-175860, Japanese Patent Application Laid-Open Publication No. 2-135359, Japanese Patent Application Laid-Open Publication No. 2-135361, Japanese Patent Application Laid-Open Publication No. 2-209988, Japanese Patent Application Laid-Open Publication No. 3-37992, and Japanese Patent Application Laid-Open Publication No. 3-152184.

The content ratio of the hole transport material is, when it is used as a light emitting layer, preferably 3 to 30 parts by mass, more preferably 3 to 20 parts by mass, especially preferably 3 to 10 parts by mass based on 100 parts by mass of the polymer compound according to the present embodiment from the viewpoint of the good charge balance.

The content ratio of the hole transport material is, when it is used as a hole transfer layer, preferably 3 to 95 parts by mass, more preferably 3 to 90 parts by mass, especially preferably 5 to 80 parts by mass based on 100 parts by mass of the polymer compound according to the present embodiment from the viewpoint of the good charge balance.

Examples of the electron transport material include oxadiazole derivatives, anthraquinodimethane and derivatives thereof, benzoquinone and derivatives thereof, naphthoquinone and derivatives thereof, anthraquinone and derivatives thereof, teteracyanoanthraquinonodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof. Further examples include those electron transport materials described in 63-70257, Japanese Patent Application Laid-Open Publication No. 63-175860, Japanese Patent Application Laid-Open Publication No. 2-135359, Japanese Patent Application Laid-Open Publication No. 2-135361, Japanese Patent Application Laid-Open Publication No. 2-209988, Japanese Patent Application Laid-Open Publication No. 3-37992, and Japanese Patent Application Laid-Open Publication No. 3-152184.

The content ratio of the electron transport material is preferably 5 to 50 parts by mass, more preferably 5 to 30 parts by mass, especially preferably 5 to 20 parts by mass based on 100 parts by mass of the polymer compound according to the present embodiment from the viewpoint of obtaining the good charge balance.

The content ratio of the electron transport material is preferably 3 to 95 parts by mass, more preferably 3 to 90 parts by mass, especially preferably 5 to 80 parts by mass based on 100 parts by mass of the polymer compound according to the present embodiment from the viewpoint of obtaining good charge balance.

The polymer composition according to the present embodiment can be used with an organic solvent to form a solution or a dispersion liquid (hereinafter, referred to simply as a “solution”). By making it form a solution, a film can be formed by a coating method. This solution is generally called an ink composition, a liquid composition or the like. The solution may also contain the hole transport material and/or the electron transport material described above.

Examples of the organic solvent include chlorine based solvents, such as chloroform, methylene chloride, 1,2-dichloroethane, 1,1,2-trichloroethane, chlorobenzene, and o-dichlorobenzene, ether based solvents, such as tetrahydrofuran and dioxane, aromatic hydrocarbon based solvents, such as toluene, xylene, trimethylbenzene, and mesitylene, aliphatic hydrocarbon based solvents, such as cyclohexane, methylcyclohexane, n-pentane, n-hexane, n-heptane, n-octane, n-nonane, and n-decane, ketone based solvents, such as acetone, methyl ethyl ketone, and cyclohexanone, ester based solvents, such as ethyl acetate, butyl acetate, methyl benzoate, and ethyl cellosolve acetate, polyols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, and 1,2-hexanediol or derivatives thereof, alcoholic solvents, such as methanol, ethanol, propanol, isopropanol, and cyclohexanol, sulfoxide based solvents, such as dimethylsulfoxide, and amide based solvents, such as N-methyl-2-pyrolidone, and N,N-dimethyl formamide. These solvents may be used either singly or in combination of two or more kinds. Among these solvents, it is preferable to include organic solvents having a structure including a benzene ring, and having a melting point of 0° C. or lower and boiling point of 100° C. or higher, because the solution has an appropriate viscosity and, as a result, there is a tendency that film-forming property gets better.

Content ratio of the organic solvent is preferably 10 to 1000 parts by mass, more preferably 20 to 500 parts by mass, especially preferably 30 to 100 parts by mass based on 1 part by mass of the polymer compound according to the present embodiment from the viewpoint of obtaining good film-forming property.

For a case in which the polymer compound according to the present embodiment contains an organic solvent, it is only necessary to remove the organic solvent by drying after applying the solution for laminating/forming a film made of the polymer compound, which is very advantageous in manufacture. Further, for drying, the light emitting material may be dried with heating to about 50 to 150° C. or dried under a reduced pressure of about 10⁻³ Pa.

For lamination and film formation, there can be used coating methods such as a spin coating method, a casting method, a micro-gravure coating method, a gravure coating method, a bar coating method, a roll coating method, a wire bar coating method, a dip coating method, a slit coating method, a capillary coating method, a spray coating method, a screen printing method, a flexographic printing method, an offset printing method, an inkjet printing method, and a nozzle coating method.

If the polymer compound according to the present embodiment includes an organic solvent, viscosity of the solution is preferably in a range of 0.5 to 500 mPa·s at 25° C., although it may vary depending on the printing method. Further, viscosity is preferably in a range of 0.5 to 20 mPa·s at 25° C. for preventing clogging and deflection during jetting in the case of a printing method in which a solution passes through a jetting apparatus, such as an inkjet printing method or the like.

[Film]

The aforementioned polymer compound forms a film as an organic layer. Such film can be easily produced from the above-mentioned solution by the method described above. Such film contains the polymer compound, and therefore is suitable as a light emitting layer and/or a charge transport layer of an organic EL device, and an organic EL device having the film as a light emitting layer and/or a charge transport layer has an improved luminous life time.

[Organic EL Device]

The organic EL device includes a pair of electrodes consisting of an anode and a cathode and an organic layer provided between the pair of electrodes. Here, the organic layer functions as a light emitting layer and/or a charge transport layer. The organic EL device preferably has a light emitting layer and/or a charge transport layer consisting of the film described above.

Constitutions of the organic EL device include the following constitutions a) to d).

a) anode/light emitting layer/cathode
b) anode/hole transport layer/light emitting layer/cathode
c) anode/light emitting layer/electron transport layer/cathode
d) anode/hole transport layer/light emitting layer/electron transport layer/cathode

Here, / means that the layers are laminated adjacent to one another. The same applies hereinafter.

The light emitting layer is a layer having a function of emitting light, the hole transport layer is a layer having a function of transporting holes, and the electron transport layer is a layer having a function of transporting electrons. The hole transport layer and the electron transport layer are collectively called a charge transport layer.

Lamination/film formation of the layers can be carried out from a solution. For lamination/film formation from a solution, there can be used coating methods such as a spin coating method, a casting method, a micro-gravure coating method, a gravure coating method, a bar coating method, a roll coating method, a wire bar coating method, a dip coating method, a slit coating method, a capillary coating method, a spray coating method, a screen printing method, a flexographic printing method, an offset printing method, an inkjet printing method, and a nozzle coating method.

Film thickness of the light emitting layer may be selected so that the driving voltage and light emitting efficiency become appropriate values, but is usually 1 nm to 1 μm, preferably 2 nm to 500 nm, and still more preferably 5 nm to 200 nm.

If the organic EL device has a hole transport layer, examples of the hole transport material used include the same materials as those described above. Film formation of the hole transport layer may be carried out by any method, but if the hole transport material is a small molecule compound, it is preferable to form a film from a mixed solution with a polymer binder. If the hole transport material is a polymer compound, it is preferable to form a film from a solution. For film formation from a solution, a method provided as an example of a coating method may be used.

The polymer binder to be mixed is preferably a compound that does not extremely hinder charge transportation, and has no strong absorption of visible light. Examples of the polymer binder include polycarbonate, polyacrylate, polymethyl acrylate, polymethyl methacrylate, polystyrene, polyvinyl chloride, and polysiloxane.

Film thickness of the hole transport layer may be selected so that the driving voltage and light emitting efficiency become appropriate values, but at least the thickness such that pinholes do not form is necessary, and exceeding thickness is not preferable because it brings down high driving voltage of the device. Thus, film thickness of the hole transport layer is usually 1 nm to 1 μm, preferably 2 nm to 500 nm, and still more preferably 5 nm to 200 nm.

If the organic EL device has an electron transport layer, examples of the electron transport material used include the same materials as those described above. Film formation of the electron transport layer may be carried out by any method, but if the electron transport material is a small molecule compound, a vacuum deposition method from a powder, and a method by film formation from a solution or a molten state are preferable. If the electron transport material is a polymer compound, a method by film formation from a solution or a molten state is preferable. For film formation from a solution or a molten state, a polymer binder may be used in combination. For film formation from a solution, a method provided as an example of a coating method may be used.

The polymer binder to be mixed is preferably a compound that does not extremely hinder charge transportation, and has no strong absorption of visible light. Examples of the polymer binder include poly(N-vinylcarbazole), polyaniline and derivatives thereof, polythiophene and derivatives thereof, poly(p-phenylenevinylene) and derivatives thereof, poly(2,5-thienylenevinylene) and derivatives thereof, polycarbonate, polyacrylate, polymethyl acrylate, polymethyl methacrylate, polystyrene, polyvinyl chloride, and polysiloxane.

Film thickness of the electron transport layer may be selected so that the driving voltage and light emitting efficiency become appropriate values, but at least the thickness such that pinholes do not form is necessary, and exceeding thickness is not preferable because it brings down high driving voltage of the device. Thus, film thickness of the electron transport layer is usually 1 nm to 1 μm, preferably 2 nm to 500 nm, and still more preferably 5 nm to 200 nm.

In addition, among charge transport layers provided adjacent to the electrode, a layer having a function of improving efficiency of charge injection from the electrode and having an effect of lowering the driving voltage of the device may be particularly called a charge injection layer (hole injection layer, electron injection layer) in some cases. Moreover, the charge injection layer or an insulating layer may be provided adjacent to the electrode for improvement of adhesive properties with the electrode and improvement of injection of charges from the electrode, or a thin buffer layer may be inserted into an interface of the charge transport layer or the light emitting layer for improvement of adhesive properties of the interface, prevention of mixing and the like. Further, the order and the number of layers to be laminated and thickness of each layer may be selected as appropriate in consideration of the light emitting efficiency and device life.

The organic EL devices provided with a charge injection layer include those having the following constitutions e) to p).

e) anode/charge injection layer/light emitting layer/cathode
f) anode/light emitting layer/charge injection layer/cathode
g) anode/charge injection layer/light emitting layer/charge injection layer/cathode
h) anode/charge injection layer/hole transport layer/light emitting layer/cathode
i) anode/hole transport layer/light emitting layer/charge injection layer/cathode
j) anode/charge injection layer/hole transport layer/light emitting layer/charge injection layer/cathode
k) anode/charge injection layer/light emitting layer/charge transport layer/cathode
l) anode/light emitting layer/electron transport layer/charge injection layer/cathode
m) anode/charge injection layer/light emitting layer/electron transport layer/charge injection layer/cathode
n) anode/charge injection layer/hole transport layer/light emitting layer/charge transport layer/cathode
o) anode/hole transport layer/light emitting layer/electron transport layer/charge injection layer/cathode
p) anode/charge injection layer/hole transport layer/light emitting layer/electron transport layer/charge injection layer/cathode.

Examples of the charge injection layer include a layer including a conducting polymer, a layer provided between the anode and the hole transport layer and including a material having an ionization potential of a medium value between ionization potentials of an anode material and a hole transport material included in the hole transport layer, and a layer provided between the cathode and the electron transport layer and including a material having an electron affinity of a medium value between electron affinities of a cathode material and an electron transport material included in the electron transport layer.

If the charge injection layer is a layer including a conducting polymer, the electric conductivity of the conducting polymer is preferably 10⁻⁵ S/cm to 10³ S/cm, and is more preferably 10⁻⁵ S/cm to 10² S/cm, and still more preferably 10⁻⁵ S/cm to 10¹ S/cm for reducing a leak current between light emitting pixels. For satisfying such a range, the conducting polymer may be doped with an appropriate amount of ions.

The types of ions to be doped are an anion for the hole injection layer and a cation for the electron injection layer. Examples of the anion include a polystyrenesulfonic acid ion, an alkylbenzenesulfonic acid ion, and a camphorsulfonic acid ion, and examples of the cation include a lithium ion, a sodium ion, a potassium ion, and a tetrabutyl ammonium ion.

Film thickness of the charge injection layer is, for example, 1 to 100 nm, preferably 2 to 50 nm.

The material to be used for the charge injection layer may be appropriately selected in relation to the electrode and a material of an adjacent layer, and examples include polyaniline and derivatives thereof, polythiophene and derivatives thereof, polypyrrole and derivatives thereof, polyphenylenevinylene and derivatives thereof, polythienylenevinylene and derivatives thereof, polyquinoline and derivatives thereof, polyquinoxaline and derivatives thereof, conducting polymers such as polymers having an aromatic amine structure in the main chain or side chain, metal phthalocyanines (e.g., copper phthalocyanine), and carbon.

The insulating has a function of facilitating charge injection. Average thickness of the insulating layer is usually 0.1 to 20 nm, preferably 0.5 to 10 nm, more preferably 1 to 5 nm.

Examples of a material used for the insulating layer include metal fluorides, metal oxides, and organic insulating materials.

Examples of the organic EL device provided with an insulating layer include those having the following constitutions q) to ab).

q) anode/insulating layer/light emitting layer/cathode
r) anode/light emitting layer/insulating layer/cathode
s) anode/insulating layer/light emitting layer/insulating layer/cathode
t) anode/insulating layer/hole transport layer/light emitting layer/cathode
u) anode/hole transport layer/light emitting layer/insulating layer/cathode
v) anode/insulating layer/hole transport layer/light emitting layer/insulating layer/cathode
w) anode/insulating layer/light emitting layer/electron transport layer/cathode
x) anode/light emitting layer/electron transport layer/insulating layer/cathode
y) anode/insulating layer/light emitting layer/electron transport layer/insulating layer/cathode
z) anode/insulating layer/hole transport layer/light emitting layer/electron transport layer/cathode
aa) anode/hole transport layer/light emitting layer/electron transport layer/insulating layer/cathode
ab) anode/insulating layer/hole transport layer/light emitting layer/electron transport layer/insulating layer/cathode

The substrate to form the organic EL device may be any substrate as long as it does not chemically decompose when an electrode and a layer of an organic substance are formed, and examples thereof include substrates of glass, plastic, polymer films, and silicon. In the case of a nontransparent substrate, an electrode closer to the substrate and an opposite electrode are preferably transparent or semitransparent.

In the present embodiment, usually at least one of electrodes including an anode and a cathode is transparent or semitransparent, and preferably the electrode at the anode side is transparent or semitransparent.

As a material of the anode, an conducting metal oxide film, a semitransparent metal film or the like is used, and specifically a film prepared using a conducting inorganic compound including indium oxide, zinc oxide, tin oxide, and indium/tin/oxide (ITO), indium/zinc/oxide and the like that are a complex thereof, NESA, gold, platinum, silver, copper or the like is used. Also, an organic transparent conducting film of polyaniline and a derivative thereof, polythiophene and a derivative thereof, or the like may be used as an anode. Also, a layer made of a phthalocyanine derivative, a conducting polymer, carbon or the like, or a layer made of a metal oxide, a metal fluoride, an organic insulating material or the like may be provided on the anode for facilitating charge injection.

Examples of a method for preparing an anode include a vacuum deposition method, a sputtering method, an ion plating method, and a plating method.

Film thickness of the anode may be selected as appropriate in consideration of light transmittance and electric conductivity, but is usually 10 nm to 10 μm, preferably 20 nm to 1 μm, and still more preferably 40 nm to 500 nm.

As a material of the cathode, a material having a small work function is preferable, and a metal such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium or the like, an alloy of two or more of these metals, an alloy of one or more of these metals with one or more of gold, silver, platinum, copper, manganese, titanium, cobalt, nickel, tungsten and tin, or graphite, a graphite intercalation compound or the like is used.

As a method for preparing a cathode, a vacuum deposition method, a sputtering method, and a lamination method by thermocompression of a metal film, or the like is used.

Film thickness of the cathode may be selected as appropriate in consideration of electric conductivity and durability, but is usually 10 nm to 10 μm, preferably 20 nm to 1 μm, and still more preferably 50 nm to 500 nm.

Also, a layer made of a conducting polymer or a layer made of a metal oxide, a metal fluoride, an organic insulating material or the like may be provided between the cathode and the light emitting layer or the cathode and the electron transport layer, or a protective layer for protecting the organic EL device may be mounted after preparation of the cathode. For using the organic EL device with stability for a long time period, a protective layer and/or a protective cover are preferably mounted for protecting the organic EL device from outside.

As the protective layer, a resin, a metal oxide, a metal fluoride, a metal boride or the like may be used. In addition, as the protective cover, a glass plate, a plastic plate with the surface subjected to a water permeability reducing treatment, or the like may be used, and a method is suitably used in which the protective cover is laminated with a device substrate by a thermosetting resin or a photocurable resin to perform sealing. If a space is maintained using a spacer, the device is easily prevented from being scratched. If an inert gas such as nitrogen, argon or the like is filled in the space, oxidation of the cathode can be prevented, and further by placing a drying agent such as barium oxide or the like in the space, moisture adsorbed in a manufacturing step is easily inhibited from damaging the device.

An organic EL device which has an organic layer containing the polymer compound of the present embodiment is useful for, for example, a surface light sources (e.g., lighting) such as a curved surface light source, and a flat light source; displays such as a segment display, a dot matrix display (e.g., a dot matrix flat display), a liquid crystal display (e.g., a liquid crystal display, backlight of a liquid crystal display). In addition, the polymer compound according to the present embodiment is not only suitable as a material for use in production of the above-mentioned articles, but also useful, for example, as a pigment for a laser, a material for an organic solar battery, an organic semiconductor for an organic transistor, a material for a conductive film such as an electrically conductive film or an organic semiconductor film, a light emitting film material emitting fluorescence, a material of a polymer electric field effect transistor.

If a light emitting layer containing the polymer compound of the present embodiment is used as a part of white lighting, a light emitting material with a color other than blue may be contained in the light emitting layer, or a second light emitting layer having a light emitting material with a color other than blue may be included for obtaining white color purity.

For obtaining planar light emission using the organic EL device which has an organic layer containing the polymer compound according to the present embodiment, a planar anode and cathode may be arranged so that they are superimposed on each other. In addition, for obtaining patterned light emission, there are a method in which a mask provided with a patterned window is placed on the surface of the planar organic

EL device and a method in which either one of an anode and a cathode, or both the electrodes are formed in a patterned form. A pattern is formed by either of these methods, and some electrodes are arranged so that they can be independently turned ON/OFF, to thereby obtain a segment type display device that can display numbers, characters, simple symbols and the like. Further, for forming a dot matrix display device, both an anode and a cathode may be formed in a striped form and placed so that they are orthogonal to each other. Partial color display device and multi-color display device can be provided by a method of painting in different colors multi kinds of polymer compounds with different luminescent colors or a method of using a color filter or a fluorescence conversion filter. The dot matrix display device can be passively driven, or may be actively driven in combination with a TFT or the like. These display devices can be used, for example, as displays of computers, televisions, portable terminals, mobile phones, car navigations, and view finders of video cameras.

### EXAMPLES

Hereinafter, the present invention will be described more specifically based on examples and comparative examples, but the present invention is not in any way limited to the following examples.

(Number Average Molecular Weight and Weight Average Molecular Weight)

In the examples, the polystyrene equivalent number average molecular weight and weight average molecular weight were determined by gel permeation chromatography (GPC, manufactured by

Shimadzu Corporation, trade name: LC-10 Avp). A compound to be measured was dissolved in tetrahydrofuran (hereinafter, referred to as “THF”) so as to have a concentration of about 0.5% by mass, and the solution was injected into GPC in an amount of 30 μl. Tetrahydrofuran was used for a mobile phase of GPC, and was allowed to flow at a flow rate of 0.6 mL/minute. For a column, two pieces of TSKgel Super HM-H (manufactured by TOSOH CORPORATION) and a piece of TSKgel SuperH 2000 (manufactured by TOSOH CORPORATION) connected in series were used. For a detector, a differential refractive index detector (manufactured by Shimadzu Corporation, trade name: RID-10A) was used.

(NMR Measurement)

In the examples, the NMR measurement of the monomers was carried out under the following conditions.

Apparatus: nuclear magnetic resonance apparatus, INOVA 300 (trade name), manufactured by Varian Medical Systems Inc.
Measurement solvent: deuterated chloroform or deuterated tetrahydrofuran
Concentration of sample: about 1% by mass
Measurement temperature: 25° C.

(LC-MS Measurement)

LC-MS measurement was performed according to the following method. The measurement sample was dissolved in chloroform or tetrahydrofuran to have concentration of about 2 mg/mL, and then 1 μL was injected to LC-MS (trade name: 1100LCMSD, manufactured by Agilent Technologies). As a mobile phase for LC-MS, ion exchange water, acetonitrile, tetrahydrofuran, or a mixture liquid thereof was used, and acetic acid was added, if necessary. As a column, L-column 2 ODS (3 μm) (manufactured by Chemicals Evaluation and Research Institute, inner diameter: 2.1 mm, length: 100 mm, particle diameter: 3 μm) was used.

(Synthesis of Compounds Used for Polymerization)

### Synthesis Example 1

### Synthesis of Compound 3A

Gas within a four neck flask was replaced with nitrogen and 16.5 parts by mass of 2,7-dibromofluorenone were suspended in diphenyl ether contained in the flask. The suspension was heated to 120° C. to dissolve 2,7-dibromofluorenone, 15.5 parts by mass of potassium hydroxide were added to the solution, and after raising the temperature to 160° C., it was stirred for 2.5 hours. The solution was cooled to the room temperature, then added with hexane, filtered, and the resulting solid matter was washed with hexane. Gas within a four neck flask was replaced with nitrogen and the product obtained from above was dissolved in dehydrated N,N-dimethylformamide (herein below, referred to as “DMF”) contained in the flask. The obtained solution was heated to 90° C., and then total amount of 53.0 parts by mass of methyl iodide was added thereto while following the reaction. The reaction time was 10 hours in total. The solution cooled to the room temperature was added dropwise to water which has been cooled to 0° C., and the reaction product was extracted twice with hexane. Filtration through a glass filter overlaid with silica gel was conducted, and followed by condensation. The concentrate was purified by silica gel column chromatography to obtain the compound 1A in an amount of 13.3 parts by mass.

¹H-NMR (300 MHz/CDCl₃):

δ (ppm)=3.68 (s, 3H), 7.15 (d, 2H), 7.20 (d, 1H), 7.52 (d, 2H), 7.65 (d, 1H), 8.00 (brs, 1H).

¹³C-NMR (300 MHz/CDCl₃):

δ(ppm)=52.6, 121.8, 122.2, 130.1, 131.6, 132.3, 132.4, 133.2, 134.7, 139.4, 140.6, 167.8.

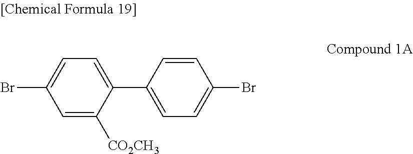 [SMILES: COC(=O)c1cc(Br)ccc1-c1ccc(Br)cc1]

To a three neck round-bottomed flask, 7.5 parts by mass of 1-bromo-4-n-hexylbenzene and anhydrous tetrahydrofuran were added and cooled to −78° C. Thereafter, 1.6 M n-butyl lithium/hexane solution (1 mol equivalent to 1-bromo-4-n-hexylbenzene) was added slowly and stirred for 2 hours at −78° C. While maintaining the temperature, 4.95 parts by mass of the compound 1A were dissolved in anhydrous tetrahydrofuran and, the solution was added dropwise by using a dropping funnel while the temperature is maintained at −70° C. or less. After the dropwise addition was completed, the mixture was stirred for 2 hours at −78° C. and slowly warmed to the room temperature. To the solution, saturated aqueous solution of ammonium chloride was added and stirred. After transferring to a separatory funnel, the aqueous layer was removed. The solution was washed twice with water and dried by adding anhydrous sodium sulfate to the resulting tetrahydrofuran solution. To a glass filter overlaid with silica gel layer, the resulting tetrahydrofuran solution was applied and then filtered, and washed with tetrahydrofuran. The resulting solution was concentrated and dried. Subsequently, it was suspended in 300 mL of hexane, stirred, and filtered to obtain the compound 2A in an amount of 6.0 parts by mass.

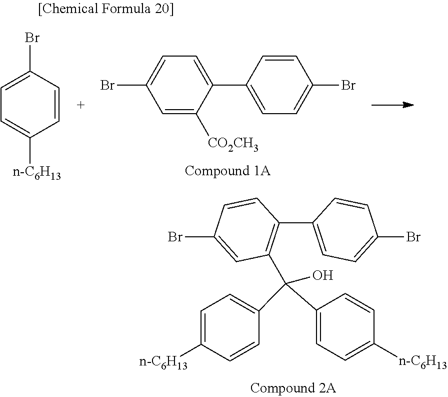

To a three neck round-bottomed flask, the compound 2A (6.0 parts by mass) and dichloromethane were added and cooled to 0° C. by using an ice bath. To the solution, boron trifluoride diethyl ether complex (27 parts by mass) was added dropwise by using a dropping funnel. The solution was stirred for 2 hours at 0° C., and then the solution was added to a beaker containing water and ice to terminate the reaction. The reaction solution was transferred to a separatory funnel for liquid separation. After extraction with dichloromethane, the organic layer was combined, washed twice with water, and dried by adding anhydrous sodium sulfate. To a glass filter overlaid with silica gel layer, the sodium sulfate was filtered off and the filtered solution was concentrated. The resulting oily material was added with toluene and refluxed under heating. After cooling to 70° C., isopropyl alcohol was added, stirred, and then the mixture was kept at the room temperature for cooling. The produced crystals were filtered and dried. The obtained crystals were added to an eggplant flask, additionally added with hexane and activated carbon, and refluxed for 2 hours under heating. A glass filter overlaid with Celite on top of Radiolite (manufactured by Showa Chemical Industry Co., Ltd.) was heated to 70° C. and then the activated carbon was removed by filtering using the glass filter. The obtained filtered solution was concentrated to half volume, refluxed under heating, and stirred at the room temperature for 1 hour. The reaction solution was again stirred for 2 hours under cooling by using an ice bath, and the crystals produced were filtered and collected. As a result, the compound 3A as a target compound was obtained in an amount of 5.4 parts by mass.

¹H-NMR (300 MHz/CDCl₃):

δ(ppm)=0.87 (t, 6H), 1.28˜1.37 (m, 12H), 1.50˜1.62 (m, 4H), 2.54 (t, 4H), 7.04 (s, 8H), 7.45 (d, 2H), 7.49 (s, 2H), 7.55 (d, 2H).

¹³C-NMR (300 MHz/CDCl₃):

δ(ppm)=14.4, 22.9, 29.4, 31.6, 32.0, 35.8, 65.4, 121.8, 122.1, 128.1, 128.7, 129.7, 131.1, 138.3, 141.9, 142.1, 153.7.

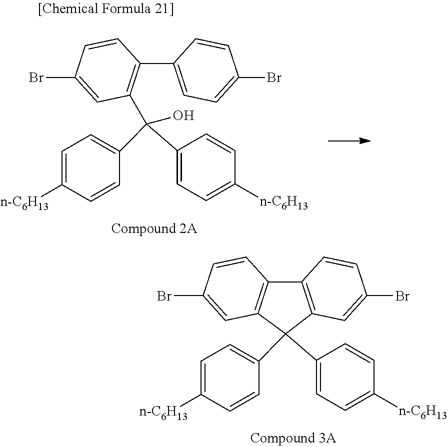

### Synthesis Example 2

### Synthesis of Compound 4A

Under inert gas atmosphere, to a solution consisting of the compound 3A (6.1 parts by mass) and anhydrous tetrahydrofuran, 2.5 M n-butyl lithium/hexane solution (2.5 mol equivalents compared to the compound 3A) were added dropwise at the temperature of −78 to −70° C., and further stirred for 6 hours. Subsequently, at the temperature of −70° C. or less, the compound 5A (isopropyl pinacol borate) (5.2 parts by mass) was added dropwise and stirred overnight at the room temperature. To the resulting reaction mixture, hydrochloric acid—diethyl ether solution was added dropwise at −30° C. After dropwise addition was completed, the temperature was brought back to the room temperature, and the mixture was concentrated under reduced pressure and stirred after adding toluene. Filtration through a filter overlaid with silica gel was conducted and the obtained filtered solution was concentrated under reduced pressure to obtain a solid. The resulting solid was re-crystallized from acetonitrile and toluene. As a result, the compound 4A as a target compound was obtained in an amount of 4.5 parts by mass.

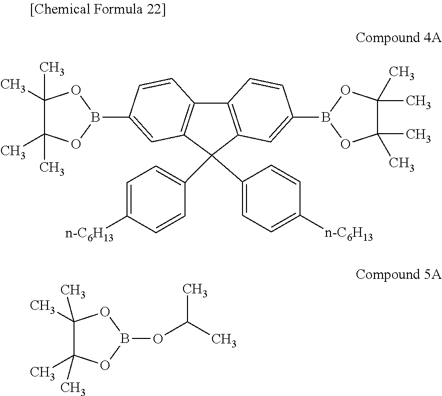

### Synthesis Example 3

### Synthesis of Compound 2B

Under argon atmosphere, 1-bromo-3,5-di-n-hexylbenzene (20.0 parts by mass) and tetrahydrofuran were added to a reaction vessel to prepare a homogeneous solution, which was then cooled to −69° C. Thereafter, 2.76 M n-butyl lithium/hexane solution (1 mol equivalent compared to 1-bromo-3,5-di-n-hexylbenzene) was added dropwise for 1.5 hours at −68° C. and stirred for 1.5 hours at −70° C. Subsequently, a solution consisting of the compound 1B-1 (9.0 parts by mass) and tetrahydrofuran were added dropwise thereto for 1 hour at −70° C. and stirred for 2 hours at −70° C. To the solution, methanol and distilled water were added at −70° C. and stirred. After warming to the room temperature, it was stirred overnight at the room temperature. Subsequently, the reaction mixture was filtered, and the filtered solution was concentrated and stirred after adding heptane and water. After maintaining for a while for liquid separation, the aqueous layer was removed from the organic layer. Saturated brine was added to the organic layer followed by stirring. After maintaining for a while for liquid separation, the aqueous layer was removed from the organic layer. The organic layer was then added with magnesium sulfate and stirred. The filtered solution obtained by filtering was concentrated to obtain the compound 1B in an amount of 23.4 parts by mass.

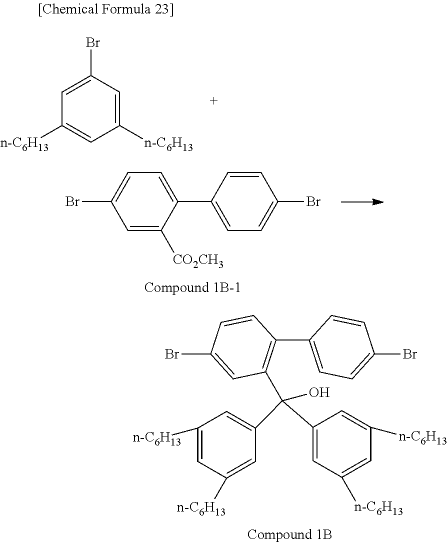

Under argon atmosphere, the compound 1B (48.0 parts by mass) and dichloromethane were added to a reaction vessel to prepare a homogeneous solution, which was then cooled to −30° C. To the solution, boron trifluoride diethyl ether complex (1 mol equivalent compared to the compound 1B) was added dropwise over 30 minutes and stirred overnight at the room temperature. The reaction mixture was then cooled to −20° C., added with distilled water and stirred for 1 hour. After maintaining for a while for liquid separation, the aqueous layer was removed from the organic layer. Subsequently, water was added and stirred. After maintaining for a while for liquid separation, the aqueous layer was removed from the organic layer. 10% by mass of aqueous solution of sodium hydrogen carbonate was added to the resulting organic layer followed by stirring. After maintaining for a while for liquid separation, the aqueous layer was removed from the organic layer. The organic layer was then concentrated to remove the solvent. Subsequently, the resultant was purified by silica gel column chromatography by using toluene and heptane as a developing solvent. The solvent was then removed by concentration. Thereafter, according to re-crystallization using butyl acetate and methanol, the compound 2B as a target compound was obtained in an amount of 23.2 parts by mass.

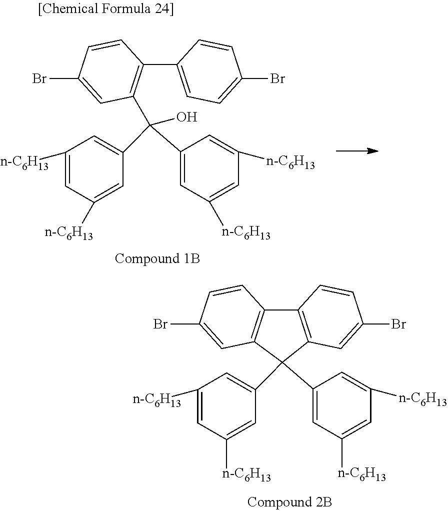

### Synthesis Example 4

### Synthesis of Compound 3B

Under argon atmosphere, the compound 2B (9.5 parts by mass), the compound 3B-1 (6.6 parts by mass), 1,4-dioxane, potassium acetate (7.05 parts by mass), 1,1′-bis(diphenylphosphino)ferrocene (dppf, 0.1 parts by mass) and 1,1′-bis(diphenylphosphino)ferrocene palladium (II) dichloride methylene chloride complex (PdCl₂(dppf)·CH₂Cl₂, 0.15 parts by mass) were added to a four neck flask, and stirred for 5 hours at 100 to 102° C. After cooling the obtained reaction mixture to the room temperature, it was filtered through a filter overlaid with Celite and silica gel, and the filtered solution was concentrated to remove the solvent. Subsequently, to a solution prepared by adding hexane, activated carbon was added and stirred for 1 hour at the temperature which allows reflux of hexane. The resulting mixture was cooled to the room temperature, filtered through a filter overlaid with Celite, and concentrated to remove the solvent. Thereafter, according to re-crystallization using toluene and acetonitrile, the compound 3B as a target compound was obtained in an amount of 10.1 parts by mass.

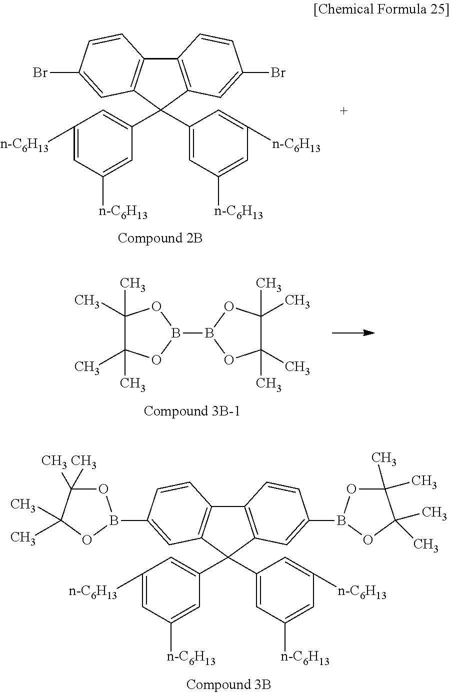

### Synthesis Example 5

### Synthesis of Compound 2C

Under inert atmosphere, 3-n-hexyl-5-methylbromobenzene (26.2 parts by mass) and anhydrous tetrahydrofuran were added to a three neck flask to prepare a homogeneous solution, which was then cooled to −70° C. To the resulting solution, 2.5 M n-butyl lithium/hexane solution (0.93 mol equivalents compared to 3-n-hexyl-5-methylbromobenzene) was added dropwise while maintaining the temperature at −70° C. and stirred for 4 hours at the same temperature to prepare a solution (hereinafter, referred to as “solution A”).

Separately, 2-methoxycarbonyl-4,4′-dibromobiphenyl (16.0 parts by mass) and anhydrous tetrahydrofuran were added to a two neck flask to prepare a solution (hereinafter, referred to as “solution B”).

The solution B was added dropwise to the solution A while maintaining the temperature of the solution A at −70° C. followed by stirring. Subsequently, the reaction solution was stirred for 15 hours at the room temperature. The reaction solution was then added with water at 0° C. and stirred. Subsequently, the solvent was removed by concentration under reduced pressure. The residuals were added with hexane and water, stirred, and kept to obtain an organic layer after removing an aqueous layer. The organic layer was washed with saturated brine, dried over anhydrous magnesium sulfate, and concentrated under reduced pressure to obtain the compound 1C represented by the following formula as a white solid.

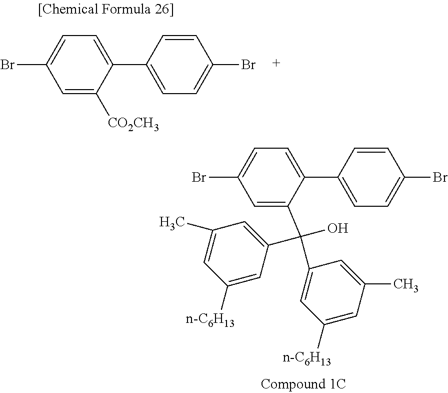

Under inert atmosphere, the compound 1C (30.0 parts by mass) and anhydrous dichloromethane were added to three neck flask and then cooled to 5° C. To the resulting solution, boron trifluoride diethyl ether complex (4.2 mol equivalents compared to the compound 1C) was added dropwise while maintaining the temperature in the range of 0 to 5° C. and stirred overnight at the room temperature. The reaction solution was carefully poured over ice water and stirred for 30 minutes. After maintaining for a while for liquid separation, the aqueous layer was removed from the organic layer. 10% by mass of aqueous solution of potassium phosphate was added to the organic layer followed by stirring for 2 hours. After maintaining for a while, the formed aqueous layer was removed from the organic layer. The organic layer was then washed with water, dried over anhydrous magnesium sulfate, and concentrated to remove the solvent by didyillation, and oily liquid was obtained. Methanol was added to the oily liquid to give a solid. The solid was re-crystallized from n-butyl acetate and methanol, and as a result, the compound 2C represented by the following formula was obtained in an amount of 24.0 parts by mass.

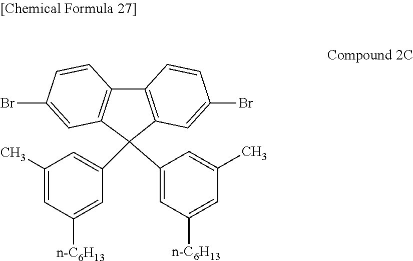

### Synthesis Example 6

### Synthesis of Compound 3C

To a three neck flask, the compound 2C (8.0 parts by mass), bis(pinacolate)diborone (6.6 parts by mass), 1,1′-bis(diphenylphosphino)ferrocene palladium (II) dichloride methylene chloride complex (Pd(dppf)·CH₂Cl₂, 0.15 parts by mass), 1,1′-bis(diphenylphosphino)ferrocene (0.099 parts by mass), and anhydrous 1,4-dioxane and potassium acetate (7.0 parts by mass) were added and stirred at 100° C. for 20 hours. The reaction solution was cooled to the room temperature, passed through silica gel, and the silica gel was washed with toluene and the obtained solution was concentrated for removing the solvent by distillation, yielding brown liquid. The resulting liquid was purified by silica gel column chromatography by using hexane as a developing solvent. To the liquid obtained by concentrating the eluent, acetonitrile was added to obtain a solid. Re-crystallization of solid was performed once from acetonitrile and toluene, and then re-crystallization of solid was performed once from dichloromethane and methanol. After drying under reduced pressure, the compound 3C represented by the following formula was obtained in an amount of 2.9 parts by mass.

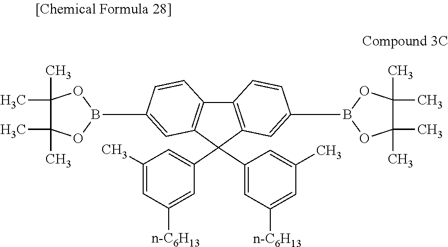

### Synthesis Example 7

### Synthesis of Compound 2D

Gas within a three neck flask was replaced with nitrogen and 22.6 parts by mass of 1-bromo-3-n-hexylbenzene were dissolved in anhydrous tetrahydrofuran in the three neck flask. The resulting solution was cooled to −75° C. or lower, added dropwise with 2.5 M n-butyl lithium/hexane solution (0.96 mol equivalents compared to 1-bromo-3-n-hexylbenzene), and stirred for 5 hours while maintaining at −75° C. or lower. A solution in which 15.0 parts by mass of 2-methoxycarbonyl-4,4′-dibromobiphenyl are dissolved in anhydrous tetrahydrofuran was added dropwise thereto while maintaining the temperature at −70° C. or lower. The solution was slowly warmed to the room temperature and stirred overnight. The reaction solution was added dropwise with water while stirring at 0° C. The solvent was removed from the reaction solution by distillation, and the residues were added with water and extracted three times with hexane. The resulting organic layer was combined, washed with saturated brine, and the aqueous layer was re-extracted with hexane. The obtained organic layer was combined and dried over magnesium sulfate. As a result of removing the solvent, a crude product of the compound 1D was obtained in an amount of 26.4 parts by mass.

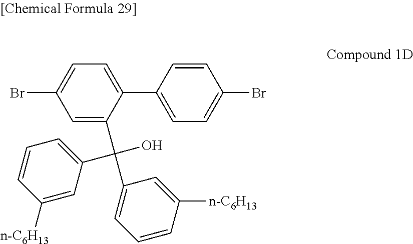

The compound 1D (26.4 parts by mass) synthesized above were dissolved in dichloromethane in a three neck flask, and the gas within the flask was replaced with nitrogen. The resulting solution was cooled to 0° C. or lower and boron trifluoride diethyl ether complex (5 mol equivalents compared to the compound 1D) was added dropwise while maintaining the temperature at 5° C. or lower. After slowly raising to the room temperature, the mixture was stirred overnight. The reaction solution was poured over ice water and stirred for 30 minutes. After liquid separation on the reaction solution, the aqueous layer was extracted with dichloromethane. The organic layer was combined, and liquid separation was performed by adding 10% by mass of aqueous solution of potassium phosphate. The organic layer was washed twice with water and dried over magnesium sulfate. The solvent was removed by distillation, and the resulting oil was dissolved in toluene and filtered by passing through a glass filter overlaid with silica gel. After the solvent was removed by distillation, methanol was added, and vigorous stirring was conducted. The resulting crystals were filtered and washed with methanol. By re-crystallization using a mixture solvent of hexane and butyl acetate, the compound 2D was obtained in an amount of 12.1 parts by mass.

¹H-NMR (300 MHz/CDCl₃):

δ(ppm)=0.86 (6H, t), 1.26 (12H, m), 1.52 (4H, m), 2.51 (4H, t), 6.87 (2H, d), 7.00 (2H,s), 7.04 (2H, d), 7.12 (2H, t), 7.46 (2H, dd), 7.48 (2H, d), 7.55 (2H, d).

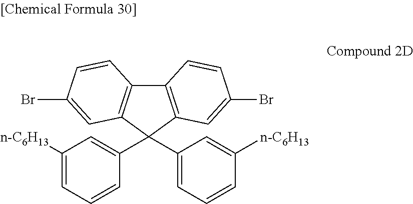

### Synthesis Example 8

### Synthesis of Compound 3D

The compound 2D (5.0 parts by mass) was added to a three neck flask, and the gas within the flask was replaced with nitrogen. Anhydrous tetrahydrofuran was added thereto, and cooled to −70° C. or lower. While maintaining the obtained solution at −70° C. or lower, 2.5 M n-butyl lithium/hexane solution (2.2 mol equivalents compared to the compound 2D) was added dropwise thereto. After the dropwise addition was completed, stirring was conducted for 4 hours while maintaining the temperature of the reaction solution. Then, 2-isopropoxy-4,4,5,5-tetramethyl-1,3,2-dioxaborolane (2.8 mol equivalents compared to the compound 2D) was added thereto. After slowly raising to the room temperature, the mixture was stirred overnight. The reaction solution was cooled to −30° C., added dropwise with 2 M hydrochloric acid/diethyl ether solution, and heated to the room temperature. After the solvent was removed therefrom by distillation, toluene was added to dissolve it, and it was filtered by passing through a glass filter overlaid with silica gel. The solvent in the obtained solution was removed by distillation to give a crude product in an amount of 5.0 parts by mass. The crude product was re-crystallized from a mixture solvent of toluene and acetonitrile under nitrogen atmosphere to give the compound 3D in an amount of 3.4 parts by mass.

¹H-NMR (300 MHz/CDCl₃):

δ(ppm)=0.86 (6H, t), 1.26-1.29 (12H, m), 1.31 (24H, s), 1.52-1.53 (4H, m), 2.50 (4H, t), 6.92 (2H, d), 7.00 (2H, d), 7.08 (2H, t), 7.13 (2H, s), 7.77 (2H, d), 7.81-7.82 (4H, m).

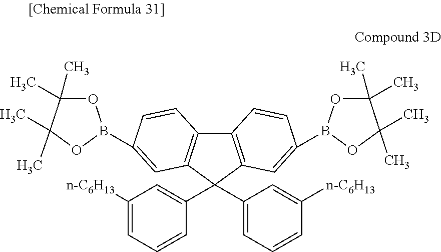

### Synthesis Example 9

### Synthesis of Compound 1E

To a solution prepared by adding chloroform to pyrene (8.8 parts by mass), a solution consisting of bromine (13.4 parts by mass) and chloroform was added dropwise over 7 hours at 20 to 25° C., and further stirred for 3 hours at 20 to 25° C. Subsequently, After the reaction solution was kept for three hours at 20 to 25° C., the precipitated solid was filtered, washed with chloroform, and dried under reduced pressure to obtain 9.7 parts by mass of solid A. Subsequently, the solid A (4.0 parts by mass) was added with toluene and stirred for 1 hour at 30 to 35° C., and kept at 5° C. for 18 hours. The precipitated solid was filtered, washed with methanol, and dried under reduced pressure. As a result, the compound 1E as a target compound was obtained in an amount of 2.66 parts by mass.

LC-MS (APPI-MS (posi)): 358 [M]⁺

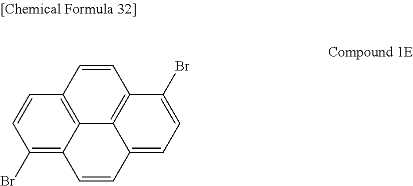 [SMILES: Brc1ccc2ccc3c(Br)ccc4ccc1c2c43]

### Synthesis Example 10

### Synthesis of Compound 41

A reaction vessel was made to be argon atmosphere, and 1-bromo-3,5-di-n-hexylbenzene (58.4 g) and tetrahydrofuran were added to prepare a homogeneous solution, which was then cooled to −75° C. To the solution, 2.5 M n-butyl lithium/hexane solution (71.2 mL) (1 mol equivalent compared to 1-bromo-3,5-di-n-hexylbenzene) was added dropwise for 1.5 hours at −75° C., and the solution was stirred for 1.5 hours at −70° C. Subsequently, a solution consisting of 2,7-dibromofluorenone (55.2 g) and tetrahydrofuran was added dropwise for 1 hour at −75° C. and, after heating to the room temperature, the reaction solution was stirred for 4 hours. Subsequently, the solution was cooled to 0° C., slowly added with acetone and 2 mol % aqueous solution of hydrochloric acid, and stirred, then raised in temperature to the room temperature followed by being kept at the room temperature. Subsequently, the reaction mixture was filtered, and the filtered solution was concentrated and stirred after adding hexane and water. After maintaining for a while for liquid separation, the aqueous layer was removed from the organic layer. Saturated brine was added to the organic layer followed by stirring. After maintaining for a while for liquid separation, the aqueous layer was removed from the organic layer. The organic layer was then added with magnesium sulfate and stirred. The filtered solution obtained by filtering was concentrated to obtain the compound 1I (30.2 g).

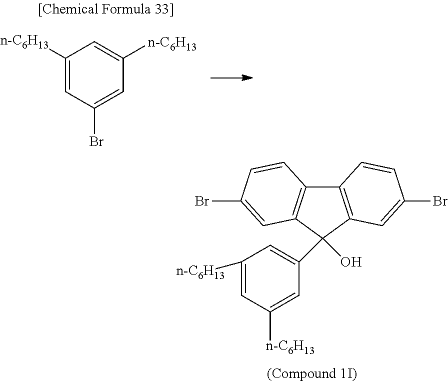

A reaction vessel was purged with argon, and added with the compound 1I (27.7 g) and trifluoroacetic acid (36 mL). A mixture solution of trimethylsilane (8.4 mL) and hexane (25 mL) was added dropwise to the solution over 30 minutes and stirred overnight at the room temperature. Subsequently, the reaction solution was cooled to 10° C., added with hexane and distilled water, and stirred for 1 hour. After maintaining for a while for liquid separation, the aqueous layer was removed from the organic layer. Water was added followed by stirring. After maintaining for a while for liquid separation, the aqueous layer was removed from the organic layer. The organic layer was then added with saturated brine and stirred. After maintaining for a while for liquid separation, the aqueous layer was removed from the organic layer. The organic layer was added with magnesium sulfate and stirred. The filtered solution obtained by filtering was concentrated. Subsequently, it was purified by silica gel column chromatography by using hexane and dichloromethane as a developing solvent. Then washing with methanol, the compound 21 (12.1 g) as a target compound was obtained.

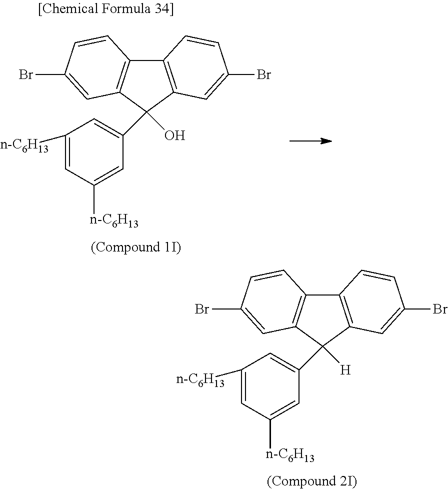

A reaction vessel was purged with argon, and added with the compound 21 (12.0 g), dimethyl sulfoxide (60 mL), water (2 mL) and potassium hydroxide (4.85 g) were added to a reaction vessel. To the solution, methyl iodide (4.1 mL) was added dropwise and stirred overnight at the room temperature. Subsequently, the reaction solution was added with hexane and distilled water at the room temperature and stirred for 1 hour. After maintaining for a while for liquid separation, the aqueous layer was removed from the organic layer. Water was added followed by stirring. After maintaining for a while for liquid separation, the aqueous layer was removed from the organic layer. Saturated brine was added to the organic layer followed by stirring. After maintaining for a while for liquid separation, the aqueous layer was removed from the organic layer. The organic layer was added with magnesium sulfate and the filtered solution obtained by filtration was concentrated. Subsequently, according to re-crystallization using methanol and butyl acetate, the compound 3I (4.3 g) as a target compound was obtained.

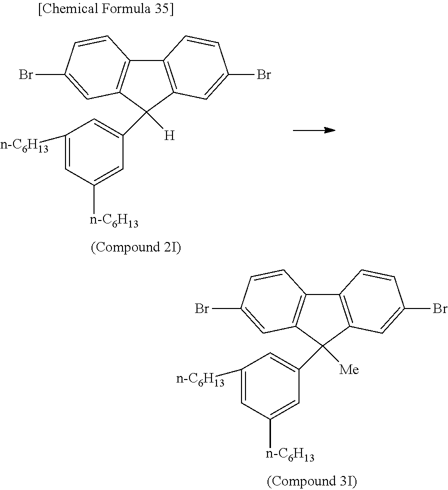

A reaction vessel was made to be argon atmosphere, and the compound 3I (4.2 g), bis(pinacolate)diborone (4,4,4′,4′,5,5,5′,5′-octamethyl-2,2′-bi-1,3,2-dioxaborolane) (4.0 g), 1,4-dioxane (45 mL), potassium acetate (4.2 g), 1,1′-bis(diphenylphosphino)ferrocene (dppf, 59 mg), and 1,1′-bis(diphenylphosphino)ferrocene palladium (II) dichloride methylene chloride complex (PdCl₂(dppf).CH₂Cl₂, 88 mg) were added and stirred at 100° C. for 20 hours. Subsequently, after cooling the obtained reaction mixture to the room temperature, it was filtered through a filter overlaid with Celite and silica gel, and the filtered solution was concentrated to remove the solvent. Subsequently, to a solution prepared by adding hexane, activated carbon was added and stirred for 1 hour at the temperature which allows reflux of hexane. The resulting mixture was cooled to the room temperature, filtered through a filter overlaid with Celite, and concentrated to remove the solvent. Thereafter, according to re-crystallization using toluene and methanol, the compound 4I as a target compound was obtained (3.9 g).

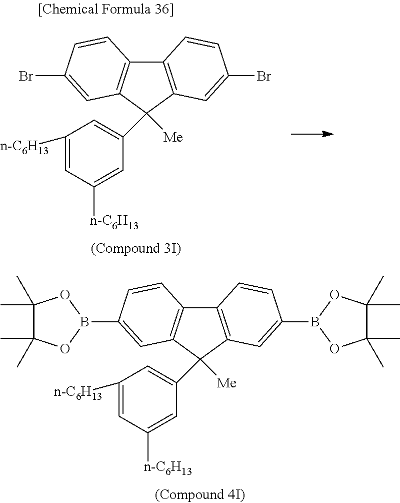

### Synthesis Example 11

### Synthesis of Compound 1T

A 100 mL three neck flask was replaced with nitrogen, and 2-ethylhexyl magnesium bromide (1.0 M diethyl ether solution, 25 mL, 25 mmol) was added followed by reflux. To the solution, a suspension in which 2-bromoanthracene (5.34 g, 20.8 mmol) and PdCl₂(dppf).CH₂Cl₂ (33 mg, 0.04 mmol) are suspended in 50 mL of anhydrous cyclopentyl methyl ether was added dropwise for 35 minutes. After reflux for 1 hour, it was cooled by placing it in an ice bath, and added dropwise with 2 M hydrochloric acid (5 mL). Then, 50 mL of toluene was added and liquid separation was carried out with 50 mL water and 30 mL water in order for washing. The aqueous layer was combined and re-extracted with toluene. The toluene layer was combined and washed with 30 mL saturated brine. It was then filtered through a glass filter applied with 20 g of silica gel and washed with toluene. The solvent was removed from the filtered solution by distillation to obtain a crude product in an amount of 7.45 g.

The crude product (5.40 g) was re-crystallized with isopropyl alcohol (54 mL). Herein, during naturally cooling after it was confirmed that the crude product was dissolved by heating, crystallization was observed at the inside temperature of 65° C., and the same temperature was kept for 2 hours. After that, the resulting solution was slowly cooled and naturally cooled to the room temperature. After filtration, washing with isopropyl alcohol was conducted. Re-crystallization using isopropyl alcohol was further repeated two times to obtain 3.81 g of 2-(2-ethylhexyl)anthracene (yield: 67.2%) as a white solid.

LC-MS (APPI positive): 291 ([M+H]⁺, exact mass=290)

¹H-NMR (300 MHz/CDCl₃):

δ(ppm)=0.87-0.94 (6H, m), 1.27-1.48 (8H, m), 1.68-1.75 (1H, m), 2.71 (2H, d), 7.29 (1H, d), 7.40-7.46 (2H, m), 7.71 (s, 1H), 7.91 (1H, d), 7.95-7.98 (2H, m), 8.32 (1H, s), 8.36 (1H, s).

¹³C-NMR (75 MHz/CDCl₃):

δ(ppm)=11.1, 14.4, 23.4, 25.9, 29.2, 32.8, 40.9, 41.0, 125.2, 125.5, 125.6, 126.2, 127.2, 128.2, 128.3, 128.4, 128.5, 131.0, 131.8, 132.2, 139.2.

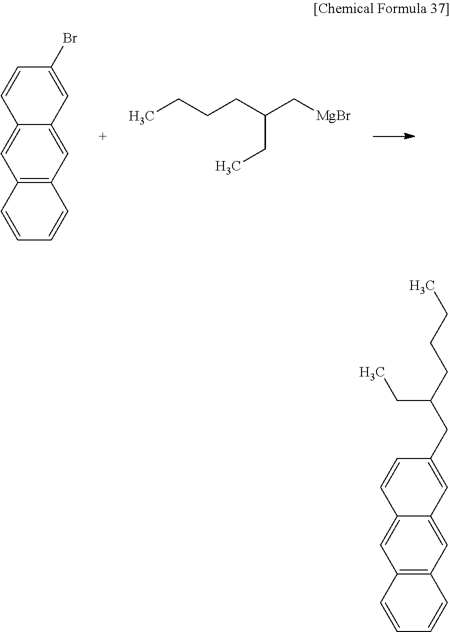

A 300 mL four neck flask was replaced with nitrogen, and added with 2-(2-ethylhexyl)anthracene (3.50 g, 12.1 mmol), which was then dissolved in 105 mL anhydrous dichloromethane. The reaction solution was cooled by placed in an ice bath, and then added dropwise with bromine (4.17 g, 26.1 mmol) for 20 minutes. After adding dropwise followed by stirring for 45 minutes, a 1% by mass aqueous solution of sodium thiosulfate was added dropwise over 5 minutes to quench the reaction. After liquid separation, the organic layer was extracted with 100 mL of chloroform. The organic layers were combined and washed with water. After filtration using a glass filter applied with 20 g of silica gel, it was washed with hexane. The filtered and washed solution was concentrated to obtain a crude product as a yellow viscous oil (5.47 g).

Purification by silica gel column chromatography (silica 120 g, developing solvent: hexane only) resulted 4.26 g of yellow viscous oil. Subsequently, 1 L of methanol was added and dissolved by heating. After maintaining it overnight, crystals were obtained. The resulting slurry solution was concentrated to about 150 mL and filtered to give 3.91 g of pale yellow solid.

The resulting solid was dissolved in hexane (50 mL), added with 1.00 g of activated carbon, and stirred for 1 hour. After filtration through a glass filter applied with 13 g of Celite and washing with hexane, the filtered and washed solution was concentrated. Then, isopropyl alcohol (100 mL) was added thereto followed by heating. After cooling to 35° C., seed crystals were added. After stirring, filtration, and washing with isopropyl alcohol, 2.76 g (yield: 51%) of 9,10-dibromo-2-(2-ethylhexyl)anthracene (the compound 1T) was obtained as a pale yellow solid.

¹H-NMR (300 MHz/CDCl₃):

δ(ppm)=0.86˜0.97 (6H, m), 1.20˜1.40 (8H, m), 1.72˜1.77 (1H, m), 2.78 (2H, d), 7.43 (1H, d), 7.55˜7.59 (2H, m), 8.28 (1H, s), 8.46 (1H, d), 8.51˜8.54 (2H, m).

¹³C-NMR (75 MHz/CDCl₃):

δ(ppm)=11.2, 14.5, 23.3, 25.9, 29.1, 32.7, 40.7, 40.9, 122.8, 123.6, 127.2, 127.3, 127.6, 128.3, 128.4, 128.5, 130.3, 130.8, 131.4, 141.7.

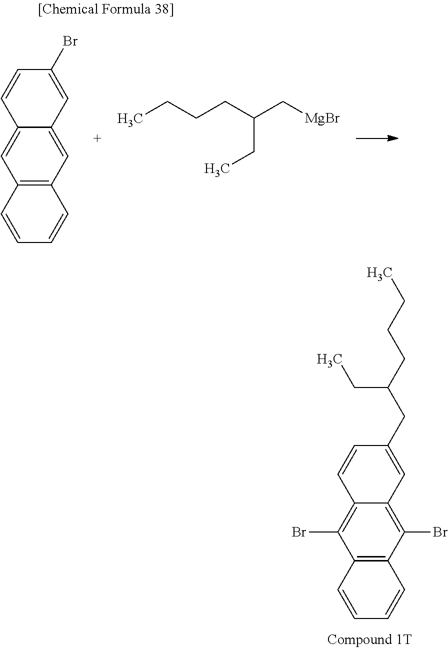

### Synthesis Example 12

### Synthesis of Compound 3P

Under nitrogen atmosphere, 1,5-naphthylbis(trifluoromethane sulfonate) (the compound 1P, 25.0 g) and [1,1′-bis(diphenylphosphino)ferrocene]palladium (II) dichloride dichloromethylene adduct (0.24 g), and tert-butyl methyl ether (410 mL) were placed and, at 10° C. or lower, 2-ethylhexyl magnesium bromide (1 mol/L diethyl ether solution, 173 mL) was added thereto dropwise followed by stirring for 4 hours at the room temperature. After the reaction was completed, the reaction solution was added to a mixture liquid of water and 2N hydrochloric acid, and the aqueous layer was extracted with ethyl acetate. Subsequently, the obtained organic layer was washed with an aqueous solution of sodium chloride. The washed organic layer was dried over magnesium sulfate and the solvent was distilled off under reduced pressure. The residues were purified by silica gel column chromatography (developing solvent: hexane) to obtain 21.3 g of compound 2P as a pale yellow oily matter.

MS (ESI, positive): [M⁺]353

¹H-NMR (300 MHz/CDCl₃):

δ(ppm)=0.75-1.00 (12H, m), 1.10-1.50 (16H, m), 1.69-1.85 (2H, m), 2.90-3.05 (4H, m), 7.24-7.38 (3H, m), 7.35-7.44 (3H, m), 7.90-7.95 (3H, m).

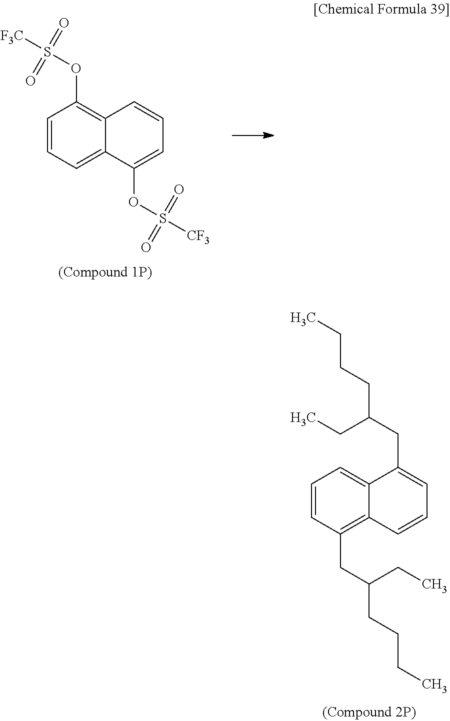

Under nitrogen atmosphere, a mixture of the compound 2P (21.3 g), bis(pinacolate)diborone (4,4,4′,4′,5,5,5′,5′-octamethyl-2,2′-bi-1,3,2-dioxaborolane) (46.0 g), bis(1,5-cyclooctadiene)di-μ-methoxy diiridium (I) (0.24 g) (manufactured by Aldrich), 4,4′-ditert-butyl-2,2′-dipyridyl (0.19 g) and dioxane (140 mL) was stirred at 100° C. for 3 hours. After cooling the resulting mixture, dioxane was distilled off under reduced pressure. The residues were added with methanol and the precipitated solid were collected by filtration followed by drying. The solid was dissolved in toluene and added with activated white clay, followed by stirring for 30 minutes at 60° C. After that, the mixture was hot-filtered using a filter pre-coated with silica gel, and the filtered liquid was concentrated under reduced pressure. The concentrated residues were added with methanol and dried to obtain the compound 3P as a white solid powder (28.0 g).

LC-MS (ESI, positive): [M⁺] 605

¹H-NMR (300 MHz/CDCl₃):

δ(ppm)=0.85-0.95 (12H, m), 1.24-1.50 (16H, m), 1.66-1.85 (2H, m), 2.90-3.18 (4H, m), 7.60 (2H, s), 8.47 (2H, s).

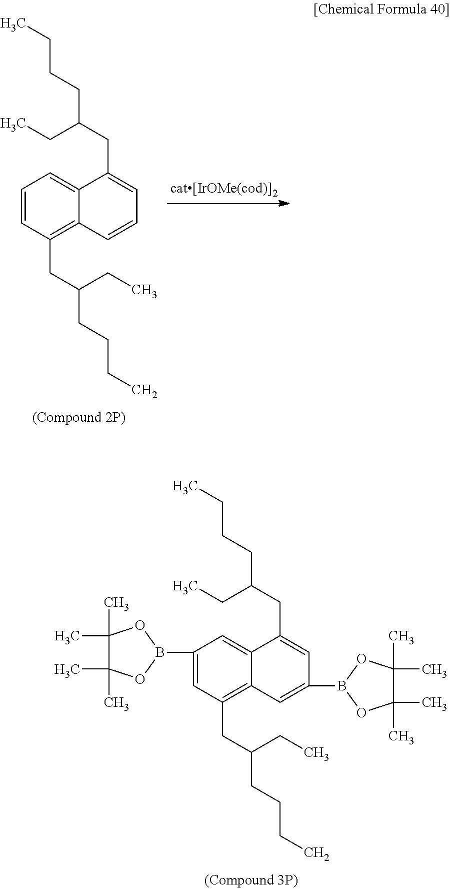

### Synthesis Example 13

### Synthesis of Compound 6M

To a three neck flask (5 L), magnesium (60.5 g, 2.485 mol), anhydrous diethyl ether (1500 mL), and 1,2-dibromoethane (1 mL, 0.0115 mol) were added, and 2-ethylhexyl bromide was slowly added thereto and stirred for 2 hours at 40° C. followed by cooling to the room temperature to prepare the solution A. Subsequently, to a 5 L three neck flask, 3,4-dibromothiophene (100 g, 0.4233 mol), bis(diphenylphosphinopropane) nickel (II), and anhydrous diethyl ether (1500 mL) were added to give a solution. The solution A was added thereto at the room temperature followed by stirring for 4 hours at the room temperature and further for 14 hours at 40° C. The obtained reaction solution was added to a mixture of 1.5 N aqueous solution of hydrochloric acid and ice and stirred to separate an resulting organic layer from an aqueous layer. The organic layer was washed with water (1000 mL) and saturated brine (1000 mL), concentrated, and solidified by drying. The obtained crude product was purified by silica gel column chromatography to obtain the compound 1M as a target compound (124 g, yield 97%).

¹H-NMR (300 MHz/CDCl₃):

δ(ppm)=0.96-1.03 (12H, m), 1.19-1.38 (16H, m), 1.55-1.60 (2H, m), 2.44 (4H, d), 6.86 (2H, s).

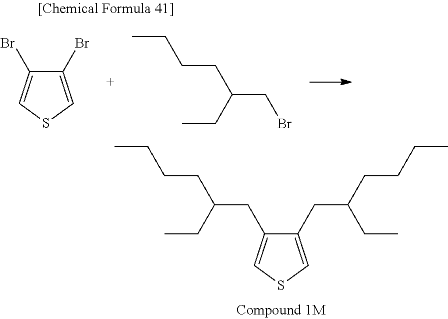

To a 5 L three neck flask, the compound 1M (124 g, 0.4018 mol) and dichloromethane (2.5 L) were added, and metachloroperbenzoic acid (m-CPBA) was slowly added thereto under stirring and further stirred for 14 hours at the room temperature. Subsequently, the mixture was added with dichloromethane (1 L) and washed twice with NaHSO₃ aqueous solution (500 mL), twice with NaHCO₃ aqueous solution (500 mL), and twice with saturated brine (500 mL). The organic layer was concentrated and solidified by drying to obtain a crude product. The crude product was purified by silica gel column chromatography to obtain the compound 2M as a target compound (80 g, yield 59%).

¹H-NMR (300 MHz/CDCl₃):

δ(ppm)=0.86-0.92 (12H, m), 1.27-1.39 (16H, m), 1.40-1.60 (2H, m), 2.22 (4H, d), 6.20 (2H, s).

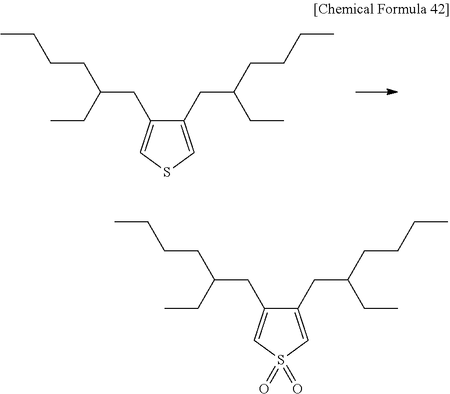

To a 2 L three neck flask, the compound 2M (80 g, 0.2349 mol), 1,4-naphthalene dione (63.15 g, 0.3993 mol), and dimethyl sulfoxide (1600 mL) were added and stirred for 60 hours at 110° C. Subsequently, the obtained reaction solution was slowly added to water (1 L) at the room temperature, added with dichloromethane (2 L), and stirred. The resulting organic layer was separated from the aqueous layer. The organic layer was washed twice with water (500 mL) and once with saturated brine (1000 mL), concentrated and solidified by drying to obtain a crude product. Subsequently the crude product was purified by silica gel column chromatography to obtain the compound 3M as a target compound (51 g, yield 49%).

¹H-NMR (300 MHz/CDCl₃):

δ(ppm)=0.92-0.99 (12H, m), 1.26-1.39 (16H, m), 1.66-1.68 (2H, m), 2.71 (4H, d), 7.78 (2H, dd), 8.05 (2H, s), 8.31 (2H, dd).

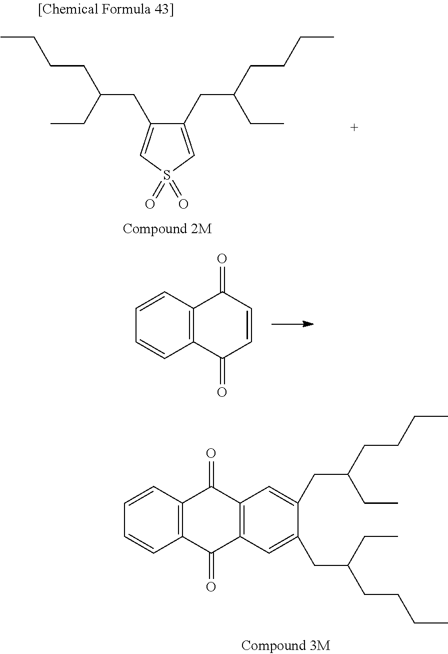 [SMILES: CCCCC(CC)CC1=CS(=O)(=O)C=C1CC(CC)CCCC ; O=C1C=CC(=O)c2ccccc21 ; CCCCC(CC)Cc1cc2c(cc1CC(CC)CCCC)C(=O)c1ccccc1C2=O]

To a solution consisting of 1,4-dibromobenzene (31.20 g, 132 mmol) and anhydrous diethyl ether (279 mL), 1.67 M (n-butyl lithium/n-hexane solution (79.2 mL, 132 mmol) was added dropwise at −78° C. followed by stirring for 1 hour at the same temperature to prepare a solution B. Subsequently, to a solution consisting of the compound 3M (14.31 g, 33 mmol) and anhydrous diethyl ether (28 mL), the solution B was added dropwise at −78° C. followed by stirring for 1 hour at the same temperature. Subsequently, it was stirred at the room temperature for 3 hours and stirred after added with water (140 mL) at 0° C. Then, ethyl acetate was added followed by stirring, and the resulting organic layer was separated from an aqueous layer. The obtained organic layer was concentrated and solidified by drying to obtain the compound 4M as a target compound (32.8 g).

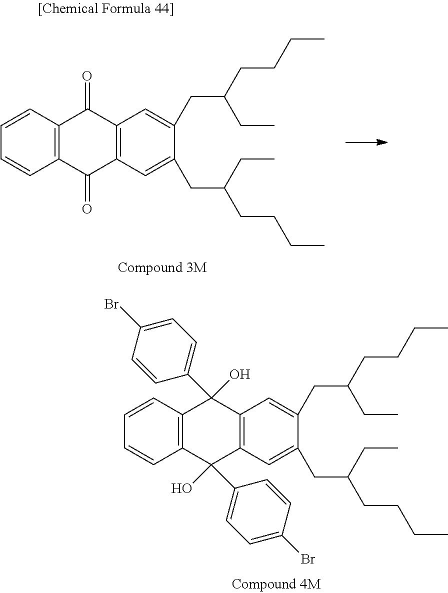 [SMILES: CCCCC(CC)Cc1cc2c(cc1CC(CC)CCCC)C(=O)c1ccccc1C2=O ; CCCCC(CC)Cc1cc2c(cc1CC(CC)CCCC)C(O)(c1ccc(Br)cc1)c1ccccc1C2(O)c1ccc(Br)cc1]

The compound 4M (24.69 g), acetic acid (165 mL), potassium iodide (14.27 g) and NaHPO₂. H₂O (31.54 g) were stirred at 125° C. for 3 hours. The obtained reaction solution was poured over ice water, stirred, further added with toluene, and stirred. The resulting organic layer was separated from an aqueous layer. The organic layer was concentrated, solidified by drying, and purified by silica gel column chromatography to obtain the compound 5M as a target compound was obtained (21.83 g).

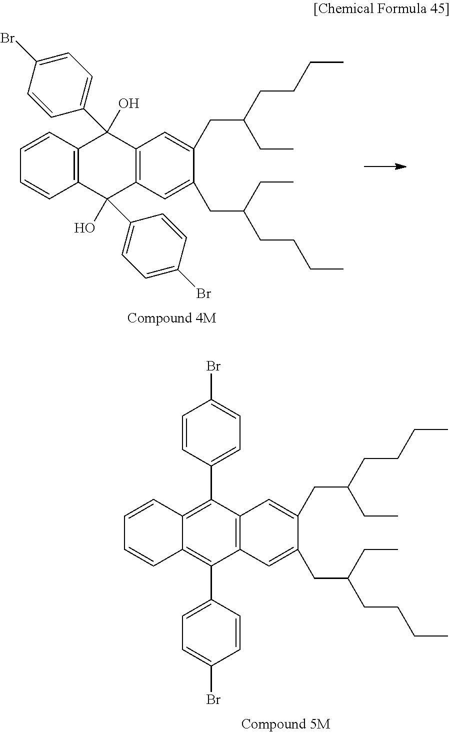 [SMILES: CCCCC(CC)Cc1cc2c(cc1CC(CC)CCCC)C(O)(c1ccc(Br)cc1)c1ccccc1C2(O)c1ccc(Br)cc1 ; CCCCC(CC)Cc1cc2c(-c3ccc(Br)cc3)c3ccccc3c(-c3ccc(Br)cc3)c2cc1CC(CC)CCCC]

Under inert gas atmosphere, the compound 5M (1.70 g, 2.39 mmol), bis(pinacolate)diborone (4,4,4′,4′,5,5,5′,5′-octamethyl-2,2′-bi-1,3,2-dioxaborolane) (1.33 g, 5.25 mmol), 1,1-bis(diphenylphosphino)ferrocene palladium (II) dichloride dichloromethane complex (Pd(dppf).CH₂Cl₂, 38 mg, 0.05 mmol), 1,1-bis(diphenylphosphino)ferrocene (30 mg, 0.05 mmol), anhydrous 1,4-dioxane (20 mL) and potassium acetate (1.4 g, 14.31 mmol) were added and stirred under reflux for 6 hours. The resulting mixture was brought back to the room temperature, added with water and toluene, and stirred. The resulting organic layer is separated from an aqueous layer, concentrated, and solidified by drying to obtain a crude product. The crude product was added with hexane (100 mL) and activated carbon (0.3 g), stirred for 30 minutes at 40° C., and filtered through a filter overlaid with Celite. By concentration and solidification by drying, a solid was obtained. The solid was re-crystallized with hexane and the compound 6M as a target compound was obtained (0.43 g).

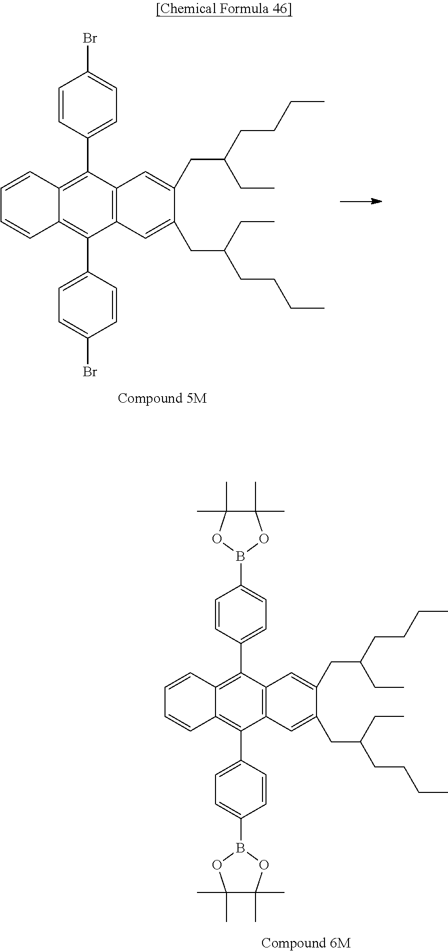 [SMILES: CCCCC(CC)Cc1cc2c(-c3ccc(Br)cc3)c3ccccc3c(-c3ccc(Br)cc3)c2cc1CC(CC)CCCC ; CCCCC(CC)Cc1cc2c(-c3ccc(B4OC(C)(C)C(C)(C)O4)cc3)c3ccccc3c(-c3ccc(B4OC(C)(C)C(C)(C)O4)cc3)c2cc1CC(CC)CCCC]

### Synthesis Example 14

### Synthesis of Compound 5N

First, the compound 2N was synthesized as described below by using the compound 1N.

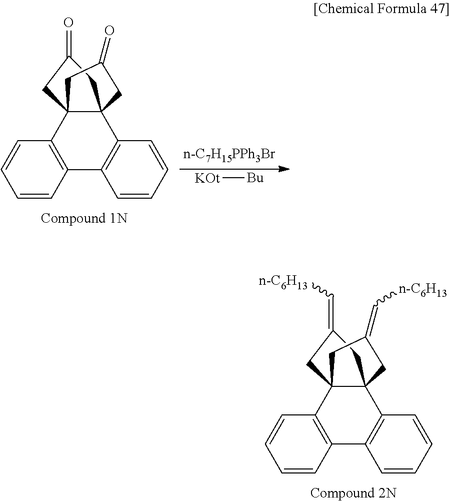

In the formula, broken lines indicate that the compound with the broken lines is a mixture of geometric isomers.

To a four neck flask (1 L) equipped with a stirrer, heptyltriphenyl phosphonium bromide (115.0 g) was added and the gas within the flask was replaced with argon. Toluene (375 g) was added to the flask and cooled to 5° C. or lower. Potassium tert-butoxide (29.2 g) was added, heated to the room temperature, and stirred while keeping the room temperature for 3 hours. To the red slurry generated in the reaction solution, the compound 1N (15.0 g) was added and stirred for 12 hours while keeping the room temperature. To the reaction solution, acetic acid (10.0 g) was added, stirred for 15 minutes, and filtered. The filtered residues were washed several times with toluene. The filtered solution obtained after several washings were combined, concentrated, and added with hexane. As a result, slurry was generated, which was then stirred for 1 hour at 50° C. while keeping the temperature. The resulting mixture was cooled to the room temperature and filtered. The filtered residues were washed several times with hexane, and the filtered solution obtained after several times were combined and concentrated to obtain a crude product. The crude product was purified by using a silica gel column (developing solvent: hexane) to obtain the compound 2N as a colorless and transparent liquid (21.7 g).

LC-MS (ESI, positive): [M+K]⁺491

¹H-NMR (300 MHz/CDCl₃):

δ(ppm)=0.87 (6H, t), 1.20-1.36 (16H, m), 1.82-1.97 (4H, m), 2.57-2.81 (8H, m), 5.20 (2H, br), 7.23-7.32 (4H, m), 7.41-7.48 (2H, m), 7.87-7.90 (2H, m).

Subsequently, the compound 3N was synthesized as described below by using the compound 2N.

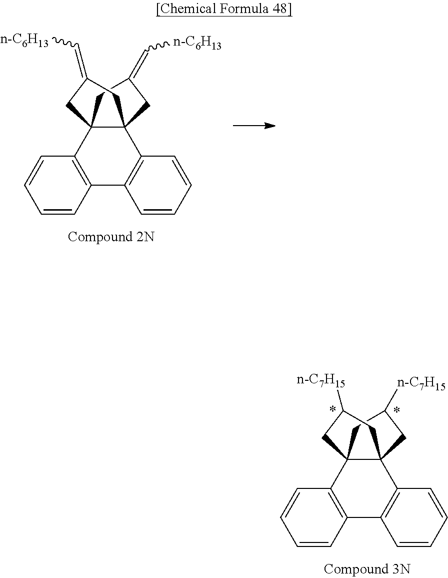

In the formula, broken lines indicate that the compound with the broken lines is a mixture of geometric isomers, further, * in the formula means that the carbon atom bearing the symbol is an asymmetrical carbon atom.

To a 1 L four neck flask equipped with a stirrer, the compound 2N (21.7 g) was added and ethyl acetate (152.4 g) and ethanol (151.6 g) were further added. The gas within the flask was replaced with nitrogen. 5% by mass Pd/C (containing moisture in an amount of about 50% by mass) (4.3 g) was added and the gas within the flask was replaced with hydrogen. Under hydrogen atmosphere, the mixture was stirred for 27 hours at 40° C. while keeping the temperature. The obtained mixture was cooled to the room temperature and filtered through a filter precoated with Celite. The residues were washed several times with ethyl acetate, and the filtered solution obtained after several times were combined and concentrated to obtain a crude product. The crude product was purified by using a silica gel column (developing solvent: hexane) to obtain the compound 3N as a colorless and transparent liquid (21.7 g).

LC-MS (APPI, positive): [M]⁺456

¹H-NMR (300 MHz/CDCl₃):

δ(ppm)=0.66-0.98 (6H, m), 1.00-2.22 (34H, m), 7.13-7.50 (6H, m), 7.80-7.98 (2H, m).

Subsequently, the compound 4N was synthesized as described below by using the compound 3N.

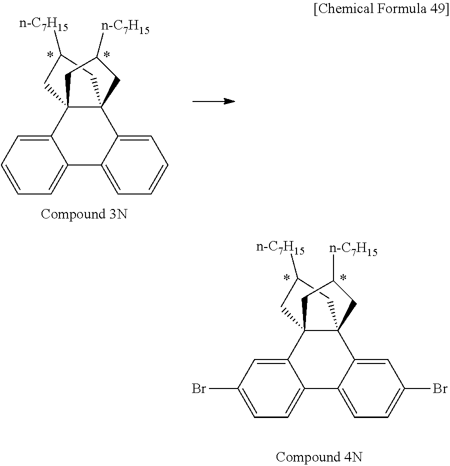

In the formula, * means that the carbon atom bearing the symbol is an asymmetrical carbon atom.

To a four neck flask (500 mL) equipped with a stirrer, the compound 3N (21.7 g), chloroform (261.1 g) and trifluoroacetic acid (44 g) were added and the gas within the flask was replaced with argon. Then, the four neck flask was completely covered against light and a mixture of bromine (19.0 g) and chloroform (65.3 g) was added dropwise to the flask over 15 minutes at the room temperature, and the temperature was raised to 35° C. thereafter.

After stirring for 7 hours at 35° C. while keeping the temperature, it was cooled to 15° C. or less. The reaction solution was added with 10% by mass aqueous solution of sodium sulfite (109 g) and the temperature was raised to the room temperature. The aqueous layer was separated from the reaction solution and the organic layer was washed with water, 5% by mass aqueous solution of sodium hydrogen carbonate, and water in order. The organic layer obtained was dried over magnesium sulfate and filtered. The filtered solution was concentrated to obtain a crude product. The crude product was re-crystallized twice with a mixture of ethanol and hexane. The obtained solid was dissolved in hexane, and purified by using a silica gel column (developing solvent: hexane). To the resulting hexane solution, activated carbon (2.1 g) was added and stirred for 1 hour at 45° C. while keeping the temperature. The obtained mixture was cooled to the room temperature, filtered through a filter precoated with Celite, and the residues were washed several times with hexane. The filtered solutions obtained after several times were combined and partially concentrated to obtain a hexane solution. The hexane solution was added with ethanol and the compound 4N as a white solid (18.8 g). was obtained by re-crystallization.

LC-MS (ESI, negative): [M+Cl]⁻ 648

¹H-NMR (300 MHz/CDCl₃):

δ(ppm)=0.66-0.98 (6H, m), 1.00-2.20 (34H, m), 7.22-7.78 (6H, m).

Based on the ¹H-NMR measurement result, it was found that the compound 4N is a mixture of isomers with different stereochemistry (4a:4b:4c=51:39:10) (molar ratio).

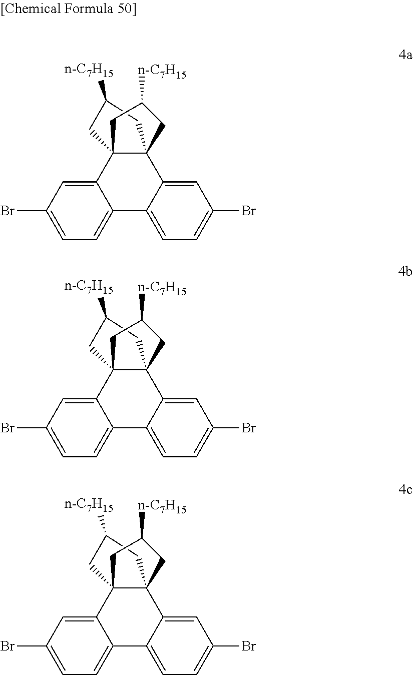

Subsequently, the compound 5N was synthesized as described below by using the compound 4N.

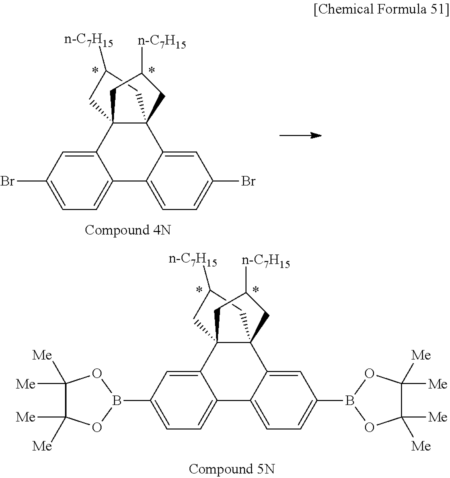

In the formula, * means that the carbon atom bearing the symbol is an asymmetrical carbon atom.

To a 200 mL four neck flask, the compound 4N (9.70 g), bis(pinacolate)diborone (8.82 g) and potassium acetate (9.25 g) were added and the gas with the flask was replaced with nitrogen. 1,4-dioxane (95 mL), palladium chloride (diphenylphosphinoferrocene)dichloromethane adduct (PdCl₂(dppf) (CH₂Cl₂) (0.195 g) and diphenylphosphinoferrocene (dppf) (0.131 g) were added thereto and stirred for 7 hours at 105° C. The resulting solution was cooled to the room temperature, and filtered through a funnel precoated with Celite. The filtered solution was concentrated under reduced pressure and the obtained concentrated was dissolved in hexane, added with activated carbon, and stirred for 1 hour at 40° C. with heating. The obtained mixture was cooled to the room temperature, and filtered through a funnel precoated with Celite. The solid obtained after concentration under reduced pressure was re-crystallized with a mixture solvent of toluene and acetonitrile, and as a result, the compound 5N was obtained as a white solid (9.0 g).

LC-MS (ESI, positive, added with KCl): [M+K]⁺747

### Synthesis Example 15

### Synthesis of Compound 2Q

The compound 1Q (3.00 g) described below, bis(pinacolate)diborone (2.84 g), potassium acetate (2.99 g), 1,4-dioxane (30 g), palladium chloride (diphenylphosphinoferrocene)dichloromethane adduct (PdCl₂(dppf) (CH₂Cl₂) (83 mg) and diphenylphosphinoferrocene (dppf) (56 mg) were stirred at 103° C. for 6 hours. The resulting solution was cooled to the room temperature, and filtered through a funnel overlaid with Celite. The filtered solution was concentrated under reduced pressure and the obtained concentrated was dissolved in hexane, added with activated carbon, and stirred for 1 hour at 40° C. with heating. The obtained mixture was cooled to the room temperature, and filtered through a funnel overlaid with Celite. The solid obtained after concentration under reduced pressure was re-crystallized with a mixture solvent of toluene and acetonitrile, and as a result, the compound 2Q was obtained as a white solid (2.6 g).

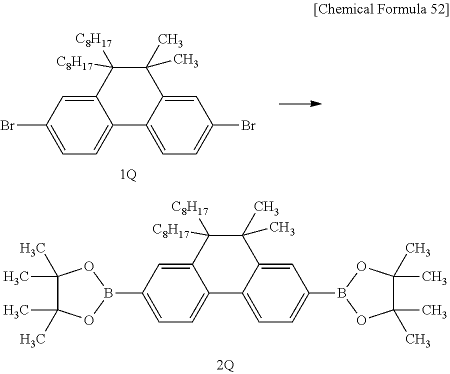

### Production of Polymers

### Polymerization Example 1

### Synthesis of Polymer 1

Under inert atmosphere, the compound 3C (13.380 g, 17.45 mmol), the compound (F8BE: 3.702 g, 6.98 mmol) represented by the following formula,

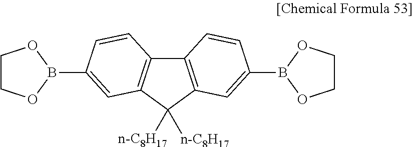

the compound 2D (16.121 g, 24.93 mmol), dichlorobis(triphenylphosphine) palladium (17.5 mg), and toluene (478 mL) were mixed and heated to 100° C. 20% by mass aqueous solution of tetraethylammonium hydroxide (83.7 g) was added dropwise to the reaction solution, which was then refluxed for 4.5 hours. After the reaction, phenylboronic acid (300 mg) and dichlorobis(triphenylphosphine) palladium (17.5 mg) were added and reflux was continued for further 14 hours. Next, an aqueous solution of sodium diethyl dithiacarbamate was added followed by stirring at 80° C. for 2 hours. After cooling the mixture obtained, washing was performed twice with water, twice with 3% by mass aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give 14.75 g of the polymer 1. The polystyrene equivalent number average molecular weight of the polymer 1 was 6.1×10⁴, and the polystyrene equivalent weight average molecular weight was 2.1×10⁵.

The polymer 1 was a copolymer having a constitutional unit represented by the following formula:

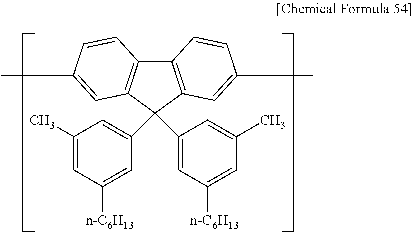

a constitutional unit represented by the following formula; and

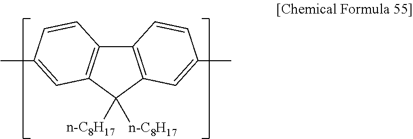

a constitutional unit represented by the following formula;

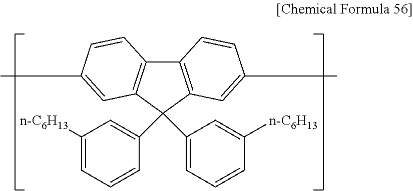

in a molar ratio of 36:14:50, as the theoretical value calculated from the amounts of the used starting materials.

### Polymerization Example 2

### Synthesis of Polymer 2 That is to be Polymerization Example 1

Under inert atmosphere, the compound 3A (2.218 g, 3.00 mmol), the compound (the compound 1F: 1.008 g, 3.02 mmol) represented by the following formula,

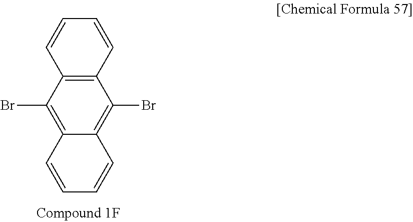 [SMILES: Brc1c2ccccc2c(Br)c2ccccc12]

dichlorobis (triphenylphosphine) palladium (2.1 mg), and toluene (75 mL) were mixed heated to 105° C. 20% by mass of an aqueous tetraethylammonium hydroxide solution (10 mL) was added dropwise to the reaction solution, which was then refluxed for 5.5 hours. After the reaction, phenylboronic acid (36.6 mg), dichlorobis (triphenylphosphine) palladium (2.1 mg), and 20% by mass of an aqueous tetraethylammonium hydroxide solution (10 mL) were added and was refluxed for 14 hours. Next, an aqueous solution of sodium diethyl dithiacarbamate was added thereto followed by stirring at 80° C. for 2 hours. After cooling the mixture obtained, washing was performed twice with water, twice with 3% by mass aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give 1.33 g of the polymer 2. The polystyrene equivalent number average molecular weight of the polymer 2 (polymer compound) was 1.4×10⁵, and the polystyrene equivalent weight average molecular weight was 3.2×10⁵.

The polymer 2 was an alternating copolymer having a constitutional unit represented by the following formula, which corresponds to Z:

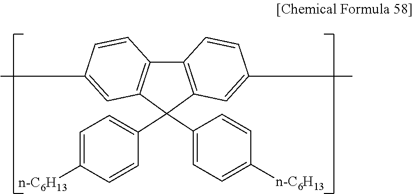

and a constitutional unit represented by the following formula, which corresponds to Y:

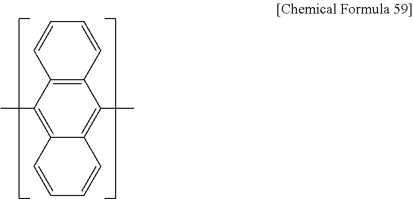

in a molar ratio of 50:50, as the theoretical value calculated from the amounts of the used starting materials, in which the copolymer consists of the constitutional sequence (n=1) represented by the formula (1) only.

### Polymerization Example 3

### Synthesis of Polymer 3 that is to be Polymerization Working Example 2

Under inert atmosphere, the compound 3B (2.694 g, 2.97 mmol), the compound 1H (1.008 g, 3.00 mmol), phenylboronic acid (7.3 mg), dichlorobis(triphenylphosphine) palladium (2.1 mg), and toluene (71 mL) were mixed and heated to 105° C. 20% by mass aqueous tetraethylammonium hydroxide solution (10 mL) was added dropwise to the reaction solution, which was then refluxed for 6.5 hours. After the reaction, phenylboronic acid (36.5 mg), dichlorobis(triphenylphosphine) palladium (2.1 mg), and 20% by mass aqueous tetraethylammonium hydroxide solution (10 mL) were added and refluxed for further 16.5 hours. Next, an aqueous sodium diethyl dithiacarbamate solution was added thereto followed by stirring at 80° C. for 2 hours. After cooling the mixture obtained, washing was performed twice with water, twice with 3% by mass aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give 2.13 g of the polymer 3 (polymer compound). The polystyrene equivalent number average molecular weight of the polymer 3 was 2.9×10⁴, and the polystyrene equivalent weight average molecular weight was 8.6×10⁴.

The polymer 3 was an alternating copolymer having a constitutional unit represented by the following formula, which corresponds to Z:

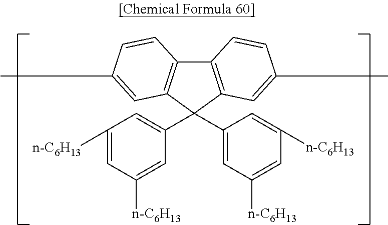

and a constitutional unit represented by the following formula, which corresponds to Y:

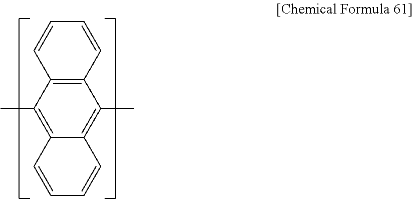

in a molar ratio of 50:50, as the theoretical value calculated from the amounts of the used starting materials, in which the copolymer consists of the constitutional sequence (n=1) represented by the formula (1) only.

### Polymerization Example 4

### Synthesis of Polymer 4 that is to be Polymerization Working Example 3

Under inert atmosphere, the compound 3C (2.300 g, 3.00 mmol), the compound 1H (1.008 g, 3.00 mmol), dichlorobis(triphenylphosphine) palladium (2.1 mg), and toluene (71 mL) were mixed and heated to 105° C. 20% by mass aqueous tetraethylammonium hydroxide solution (10 mL) was added dropwise to the reaction solution, which was then refluxed for 3.5 hours. After the reaction, phenylboronic acid (37.0 mg), dichlorobis(triphenylphosphine) palladium (2.1 mg), and 20% by mass aqueous tetraethylammonium hydroxide solution (10 mL) were added and refluxed for 16 hours. Next, an aqueous solution of sodium diethyl dithiacarbamate was added thereto followed by stirring at 80° C. for 2 hours. After cooling the mixture obtained, washing was performed twice with water, twice with 3% by mass aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give 1.50 g of the polymer 6 (polymer compound). The polystyrene equivalent number average molecular weight of the polymer 6 was 1.3×10⁵, and the polystyrene equivalent weight average molecular weight was 3.6×10⁵.

The polymer 4 was an alternating copolymer having a constitutional unit represented by the following formula, which corresponds to Z:

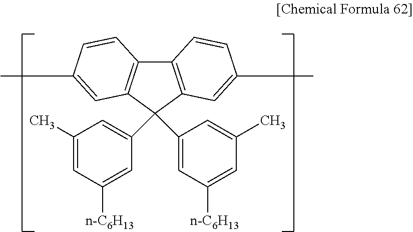

and a constitutional unit represented by the following formula, which corresponds to Y:

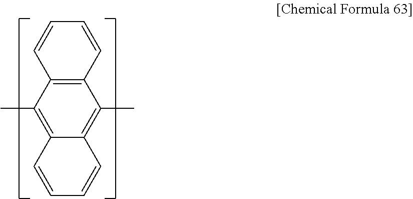

in a molar ratio of 50:50, as the theoretical value calculated from the amounts of the used starting materials, in which the copolymer consists of the constitutional sequence (n=1) represented by the formula (1) only.

### Polymerization Example 5

### Synthesis of Polymer 5 that is to be Polymerization Working Example 4

Under inert atmosphere, the compound 3B (1.785 g, 1.97 mmol), the compound 1E (0.720 g, 2.00 mmol), dichlorobis (triphenylphosphine) palladium (1.4 mg), and toluene (47 mL) were mixed and heated to 105° C. 20% by mass aqueous tetraethylammonium hydroxide solution (7 mL) was added dropwise to the reaction solution, which was then refluxed for 4 hours. After the reaction, phenylboronic acid (24.4 mg), dichlorobis (triphenylphosphine) palladium (1.3 mg), and 20% by mass aqueous tetraethylammonium hydroxide solution (7 mL) were added and refluxed for 19 hours. Next, an aqueous sodium diethyl dithiacarbamate solution was added thereto followed by stirring at 80° C. for 2 hours. After cooling the mixture obtained, washing was performed twice with water, twice with 3% by mass aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give 1.41 g of the polymer 5 (polymer compound). The polystyrene equivalent number average molecular weight of the polymer 5 was 6.1×10⁴, and the polystyrene equivalent weight average molecular weight was 1.5×10⁵.

The polymer 5 was an alternating copolymer having a constitutional unit represented by the following formula, which corresponds to Z:

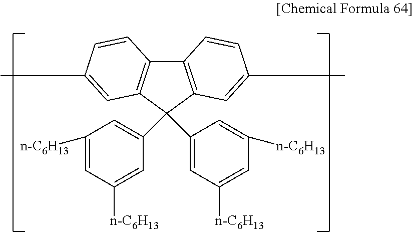

and a constitutional unit represented by the following formula, which corresponds to Y:

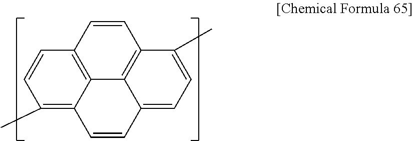

in a molar ratio of 50:50, as the theoretical value calculated from the amounts of the used starting materials, in which the copolymer consists of the constitutional sequence (n=1) represented by the formula (1) only.

### Polymerization Example 6

### Synthesis of Polymer 6 that is to be Polymerization Working Example 5

Under inert atmosphere, the compound 3B (1.805 g, 1.99 mmol), the compound 1J (1.024 g, 2.00 mmol) represented by the following formula,

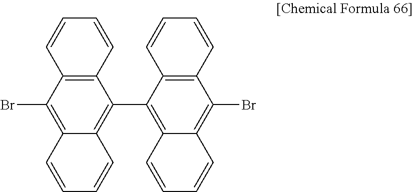 [SMILES: Brc1c2ccccc2c(-c2c3ccccc3c(Br)c3ccccc23)c2ccccc12]

acetic acid palladium (0.5 mg), tris(tri-o-methoxyphenylphosphine) (2.8 mg), and toluene (60 mL) were mixed and heated to 105° C. 20% by mass aqueous tetraethylammonium hydroxide solution (7 mL) was added dropwise to the reaction solution, which was then refluxed for 3 hours. After the reaction, phenylboronic acid (24.4 mg), acetic acid palladium (0.5 mg), tris(tri-o-methoxyphenylphosphine) (2.8 mg), and 20% by mass aqueous tetraethylammonium hydroxide solution (7 mL) were added and refluxed for further 18.5 hours. Next, an aqueous sodium diethyl dithiacarbamate solution was added followed by stirring at 80° C. for 2 hours. After cooling the mixture obtained, washing was performed twice with water, twice with 3% by mass aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give 0.87 g of the polymer 6 (polymer compound). The polystyrene equivalent number average molecular weight of the polymer 6 was 5.6×10⁴, and the polystyrene equivalent weight average molecular weight was 3.1×10⁵.

The polymer 6 was an alternating copolymer having a constitutional unit represented by the following formula, which corresponds to Z:

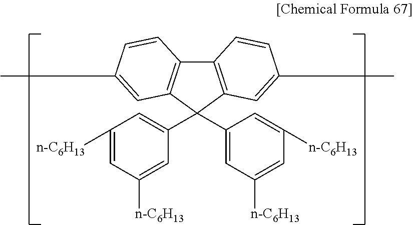

and a constitutional unit represented by the following formula, which corresponds to Y:

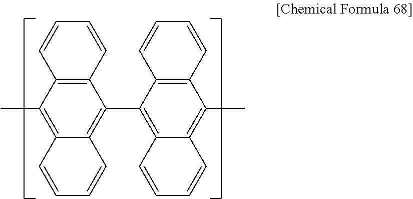

in a molar ratio of 50:50, as the theoretical value calculated from the amounts of the used starting materials, in which the copolymer consists of the constitutional sequence (n=2) represented by the formula (1) only.

### Polymerization Example 7

### Synthesis of Polymer 7

Under inert atmosphere, the compound 3B (2.688 g, 2.96 mmol), the compound 1K (1.640 g, 1.80 mmol) represented by the following formula:

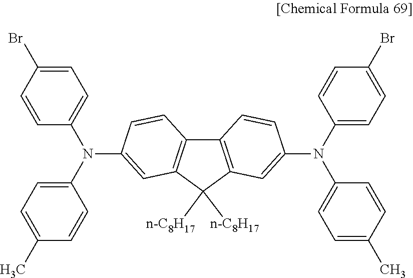

the compound F8BR: 0.411 g, 0.75 mmol) represented by the following formula; and

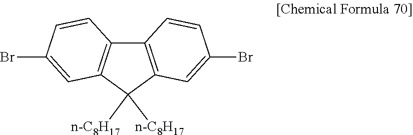

the compound 1L (0.238 g, 0.45 mmol) represented by the following formula,

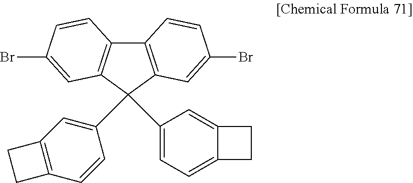 [SMILES: Brc1ccc2c(c1)C(c1ccc3c(c1)CC3)(c1ccc3c(c1)CC3)c1cc(Br)ccc1-2]

dichlorobis(triphenylphosphine) palladium (2.1 mg), and toluene (62 mL) were mixed and heated to 105° C. 20% by mass an aqueous tetraethylammonium hydroxide solution (10 mL) was added dropwise to the reaction solution, which was then refluxed for 3 hours and 20 minutes. After the reaction, phenylboronic acid (36.8 mg), dichlorobis(triphenylphosphine) palladium (2.1 mg), and 20% by mass an aqueous tetraethylammonium hydroxide solution (10 mL) were added and refluxed for 16 hours. Next, aqueous solution of sodium diethyl dithiacarbamate was added followed by stirring at 80° C. for 2 hours. After cooling the mixture obtained, washing was performed twice with water, twice with a 3% by mass of an aqueous acetic acid solution, and twice with water, and the obtained solution was added dropwise to methanol and filtered to obtain a precipitate. The precipitate was dissolved in toluene and passed through an alumina column and a silica gel column in that order for purification. The obtained solution was added dropwise to methanol and stirred, and then the resulting precipitate was filtered and dried to give the polymer 7 (3.12 g). The polystyrene equivalent number average molecular weight of the polymer 7 was 8.0×10⁴, and the polystyrene equivalent weight average molecular weight was 2.6×10⁵.

The polymer 7 was a copolymer having a constitutional unit represented by the following formula:

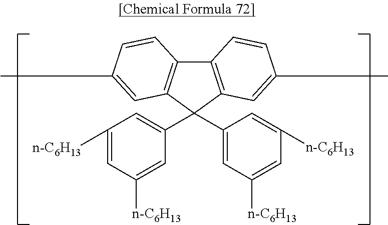

a constitutional unit represented by the following formula;

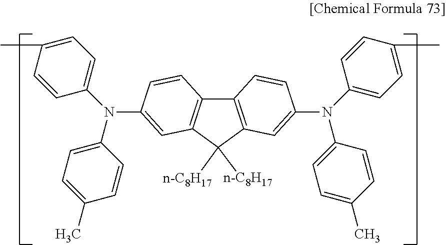

a constitutional unit represented by the following formula; and

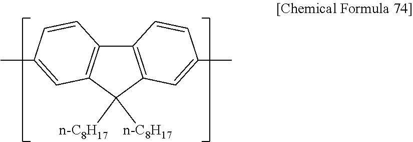

and a constitutional unit represented by the following formula:

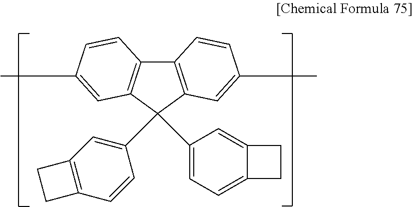

in a molar ratio of 50:30:12.5:7.5, as the theoretical value calculated from the amounts of the used starting materials.

### Polymerization Example 8

### Synthesis of Polymer 8 that is to be Polymerization Working Example 6

Under inert atmosphere, the compound 4I (1.725 g, 2.55 mmol), the compound 1H (0.8401 g, 2.50 mmol), dichlorobis(tris-o-methoxyphenylphosphine) palladium (2.2 mg), and toluene (39 mL) were mixed and heated to 100° C. 20% by mass aqueous tetraethylammonium hydroxide solution (8.3 mL) was added dropwise to the reaction solution, which was then refluxed for 2.5 hours. After the reaction, phenylboronic acid (30.5 mg), dichlorobis(tris-o-methoxyphenylphosphine) palladium (2.2 mg), and 20% by mass aqueous tetraethylammonium hydroxide solution (8.3 mL) were added and refluxed for 12 hours. Next, an aqueous sodium diethyl dithiacarbamate solution was added thereto followed by stirring at 80° C. for 2 hours. After cooling the mixture obtained, washing was performed twice with water (18 mL), twice with 3% by mass aqueous acetic acid solution (18 mL), and twice with water (18 mL), and the obtained solution was added dropwise to methanol (253 mL) and filtered to obtain a precipitate. The precipitate was dissolved in toluene (52 mL) and passed through an alumina column and a silica gel column in that order for purification. The obtained solution was added dropwise to methanol (253 mL) and stirred, and then the resulting precipitate was filtered and dried to give 6.4 g of the polymer 15 (polymer compound). The polystyrene equivalent number average molecular weight of the polymer 15 was 1.2×10⁵, and the polystyrene equivalent weight average molecular weight was 4.8×10⁵.

The polymer 8 was an alternating copolymer having a constitutional unit represented by the following formula, which corresponds to Z:

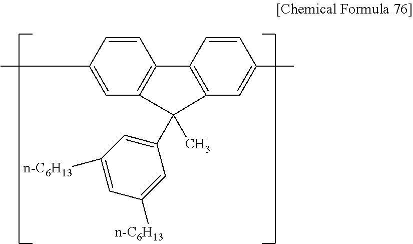

and a constitutional unit represented by the following formula, which corresponds to Y:

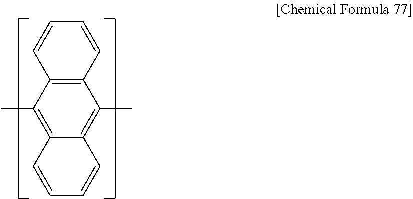

in a molar ratio of 50:50, as the theoretical value calculated from the amounts of the used starting materials, in which the copolymer consists of the constitutional sequence (n=1) represented by the formula (1) only.

### Polymerization Example 9

### Synthesis of Polymer 9 that is Polymerization Working Example 7

Under inert atmosphere, the compound 4I (1.999 g, 3.0 mmol), the compound 1T (1.345 g, 3.0 mmol), dichlorobis (tris-o-methoxyphenylphosphine) palladium (2.7 mg), and toluene (55 mL) were mixed and heated to 100° C. 20% by mass aqueous tetraethylammonium hydroxide solution (10 mL) was added dropwise to the reaction solution, which was then refluxed for 6.5 hours. After the reaction, phenylboronic acid (37 mg), dichlorobis(tris-o-methoxyphenylphosphine) palladium (2.7 mg), and 20% by mass aqueous tetraethylammonium hydroxide solution (10 mL) were added thereto and refluxed for 12 hours. Next, an aqueous solution of sodium diethyl dithiacarbamate was added thereto and followed by stirring at 80° C. for 2 hours. After cooling the mixture obtained, washing was performed twice with water (30 mL), twice with a 3% by mass of an aqueous acetic acid solution (30 mL), and twice with water (30 mL), and the obtained solution was added dropwise to methanol and filtered to obtain a precipitate. The precipitate was dissolved in toluene (123 mL) and passed through an alumina column and a silica gel column in that order for purification. The obtained solution was added dropwise to methanol (360 mL) and stirred, and then the resulting precipitate was filtered and dried to give the polymer 9 (polymer compound: 1.37 g). The polystyrene equivalent number average molecular weight of the polymer 9 was 9.4×10⁴, and the polystyrene equivalent weight average molecular weight was 2.6×10⁵.

The polymer 9 was an alternating copolymer having a constitutional unit represented by the following formula, which corresponds to Z:

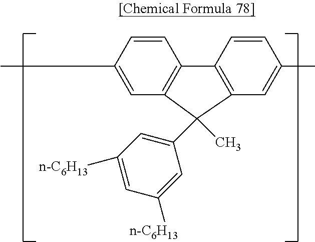

and a constitutional unit represented by the following formula, which corresponds to Y:

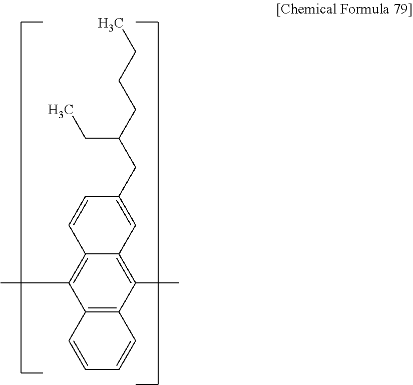

in a molar ratio of 50:50, as the theoretical value calculated from the amounts of the used starting materials, in which the copolymer consists of the constitutional sequence (n=1) represented by the formula (1) only.

### Polymerization Example 10

### Synthesis of Polymer 10 that is Polymerization Working Example 8

Under inert atmosphere, the compound 3P (1.782 g, 2.95 mmol), the compound 1T (1.345 g, 3.00 mmol), dichlorobis(tris-o-methoxyphenylphosphine) palladium (2.7 mg), and toluene (50 mL) were mixed and heated to 100° C. 20% by mass aqueous tetraethylammonium hydroxide solution (10 mL) was added dropwise to the reaction solution, which was then refluxed for 3.0 hours. After the reaction, phenylboronic acid (37 mg), dichlorobis(tris-o-methoxyphenylphosphine) palladium (2.7 mg), and 20% by mass aqueous tetraethylammonium hydroxide solution (10 mL) were added thereto and refluxed for 12 hours. Next, aqueous solution of sodium diethyl dithiacarbamate was added thereto followed by stirring at 80° C. for 2 hours. After cooling the mixture obtained, washing was performed twice with water (27 mL), twice with 3% by mass aqueous acetic acid solution (27 mL), and twice with water (27 mL), and the obtained solution was added dropwise to methanol (323 mL) and filtered to give a precipitate. The precipitate was dissolved in toluene (199 mL) and passed through an alumina column and a silica gel column in that order for purification. The obtained solution was added dropwise to methanol (323 mL) and stirred, and then the resulting precipitate was filtered and dried to give the polymer 10 (polymer compound: 1.60 g). The polystyrene equivalent number average molecular weight of the polymer 10 was 4.4×10⁴, and the polystyrene equivalent weight average molecular weight was 2.9×10⁵.

The polymer 10 was an alternating copolymer having a constitutional unit represented by the following formula, which corresponds to Z:

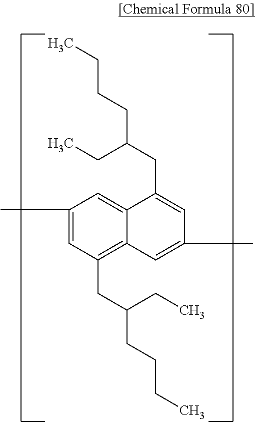

and a constitutional unit represented by the following formula, which corresponds to Y:

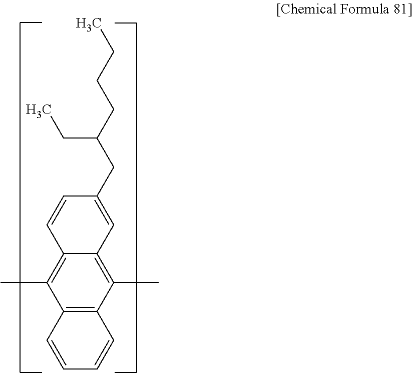

in a molar ratio of 50:50, as the theoretical value calculated from the amounts of the used starting materials, in which the copolymer consists of the constitutional sequence (n=1) represented by the formula (1) only.

### Polymerization Example 12

### Synthesis of Polymer 12 that is Polymerization Working Example 10

Under inert atmosphere, the compound 3P (0.7300 g, 1.21 mmol), the compound 5N (0.8858 g, 1.25 mmol), the compound 1T (1.1206 g, 2.50 mmol), dichlorobis(tris-o-methoxyphenylphosphine) palladium (2.2 mg), and toluene (45 mL) were mixed and heated to 100° C. 20% by mass aqueous tetraethylammonium hydroxide solution (8.3 mL) was added dropwise to the reaction solution, which was then refluxed for 4 hours. After the reaction, phenylboronic acid (31 mg), dichlorobis(tris-o-methoxyphenylphosphine) palladium (2.2 mg), and 20% by mass an aqueous tetraethylammonium hydroxide solution (8.3 mL) were added thereto and refluxed for 20 hours. Next, an aqueous sodium diethyl dithiacarbamate solution was added thereto followed by stirring at 80° C. for 2 hours. After cooling the mixture obtained, washing was performed twice with water (24 mL), twice with a 3% by mass of an aqueous acetic acid solution (24 mL), and twice with water (24 mL), and the obtained solution was added dropwise to methanol (292 mL) and filtered to give a precipitate. The precipitate was dissolved in toluene (120 mL) and passed through an alumina column and a silica gel column in that order for purification. The obtained solution was added dropwise to methanol (292 mL) and stirred, and then the resulting precipitate was filtered and dried to give the polymer 12 (polymer compound: 1.25 g). The polystyrene equivalent number average molecular weight of the polymer 12 was 7.0×10⁴, and the polystyrene equivalent weight average molecular weight was 8.0×10⁵.

The polymer 12 was a copolymer having a constitutional unit represented by the following formula, which corresponds to Z:

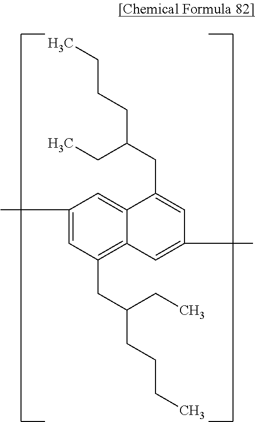

a constitutional unit represented by the following formula, which corresponds to Z:

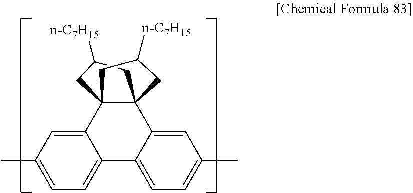

and a constitutional unit represented by the following formula, which corresponds to Y:

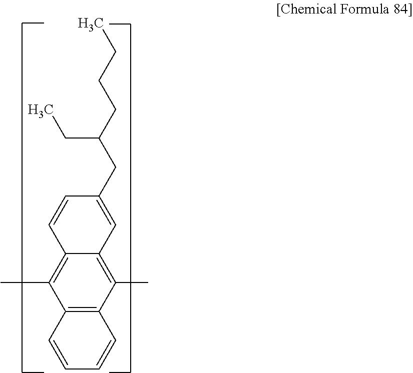

in a molar ratio of 25:25:50, as the theoretical value calculated from the amounts of the used starting materials, in which the copolymer consists of the constitutional sequence (n=1) represented by the formula (1) only.

### Polymerization Example 13

### Synthesis of Polymer 13 that is to be Polymerization Working Example 11

Under inert atmosphere, the compound 2Q (1.3419 g, 1.960 mmol), the compound 4I (0.3383 g, 0.500 mmol), the compound 1T (1.1206 g, 2.50 mmol), dichlorobis(tris-o-methoxyphenylphosphine) palladium (2.2 mg), and toluene (46 mL) were mixed and heated to 100° C. 20% by mass aqueous tetraethylammonium hydroxide solution (8.3 mL) was added dropwise to the reaction solution, which was then refluxed for 4 hours. After the reaction, phenylboronic acid (31 mg), dichlorobis(tris-o-methoxyphenylphosphine) palladium (2.2 mg), and 20% by mass aqueous tetraethylammonium hydroxide solution (8.3 mL) were added thereto and refluxed for 20 hours. Next, aqueous sodium diethyl dithiacarbamate solution was added thereto followed by stirring at 80° C. for 2 hours. After cooling the mixture obtained, washing was performed twice with water (25 mL), twice with 3% by mass an aqueous acetic acid solution (25 mL), and twice with water (25 mL), and the obtained solution was added dropwise to methanol (303 mL) and filtered to give a precipitate. The precipitate was dissolved in toluene (124 mL) and passed through an alumina column and a silica gel column in that order for purification. The obtained solution was added dropwise to methanol (673 mL) and stirred, and then the resulting precipitate was filtered and dried to give the polymer 13 (polymer compound: 1.36 g). The polystyrene equivalent number average molecular weight of the polymer 13 was 7.5×10⁴, and the polystyrene equivalent weight average molecular weight was 3.0×10⁵.

The polymer 13 was a copolymer having a constitutional unit represented by the following formula, which corresponds to Z:

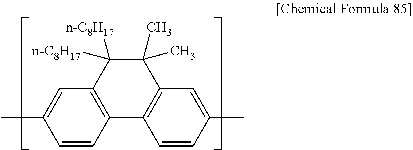

a constitutional unit represented by the following formula, which corresponds to Z:

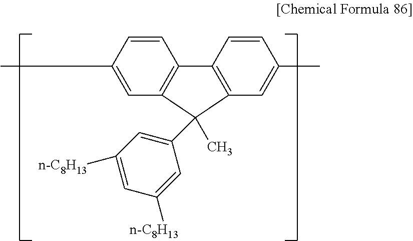

and a constitutional unit represented by the following formula, which corresponds to Y:

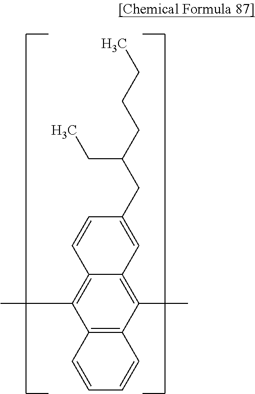

in a molar ratio of 40:10:50, as the theoretical value calculated from the amounts of the used starting materials, in which the copolymer consists of the constitutional sequence (n=1) represented by the formula (1) only.

### Polymerization Example 14

### Synthesis of Polymer 14 that is to be Polymerization Working Example 12

Under inert atmosphere, the compound 3P (0.7330 g, 1.213 mmol), the compound 4I (0.8457 g, 1.250 mmol), the compound 1T (1.1206 g, 2.50 mmol), dichlorobis(tris-o-methoxyphenylphosphine) palladium (2.2 mg), and toluene (44 mL) were mixed heated to 100° C. 20% by mass aqueous tetraethylammonium hydroxide solution (8.3 mL) was added dropwise to the reaction solution, which was then refluxed for 5 hours. After the reaction, phenylboronic acid (31 mg), dichlorobis(tris-o-methoxyphenylphosphine) palladium (2.2 mg), and 20% by mass aqueous tetraethylammonium hydroxide solution (8.3 mL) were added thereto and refluxed for further 20 hours. Next, aqueous sodium diethyl dithiacarbamate solution was added thereto followed by stirring at 80° C. for 2 hours. After cooling the mixture obtained, washing was performed twice with water (24 mL), twice with 3% by mass aqueous acetic acid solution (24 mL), and twice with water (24 mL), and the obtained solution was added dropwise to methanol (285 mL) and filtered to give a precipitate. The precipitate was dissolved in toluene (117 mL) and passed through an alumina column and a silica gel column in that order for purification. The obtained solution was added dropwise to methanol (380 mL) and stirred, and then the resulting precipitate was filtered and dried to give the polymer 14 (polymer compound: 1.14 g). The polystyrene equivalent number average molecular weight of the polymer 14 was 8.0×10⁴, and the polystyrene equivalent weight average molecular weight was 2.6×10⁵.

The polymer 21 was a copolymer having a constitutional unit represented by the following formula, which corresponds to Z in the formula (1):

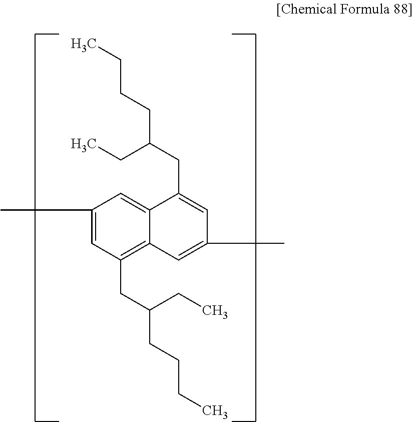

a constitutional unit represented by the following formula, which corresponds to Z:

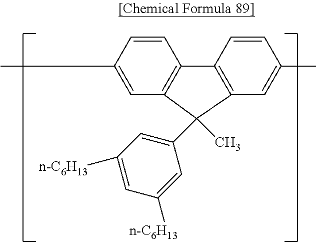

and a constitutional unit represented by the following formula, which corresponds to Y:

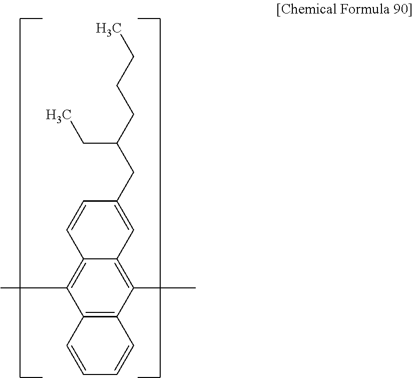

in a molar ratio of 25:25:50, as the theoretical value calculated from the amounts of the used starting materials, in which the copolymer consists of the constitutional sequence (n=1) represented by the formula (1) only.

### Polymerization Example 15

### Synthesis of Polymer 15 that is to be Polymerization Working Example 13

Under inert atmosphere, the compound 3P (4.9955 g, 8.264 mmol), the compound 4I (1.4208 g, 2.100 mmol), the compound 1T (4.7064 g, 10.500 mmol), dichlorobis(tris-o-methoxyphenylphosphine) palladium (9.3 mg), and toluene (177 mL) were mixed and heated to 100° C. 20% by mass aqueous tetraethylammonium hydroxide solution (35 mL) was added dropwise to the reaction solution, which was then refluxed for 4 hours. After the reaction, phenylboronic acid (128 mg), dichlorobis(tris-o-methoxyphenylphosphine) palladium (9.3 mg), and 20% by mass aqueous tetraethylammonium hydroxide solution (35 mL) were added thereto and refluxed for 20 hours. Next, aqueous sodium diethyl dithiacarbamate solution was added thereto followed by stirring at 80° C. for 2 hours. After cooling the mixture obtained, washing was performed twice with water (96 mL), twice with 3% by mass aqueous acetic acid solution (96 mL), and twice with water (96 mL), and the obtained solution was added dropwise to methanol (1158 mL) and filtered to give a precipitate. The precipitate was dissolved in toluene (237 mL) and passed through an alumina column and a silica gel column in that order for purification. The obtained solution was added dropwise to methanol (1158 mL) and stirred, and then the resulting precipitate was filtered and dried to give the polymer 15 (polymer compound: 5.0 g). The polystyrene equivalent number average molecular weight of the polymer 15 was 7.0×10⁴, and the polystyrene equivalent weight average molecular weight was 2.6×10⁵.

The polymer 15 was a copolymer having a constitutional unit represented by the following formula, which corresponds to Z:

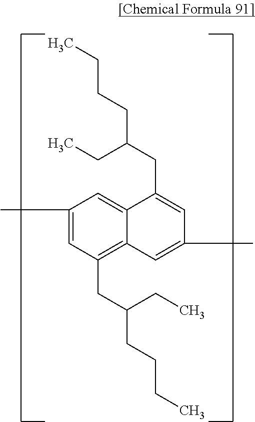

a constitutional unit represented by the following formula, which corresponds to Z:

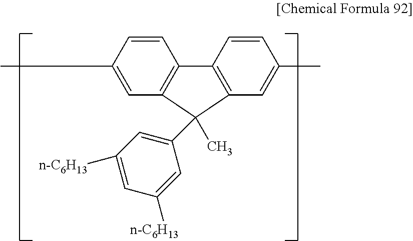

and a constitutional unit represented by the following formula, which corresponds to Y:

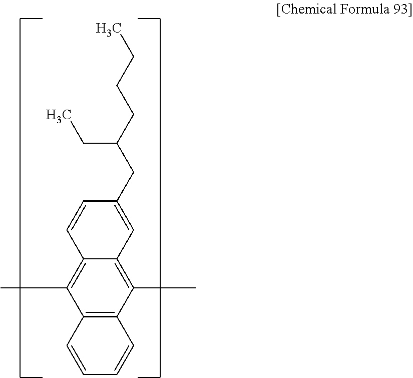

in a molar ratio of 40:10:50, as the theoretical value calculated from the amounts of the used starting materials, in which the copolymer consists of the constitutional sequence (n=1) represented by the formula (1) only.

### Polymerization Example 16

### Synthesis of Polymer 16 that is to be Polymerization Working Example 14

Under inert atmosphere, the compound 3B (8.888 g, 9.80 mmol), the compound 2B (0.813 g, 1.00 mmol), the compound 1H (3.024 g, 9.00 mmol), dichlorobis(triphenylphosphine) palladium (7.0 mg), and toluene (202 mL) were mixed and heated to 100° C. 20% by mass aqueous tetraethylammonium hydroxide solution (33 mL) was added dropwise to the reaction solution, which was then refluxed for 6 hours. After the reaction, phenylboronic acid (122 mg), dichlorobis(triphenylphosphine) palladium (7.0 mg), and 20% by mass of an aqueous tetraethylammonium hydroxide solution (33 mL) were added thereto and refluxed for 12 hours. Next, aqueous solution of sodium diethyl dithiacarbamate was added thereto followed by stirring at 80° C. for 2 hours. After cooling the mixture obtained, washing was performed twice with water (129 mL), twice with 3% by mass aqueous acetic acid solution (129 mL), and twice with water (129 mL), and the obtained solution was added dropwise to methanol (1560 mL) and filtered to obtain a precipitate. The precipitate was dissolved in toluene (320 mL) and passed through an alumina column and a silica gel column in that order for purification. The obtained solution was added dropwise to methanol (1560 mL) and stirred, and then the resulting precipitate was filtered and dried to give the polymer 16 (polymer compound: 6.4 g). The polystyrene equivalent number average molecular weight of the polymer 16 was 6.9×10⁴, and the polystyrene equivalent weight average molecular weight was 2.1×10⁵.

The polymer 16 was a copolymer having a constitutional unit represented by the following formula, which corresponds to Z:

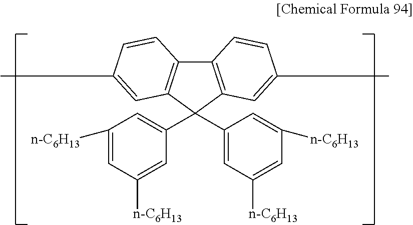

and a constitutional unit represented by the following formula, which corresponds to Y:

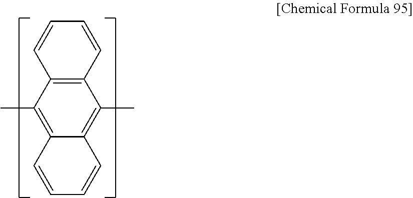

in a molar ratio of 55:45, as the theoretical value calculated from the amounts of the used starting materials. The copolymer corresponded to the Polymerization condition 9 using the Polymerization simulation described above, and it was a polymer containing the constitutional sequence (n=1, m′=9.9) included in the copolymer, which is represented by the formula (1).

### Polymerization Example 17

### Synthesis of Polymer 17 that is to be Polymerization Working Example 15

Under inert atmosphere, the compound 3B (8.888 g, 9.80 mmol), the compound 2B (1.6257 g, 2.00 mmol), the compound 1F (2.688 g, 6.00 mmol), dichlorobis(triphenylphosphine) palladium (7.0 mg), and toluene (213 mL) were mixed and heated to 100° C. 20% by mass aqueous tetraethylammonium hydroxide solution (33 mL) was added dropwise to the reaction solution, which was then refluxed for 6 hours. After the reaction, phenylboronic acid (122 mg), dichlorobis(triphenylphosphine) palladium (7.0 mg), and 20% by mass of an aqueous tetraethylammonium hydroxide solution (33 mL) were added thereto and refluxed for 12 hours. Next, aqueous solution of sodium diethyl dithiacarbamate was added thereto followed by stirring at 80° C. for 2 hours. After cooling the mixture obtained, washing was performed twice with water (129 mL), twice with 3% by mass aqueous acetic acid solution (129 mL), and twice with water (129 mL), and the obtained solution was added dropwise to methanol (1560 mL) and filtered to obtain a precipitate. The precipitate was dissolved in toluene (320 mL) and passed through an alumina column and a silica gel column in that order for purification. The obtained solution was added dropwise to methanol (1560 mL) and stirred, and then the resulting precipitate was filtered and dried to give the polymer 17 (polymer compound: 9.12 g). The polystyrene equivalent number average molecular weight of the polymer 17 was 3.1×10⁴, and the polystyrene equivalent weight average molecular weight was 9.5×10⁵.

The polymer 17 was a copolymer having a constitutional unit represented by the following formula, which corresponds to Z:

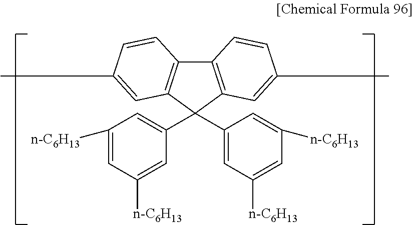

and a constitutional unit represented by the following formula, which corresponds to Y:

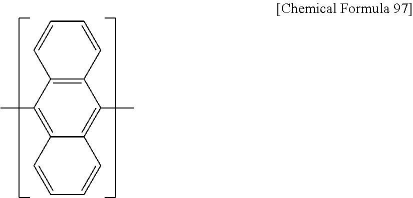

in a molar ratio of 60:40, as the theoretical value calculated from the amounts of the used starting materials. The copolymer corresponded to the Polymerization condition 8 using the Polymerization simulation described above, and it was a polymer containing the constitutional sequence (n=l, m′=5.35) included in the copolymer, which is represented by the formula (1).

### Polymerization Example 18

### Synthesis of Polymer 18

Under inert atmosphere, the compound 3B (1.796 g, 1.98 mmol), the compound 2B (0.650 g, 0.80 mmol), the compound 1H (0.403 g, 1.2 mmol), dichlorobis(triphenylphosphine) palladium (1.4 mg), and toluene (47 mL) were and heated to 100° C. 20% by mass aqueous tetraethylammonium hydroxide solution (6.6 mL) was added dropwise to the reaction solution, which was then refluxed for 5 hours. After the reaction, phenylboronic acid (24.4 mg), dichlorobis(triphenylphosphine) palladium (1.4 mg), and 20% by mass aqueous tetraethylammonium hydroxide solution (6.6 mL) were added thereto and refluxed for further 20 hours. Next, aqueous solution of sodium diethyl dithiacarbamate was added thereto followed by stirring at 80° C. for 2 hours. After cooling the mixture obtained, washing was performed twice with water (26 mL), twice with a 3% by mass of an aqueous acetic acid solution (26 mL), and twice with water (26 mL), and the obtained solution was added dropwise to methanol (311 mL) and filtered to give a precipitate. The precipitate was dissolved in toluene (63 mL) and passed through an alumina column and a silica gel column in that order for purification. The obtained solution was added dropwise to methanol (311 mL) and stirred, and then the resulting precipitate was filtered and dried to give the polymer 18 (1.74 g). The polystyrene equivalent number average molecular weight of the polymer 18 was 1.1×10⁵, and the polystyrene equivalent weight average molecular weight was 3.7×10⁵.

The polymer 18 was a copolymer having a constitutional unit represented by the following formula, which corresponds to Z:

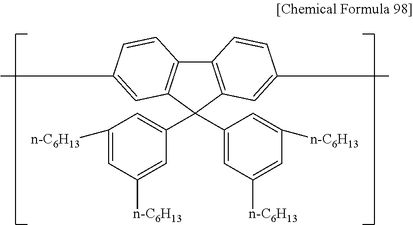

and a constitutional unit represented by the following formula, which corresponds to Y:

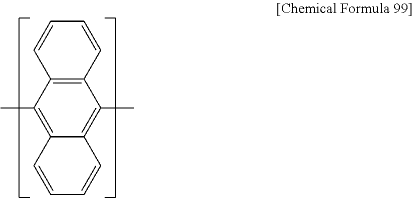

in a molar ratio of 70:30, as the theoretical value calculated from the amounts of the used starting materials. The copolymer corresponded to the Polymerization condition 6 using the “Polymerization simulation” described above, and it was a polymer containing the constitutional sequence (n=1, m′=2.95) included in the copolymer, which is represented by the formula (1).

### Polymerization Example 19

### Synthesis of Polymer 19

Under inert atmosphere, the compound 3B (1.796 g, 1.98 mmol), the compound 3C (1.301 g, 1.60 mmol), the compound 1F (0.131 g, 0.40 mmol), dichlorobis(triphenylphosphine) palladium (1.4 mg), and toluene (47 mL) were mixed and heated to 100° C. 20% by mass aqueous tetraethylammonium hydroxide solution (6.7 mL) was added dropwise to the reaction solution, which was then refluxed for 5 hours. After the reaction, phenylboronic acid (24.4 mg), dichlorobis(triphenylphosphine) palladium (1.4 mg), and 20% by mass aqueous tetraethylammonium hydroxide solution (6.6 mL) were added thereto and refluxed for further 20 hours. Next, aqueous solution of sodium diethyl dithiacarbamate was added thereto followed by stirring at 80° C. for 2 hours. After cooling the mixture obtained, washing was performed twice with water (26 mL), twice with 3% by mass aqueous acetic acid solution (26 mL), and twice with water (26 mL), and the obtained solution was added dropwise to methanol (311 mL) and filtered to give a precipitate. The precipitate was dissolved in toluene (63 mL) and passed through an alumina column and a silica gel column in that order for purification. The obtained solution was added dropwise to methanol (311 mL) and stirred, and then the resulting precipitate was filtered and dried to give the polymer 19 (2.07 g). The polystyrene equivalent number average molecular weight of the polymer 19 was 1.1×10⁵, and the polystyrene equivalent weight average molecular weight was 3.4×10⁵.

The polymer 19 was a copolymer having a constitutional unit represented by the following formula, which corresponds to Z:

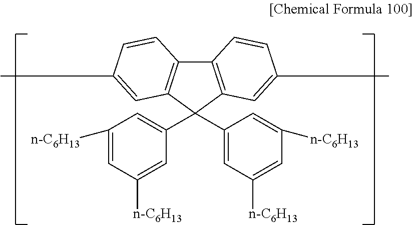

and a constitutional unit represented by the following formula, which corresponds to Y:

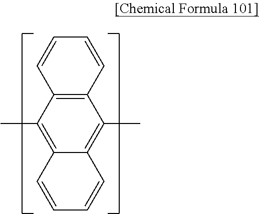

in a molar ratio of 90:10, as the theoretical value calculated from the amounts of the used starting materials. The copolymer corresponded to the Polymerization condition 2 using the “Polymerization simulation” described above, and it was a polymer containing the constitutional sequence (n=l, m′=1.75) included in the copolymer, which is represented by the formula (1).

### Polymerization Example 20

### Synthesis of Polymer 20

Under inert atmosphere, the compound F8BE (1.254 g, 2.0 mmol), the compound 1T (0.896 g, 2.0 mmol), dichlorobis(tris-o-methoxyphenylphosphine) palladium (1.8 mg), and toluene (47 mL) were mixed and heated to 100° C. 20% by mass aqueous tetraethylammonium hydroxide solution (6.6 mL) was added dropwise to the reaction solution, which was then refluxed for 5 hours. After the reaction, phenylboronic acid (24.4 mg), dichlorobis(tris-o-methoxyphenylphosphine) palladium (1.8 mg), and 20% by mass aqueous tetraethylammonium hydroxide solution (6.6 mL) were added thereto and refluxed for further 20 hours. Next, aqueous solution of sodium diethyl dithiacarbamate was added thereto followed by stirring at 80° C. for 2 hours. After cooling the mixture obtained, washing was performed twice with water (26 mL), twice with 3% by mass aqueous acetic acid solution (26 mL), and twice with water (26 mL), and the obtained solution was added dropwise to methanol (311 mL) and filtered to give a precipitate. The precipitate was dissolved in toluene (63 mL) and passed through an alumina column and a silica gel column in that order for purification. The obtained solution was added dropwise to methanol (311 mL) and stirred, and then the resulting precipitate was filtered and dried to give the polymer 20 (0.99 g). The polystyrene equivalent number average molecular weight of the polymer 20 was 5.0×10⁴, and the polystyrene equivalent weight average molecular weight was 1.4×10⁵.

The polymer 20 was a copolymer having a constitutional unit represented by the following formula, which corresponds to Z:

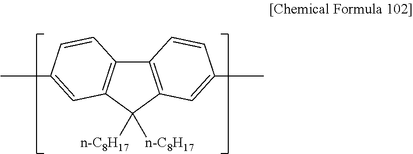

and a constitutional unit represented by the following formula, which corresponds to Y:

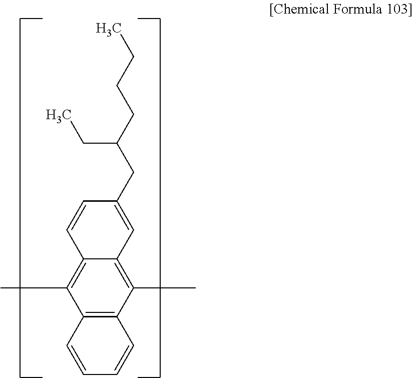

in a molar ratio of 50:50, as the theoretical value calculated from the amounts of the used starting materials.

### Synthesis Example 16

### Synthesis of Low Molecular Weight Fluorescent Substance 1

Under inert gas atmosphere, 4-octylphenyl phenylamine (4.92 g, 17.48 mmol), tris(dibenzylidene acetone) dipalladium (0.076 g, 0.08 mmol), tri-tert-butylphosphonium tetrafluoroborate (0.095 g, 0.33 mmol), and sodium tert-butoxide (2.40 g, 24.97 mmol) were added with 11 mL of toluene and dissolved therein by heating to 100° C. under stirring. To the solution obtained, dibromopyrene (3.00 g, 8.33 mmol) was added at 100° C. followed by stirring at 100° C. for 5 hours. After cooling to a room temperature, the reaction solution was added with toluene, stirred, and filtered through a filter overlaid with silica gel. The filtered solution was concentrated and solidified by drying. The solid obtained was re-crystallized with toluene and methanol and further re-crystallized with hexane to obtain the low molecular weight fluorescent substance 1 that is represented by the following formula (2.53 g, yield 40%).

¹H-NMR (300 MHz/CDCl₃):

δ(ppm)=0.89 (t, 6H), 1.28 (m, 20H), 1.58 (m, 4H), 2.53 (t, 4H), 6.90 (t, 2H), 7.01 (m, 12H), 7.18 (t, 4H), 7.79 (d, 2H), 7.89 (d, 2H), 8.07 (d, 2H), 8.13 (d, 2H).

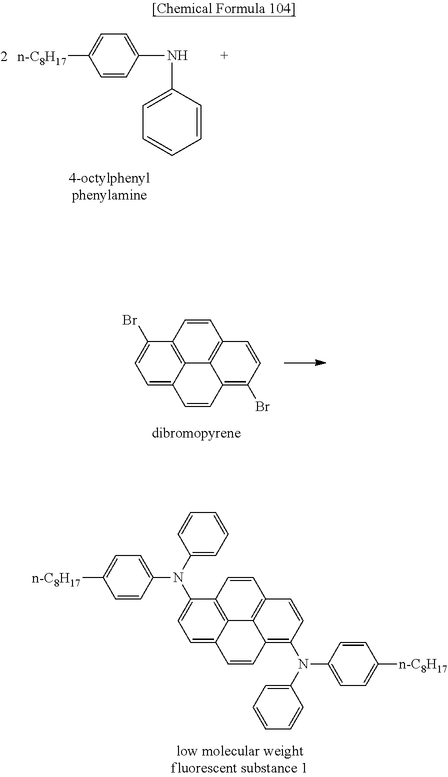

### Fabrication and evaluation Of Organic EL Device

### Example 1

### Fabrication and Evaluation of the Organic EL Device 1

AQ-1200 (manufactured by Plextronics) that was a polythiophene.sulfonic acid based hole injection agent was coated by spin coating method onto a glass panel on which an ITO film had been formed to thickness of 45 nm by sputtering method, with a film thickness of 50 nm. It was then dried on a hot plate at 170° C. for 15 minutes to fabricate a substrate for organic EL.

Next, the hole transport polymer (polymer 7) which has been dissolved in xylene solvent to the concentration of 0.7% by mass was spin-coated to form a film with thickness of about 20 nm. After that, it was treated with heat for 60 minutes at 180° C. on a hot plate under nitrogen atmosphere.

Next, a solution of the polymer 2 dissolved in xylene solvent to the concentration of 1.2% by mass, and a solution of the low molecular weight fluorescent substance 1 dissolved in xylene solvent to the concentration of 1.2% by mass were mixed such that the polymer 2: the low molecular weight fluorescent substance 1=95:5 in terms of weight ratio, thus yielding the composition 1.

The composition 1 was formed into a film on the substrate described above by spin coating at a rotation speed of 1200 rpm to fabricate a light emitting layer with a thickness of about 60 nm. This was dried under a nitrogen gas atmosphere at 130° C. for 10 minutes, after which as a cathode, sodium fluoride was deposited in a thickness of about 3 nm, and aluminum was then deposited in a thickness of about 80 nm to prepare the organic EL device 1. After the degree of vacuum reaches 1×10⁻⁴ Pa or lower, deposition of metal was started.

A voltage was applied to the obtained organic EL device 1, and EL light emission having a peak at 465 nm which originates from the low molecular weight fluorescent substance 1 was obtained from the device. The device started to emit light at 2.9 V and had a maximum light emitting efficiency of 8.0 cd/A.

A current value was set so that the organic EL device 1 obtained as described above had an initial luminance of 5000 cd/m², the device was then driven at a constant current, and a change in luminance with time was measured. As a result, it was found that the luminance decreases by half after 45 hours.

### Example 2

### Fabrication and Evaluation of the Organic EL Device 2

The organic EL device 2 was fabricated in the same manner as Example 1 except that, instead of the composition 1 of Example 1, the composition 2 obtained by mixing a solution of the polymer 3 dissolved in xylene solvent to the concentration of 1.2% by mass, a solution of the low molecular weight fluorescent substance 1 dissolved in xylene solvent to the concentration of 1.2% by mass such that the polymer 3: the low molecular weight fluorescent substance 1=95:5 in terms of weight ratio, was used. A voltage was applied to the obtained organic EL device 2, and EL light emission having a peak at 465 nm which originates from the low molecular weight fluorescent substance 1 was obtained from the device. The device started to emit light at 4.0 V and had a maximum light emitting efficiency of 5.9 cd/A.

A current value was set so that the organic EL device 2 obtained as described above had an initial luminance of 5000 cd/m², the device was then driven at a constant current, and a change in luminance with time was measured. As a result, it was found that the luminance decreases by half after 30 hours.

### Example 3

### Fabrication and Evaluation of the Organic EL Device 3

The organic EL device 3 was fabricated in the same manner as Example 1 except that, instead of the composition 1 of Example 1, the composition 3 obtained by mixing a solution of the polymer 4 dissolved in xylene solvent to the concentration of 1.2% by mass, a solution of the low molecular weight fluorescent substance 1 dissolved in xylene solvent to the concentration of 1.2% by mass such that the polymer 4: the low molecular weight fluorescent substance 1=95:5 in terms of weight ratio, was used. A voltage was applied to the obtained organic EL device 3, and EL light emission having a peak at 465 nm which originates from the low molecular weight fluorescent substance 1 was obtained from the device. The device started to emit light at 3.9 V and had a maximum light emitting efficiency of 5.8 cd/A.

A current value was set so that the organic EL device 3 obtained as described above had an initial luminance of 5000 cd/m², the device was then driven at a constant current, and a change in luminance with time was measured. As a result, it was found that the luminance decreases by half after 32 hours.

### Example 4

### Fabrication and Evaluation of the Organic EL Device 4

The organic EL device 4 was fabricated in the same manner as Example 1 except that, instead of the composition 1 of Example 1, the composition 4 obtained by mixing a solution of the polymer 5 dissolved in xylene solvent to the concentration of 1.2% by mass, a solution of the low molecular weight fluorescent substance 1 dissolved in xylene solvent to the concentration of 1.2% by mass such that the polymer 5: the low molecular weight fluorescent substance 1=95:5 in terms of weight ratio, was used. A voltage was applied to the obtained organic EL device 4, and EL light emission having a peak at 465 nm which originates from the low molecular weight fluorescent substance 1 was obtained from the device. The device started to emit light at 2.9 V and had a maximum light emitting efficiency of 7.4 cd/A.

A current value was set so that the organic EL device 4 obtained as described above had an initial luminance of 5000 cd/m², the device was then driven at a constant current, and a change in luminance with time was measured. As a result, it was found that the luminance decreases by half after 24 hours.

### Example 5

### Fabrication and Evaluation of the Organic EL Device 5

The organic EL device 5 was fabricated in the same manner as Example 1 except that, instead of the composition 1 of Example 1, the composition 5 obtained by mixing a solution of the polymer 6 dissolved in chlorobenzene solvent to the concentration of 1.0% by mass, a solution of the low molecular weight fluorescent substance 1 dissolved in chlorobenzene solvent to the concentration of 1.0% by mass such that the polymer 6: the low molecular weight fluorescent substance 1=95:5 in terms of weight ratio, was used. A voltage was applied to the obtained organic EL device 5, and EL light emission having a peak at 465 nm which originates from the low molecular weight fluorescent substance 1 was obtained from the device. The device started to emit light at 3.1 V and had a maximum light emitting efficiency of 7.1 cd/A.

A current value was set so that the organic EL device 5 obtained as described above had an initial luminance of 5000 cd/m², the device was then driven at a constant current, and a change in luminance with time was measured. As a result, it was found that the luminance decreases by half after 84 hours.

### Example 6

### Fabrication and Evaluation of the Organic EL Device 6

The organic EL device 6 was fabricated in the same manner as Example 1 except that, instead of the composition 1 of Example 1, the composition 6 obtained by mixing a solution of the polymer 8 dissolved in chlorobenzene solvent to the concentration of 1.0% by mass, a solution of the low molecular weight fluorescent substance 1 dissolved in chlorobenzene solvent to the concentration of 1.0% by mass such that the polymer 8: the low molecular weight fluorescent substance 1=95:5 in terms of weight ratio, was used. A voltage was applied to the obtained organic EL device 6, and EL light emission having a peak at 465 nm which originates from the low molecular weight fluorescent substance 1 was obtained from the device. The device started to emit light at 3.0 V and had a maximum light emitting efficiency of 8.2 cd/A.

A current value was set so that the organic EL device 6 obtained as described above had an initial luminance of 5000 cd/m², the device was then driven at a constant current, and a change in luminance with time was measured. As a result, it was found that the luminance decreases by half after 22 hours.

### Example 7

### Fabrication and Evaluation of the Organic EL Device 7

The organic EL device 7 was fabricated in the same manner as Example 1 except that, instead of the composition 1 of Example 1, the composition 7 obtained by mixing a solution of the polymer 9 dissolved in chlorobenzene solvent to the concentration of 1.0% by mass, a solution of the low molecular weight fluorescent substance 1 dissolved in chlorobenzene solvent to the concentration of 1.0% by mass such that the polymer 9: the low molecular weight fluorescent substance 1=95:5 in terms of weight ratio, was used. A voltage was applied to the obtained organic EL device 7, and EL light emission having a peak at 465 nm which originates from the low molecular weight fluorescent substance 1 was obtained from the device. The device started to emit light at 3.3 V and had a maximum light emitting efficiency of 6.2 cd/A.

A current value was set so that the organic EL device 6 obtained as described above had an initial luminance of 5000 cd/m², the device was then driven at a constant current, and a change in luminance with time was measured. As a result, it was found that the luminance decreases by half after 50 hours.

### Example 8

### Fabrication and Evaluation of the Organic EL Device 8

The organic EL device 8 was fabricated in the same manner as Example 1 except that, instead of the composition 1 of Example 1, the composition 10 obtained by mixing a solution of the polymer 10 dissolved in chlorobenzene solvent to the concentration of 1.0% by mass, a solution of the low molecular weight fluorescent substance 1 dissolved in chlorobenzene solvent to the concentration of 1.0% by mass such that the polymer 10: the low molecular weight fluorescent substance 1=95:5 in terms of weight ratio, was used. A voltage was applied to the obtained organic EL device 8, and EL light emission having a peak at 465 nm which originates from the low molecular weight fluorescent substance 1 was obtained from the device. The device started to emit light at 4.0 V and had a maximum light emitting efficiency of 5.0 cd/A.

A current value was set so that the organic EL device 8 obtained as described above had an initial luminance of 5000 cd/m², the device was then driven at a constant current, and a change in luminance with time was measured. As a result, it was found that the luminance decreases by half after 50 hours.

### Example 9

### Fabrication and Evaluation of the Organic EL Device 9

The organic EL device 9 was fabricated in the same manner as Example 1 except that, instead of the composition 1 of Example 1, the composition 12 obtained by mixing a solution of the polymer 12 dissolved in chlorobenzene solvent to the concentration of 1.0% by mass, a solution of the low molecular weight fluorescent substance 1 dissolved in chlorobenzene solvent to the concentration of 1.0% by mass such that the polymer 12: the low molecular weight fluorescent substance 1=95:5 in terms of weight ratio, was used. A voltage was applied to the obtained organic EL device 9, and EL light emission having a peak at 465 nm which originates from the low molecular weight fluorescent substance 1 was obtained from the device. The device started to emit light at 3.9 V and had a maximum light emitting efficiency of 6.4 cd/A.

A current value was set so that the organic EL device 9 obtained as described above had an initial luminance of 5000 cd/m², the device was then driven at a constant current, and a change in luminance with time was measured. As a result, it was found that the luminance decreases by half after 20 hours.

### Example 10

### Fabrication and Evaluation of the Organic EL Device 10

The organic EL device 10 was fabricated in the same manner as Example 1 except that, instead of the composition 1 of Example 1, the composition 13 obtained by mixing a solution of the polymer 13 dissolved in chlorobenzene solvent to the concentration of 1.0% by mass, a solution of the low molecular weight fluorescent substance 1 dissolved in chlorobenzene solvent to the concentration of 1.0% by mass such that the polymer 13: the low molecular weight fluorescent substance 1=95:5 in terms of weight ratio, was used. A voltage was applied to the obtained organic EL device 10, and EL light emission having a peak at 465 nm which originates from the low molecular weight fluorescent substance 1 was obtained from the device. The device started to emit light at 3.3 V and had a maximum light emitting efficiency of 8.2 cd/A.

A current value was set so that the organic EL device 10 obtained as described above had an initial luminance of 5000 cd/m², the device was then driven at a constant current, and a change in luminance with time was measured. As a result, it was found that the luminance decreases by half after 50 hours.

### Example 11

### Fabrication and Evaluation of the Organic EL Device 11

The organic EL device 11 was fabricated in the same manner as Example 1 except that, instead of the composition 1 of Example 1, the composition 14 obtained by mixing a solution of the polymer 14 dissolved in chlorobenzene solvent to the concentration of 1.0% by mass, a solution of the low molecular weight fluorescent substance 1 dissolved in chlorobenzene solvent to the concentration of 1.0% by mass such that the polymer 14: the low molecular weight fluorescent substance 1=95:5 in terms of weight ratio, was used. A voltage was applied to the obtained organic EL device 11, and EL light emission having a peak at 465 nm which originates from the low molecular weight fluorescent substance 1 was obtained from the device. The device started to emit light at 3.3 V and had a maximum light emitting efficiency of 6.4 cd/A.

A current value was set so that the organic EL device 11 obtained as described above had an initial luminance of 5000 cd/m², the device was then driven at a constant current, and a change in luminance with time was measured. As a result, it was found that the luminance decreases by half after 67 hours.

### Example 12

### Fabrication and Evaluation of the Organic EL Device 12

The organic EL device 12 was fabricated in the same manner as Example 1 except that, instead of the composition 1 of Example 1, the composition 15 obtained by mixing a solution of the polymer 15 dissolved in chlorobenzene solvent to the concentration of 1.0% by mass, a solution of the low molecular weight fluorescent substance 1 dissolved in chlorobenzene solvent to the concentration of 1.0% by mass such that the polymer 15: the low molecular weight fluorescent substance 1=95:5 in terms of weight ratio, was used. A voltage was applied to the obtained organic EL device 12, and EL light emission having a peak at 465 nm which originates from the low molecular weight fluorescent substance 1 was obtained from the device. The device started to emit light at 3.5 V and had a maximum light emitting efficiency of 6.3 cd/A.

A current value was set so that the organic EL device 12 obtained as described above had an initial luminance of 5000 cd/m², the device was then driven at a constant current, and a change in luminance with time was measured. As a result, it was found that the luminance decreases by half after 59 hours.

### Example 13

### Fabrication and Evaluation of the Organic EL Device 13

The organic EL device 13 was fabricated in the same manner as Example 1 except that, instead of the composition 1 of Example 1, the composition 16 obtained by mixing a solution of the polymer 16 dissolved in chlorobenzene solvent to the concentration of 1.0% by mass, a solution of the low molecular weight fluorescent substance 1 dissolved in chlorobenzene solvent to the concentration of 1.0% by mass such that the polymer 16: the low molecular weight fluorescent substance 1=95:5 in terms of weight ratio, was used. A voltage was applied to the obtained organic EL device 13, and EL light emission having a peak at 465 nm which originates from the low molecular weight fluorescent substance 1 was obtained from the device. The device started to emit light at 2.8 V and had a maximum light emitting efficiency of 6.8 cd/A.

A current value was set so that the organic EL device 13 obtained as described above had an initial luminance of 5000 cd/m², the device was then driven at a constant current, and a change in luminance with time was measured. As a result, it was found that the luminance decreases by half after 47 hours.

### Example 14

### Fabrication and Evaluation of the Organic EL Device 14

The organic EL device 14 was fabricated in the same manner as Example 1 except that, instead of the composition 1 of Example 1, the composition 17 obtained by mixing a solution of the polymer 17 dissolved in chlorobenzene solvent to the concentration of 1.0% by mass, a solution of the low molecular weight fluorescent substance 1 dissolved in chlorobenzene solvent to the concentration of 1.0% by mass such that the polymer 17: the low molecular weight fluorescent substance 1=95:5 in terms of weight ratio, was used. A voltage was applied to the obtained organic EL device 14, and EL light emission having a peak at 465 nm which originates from the low molecular weight fluorescent substance 1 was obtained from the device. The device started to emit light at 3.0 V and had a maximum light emitting efficiency of 6.7 cd/A.

A current value was set so that the organic EL device 14 obtained as described above had an initial luminance of 5000 cd/m², the device was then driven at a constant current, and a change in luminance with time was measured. As a result, it was found that the luminance decreases by half after 24 hours.

### Comparative Example 1

### Fabrication and Evaluation of the Organic EL Device C1

The organic EL device C1 was fabricated in the same manner as Example 1 except that, instead of the composition 1 of Example 1, the composition 8 obtained by mixing a solution of the polymer 1 dissolved in c xylene solvent to the concentration of 1.2% by mass, a solution of the low molecular weight fluorescent substance 1 dissolved in xylene solvent to the concentration of 1.2% by mass such that the polymer 1: the low molecular weight fluorescent substance 1=95:5 in terms of weight ratio, was used. A voltage was applied to the obtained organic EL device C1, and EL light emission having a peak at 465 nm which originates from the polymer 1 was obtained from the device. The device started to emit light at 2.8 V and had a maximum light emitting efficiency of 6.5 cd/A.

A current value was set so that the organic EL device C1 obtained as described above had an initial luminance of 5000 cd/m², the device was then driven at a constant current, and a change in luminance with time was measured. As a result, it was found that the luminance decreases by half after 8 hours.

### Comparative Example 2

### Fabrication and Evaluation of the Organic EL Device C2

The organic EL device C2 was fabricated in the same manner as Example 1 except that, instead of the composition 1 of Example 1, the composition 18 obtained by mixing a solution of the polymer 18 dissolved in chlorobenzene solvent to the concentration of 1.0% by mass, a solution of the low molecular weight fluorescent substance 1 dissolved in chlorobenzene solvent to the concentration of 1.0% by mass such that the polymer 18: the low molecular weight fluorescent substance 1=95:5 in terms of weight ratio, was used. A voltage was applied to the obtained organic EL device C2, and EL light emission having a peak at 465 nm which originates from the low molecular weight fluorescent substance 1 was obtained from the device. The device started to emit light at 3.2 V and had a maximum light emitting efficiency of 6.4 cd/A.

A current value was set so that the organic EL device C2 obtained as described above had an initial luminance of 5000 cd/m², the device was then driven at a constant current, and a change in luminance with time was measured. As a result, it was found that the luminance decreases by half after 10 hours.

### Comparative Example 3

### Fabrication and Evaluation of the Organic EL Device C3

The organic EL device C3 was fabricated in the same manner as Example 1 except that, instead of the composition 1 of Example 1, the composition 19 obtained by mixing a solution of the polymer 19 dissolved in chlorobenzene solvent to the concentration of 1.0% by mass, a solution of the low molecular weight fluorescent substance 1 dissolved in chlorobenzene solvent to the concentration of 1.0% by mass such that the polymer 19: the low molecular weight fluorescent substance 1=95:5 in terms of weight ratio, was used. A voltage was applied to the obtained organic EL device C3, and EL light emission having a peak at 465 nm which originates from the low molecular weight fluorescent substance 1 was obtained from the device. The device started to emit light at 3.6 V and had a maximum light emitting efficiency of 4.8 cd/A.

A current value was set so that the organic EL device C3 obtained as described above had an initial luminance of 5000 cd/m², the device was then driven at a constant current, and a change in luminance with time was measured. As a result, it was found that the luminance decreases by half after 5 hours.

### Comparative Example 4

### Fabrication and Evaluation of the Organic EL Device C4

The organic EL device C4 was fabricated in the same manner as Example 1 except that, instead of the composition 1 of Example 1, the composition 20 obtained by mixing a solution of the polymer 20 dissolved in chlorobenzene solvent to the concentration of 1.0% by mass, a solution of the low molecular weight fluorescent substance 1 dissolved in chlorobenzene solvent to the concentration of 1.0% by mass such that the polymer 20: the low molecular weight fluorescent substance 1=95:5 in terms of weight ratio, was used. A voltage was applied to the obtained organic EL device C4, and EL light emission having a peak at 465 nm which originates from the low molecular weight fluorescent substance 1 was obtained from the device. The device started to emit light at 3.3 V and had a maximum light emitting efficiency of 5.7 cd/A.

A current value was set so that the organic EL device C4 obtained as described above had an initial luminance of 5000 cd/m², the device was then driven at a constant current, and a change in luminance with time was measured. As a result, it was found that the luminance decreases by half after 17 hours.

The evaluation results of Examples 1-14 and Comparative Examples 1-4 are collectively shown in Table 1.

TABLE 1

| | | | | maximum light | half |
|---|---|---|---|---|---|
| | | | | emitting | period of |
| | | Mixing | Organic EL | efficiency | luminance |
| | Composition | ratio | device No. | (cd/A) | (hrs.) |
| Example 1 | Polymer 2 | 95 | Organic EL | 8.0 | 45 |
| | Low molecular weight | 5 | device 1 | | |
| | fluorescent substance 1 | | | | |
| Example 2 | Polymer 3 | 95 | Organic EL | 5.9 | 30 |
| | Low molecular weight | 5 | device 2 | | |
| | fluorescent substance 1 | | | | |
| Example 3 | Polymer 4 | 95 | Organic EL | 5.8 | 32 |
| | Low molecular weight | 5 | device 3 | | |
| | fluorescent substance 1 | | | | |
| Example 4 | Polymer 5 | 95 | Organic EL | 7.4 | 24 |
| | Low molecular weight | 5 | device 4 | | |
| | fluorescent substance 1 | | | | |
| Example 5 | Polymer 6 | 95 | Organic EL | 7.1 | 84 |
| | Low molecular weight | 5 | device 5 | | |
| | fluorescent substance 1 | | | | |
| Example 6 | Polymer 8 | 95 | Organic EL | 8.2 | 22 |
| | Low molecular weight | 5 | device 6 | | |
| | fluorescent substance 1 | | | | |
| Example 7 | Polymer 9 | 95 | Organic EL | 6.2 | 50 |
| | Low molecular weight | 5 | device 7 | | |
| | fluorescent substance 1 | | | | |
| Example 8 | Polymer 10 | 95 | Organic EL | 5.0 | 50 |
| | Low molecular weight | 5 | device 8 | | |
| | fluorescent substance 1 | | | | |
| Example 9 | Polymer 12 | 95 | Organic EL | 6.4 | 20 |
| | Low molecular weight | 5 | device 9 | | |
| | fluorescent substance 1 | | | | |
| Example | Polymer 13 | 95 | Organic EL | 8.2 | 50 |
| 10 | Low molecular weight | 5 | device 10 | | |
| | fluorescent substance 1 | | | | |
| Example | Polymer 14 | 95 | Organic EL | 6.4 | 67 |
| 11 | Low molecular weight | 5 | device 11 | | |
| | fluorescent substance 1 | | | | |
| Example | Polymer 15 | 95 | Organic EL | 6.3 | 59 |
| 12 | Low molecular weight | 5 | device 12 | | |
| | fluorescent substance 1 | | | | |
| Example | Polymer 16 | 95 | Organic EL | 6.8 | 47 |
| 13 | Low molecular weight | 5 | device 13 | | |
| | fluorescent substance 1 | | | | |
| Example | Polymer 17 | 95 | Organic EL | 6.7 | 24 |
| 14 | Low molecular weight | 5 | device 14 | | |
| | fluorescent substance 1 | | | | |
| Comp. | Polymer 1 | 95 | Organic EL | 6.5 | 8 |
| Example 1 | Low molecular weight | 5 | device C1 | | |
| | fluorescent substance 1 | | | | |
| Comp. | Polymer 18 | 95 | Organic EL | 6.4 | 10 |
| Example 2 | Low molecular weight | 5 | device C2 | | |
| | fluorescent substance 1 | | | | |
| Comp. | Polymer 19 | 95 | Organic EL | 4.8 | 5 |
| Example 3 | Low molecular weight | 5 | device C3 | | |
| | fluorescent substance 1 | | | | |
| Comp. | Polymer 20 | 95 | Organic EL | 5.7 | 17 |
| Example 4 | Low molecular weight | 5 | device C4 | | |
| | fluorescent substance 1 | | | | |

1. A polymer compound having a constitutional sequence represented by the following formula (1) as a main chain:
—[—(Y)ₙ—Z—]ₘ— (1)
in the formula,
Y represents a divalent group, in which two hydrogen atoms are removed from a structure represented by the following formula (Y-1) or (Y-2),
Z represents a divalent group, in which two hydrogen atoms are removed from a structure represented by the following formula (Z-1), (Z-2), (Z-3), (Z-4), (Z-5), (Z-6), (Z-7), or (Z-8),
m represents an integer of 4 to 10,000, and n represents an integer of 1 to 3,
plural Y's, Z's, and n's each may be the same as or different from each other,
a hydrogen atom included in Y and Z may be substituted by R′, and R′ each independently represents a functional group selected from a group consisting of a carboxyl group, a nitro group, a cyano group, an alkyl group, an alkoxy group, an alkylthio group, an aryl group, an aryloxy group, an arylthio group, an alkenyl group, an alkynyl group, an amino group, a silyl group, an acyl group, an acyloxy group, an imine residue, an amide compound residue, an acid imide residue, a monovalent heterocyclic group, and a monovalent heterocyclic thio group, or a halogen atom, when there is plural R′'s, they may be the same as or different from each other, and plural R′'s may be bonded to each other to form a ring structure, and the hydrogen atom included in the functional group may be further substituted by a substituent: 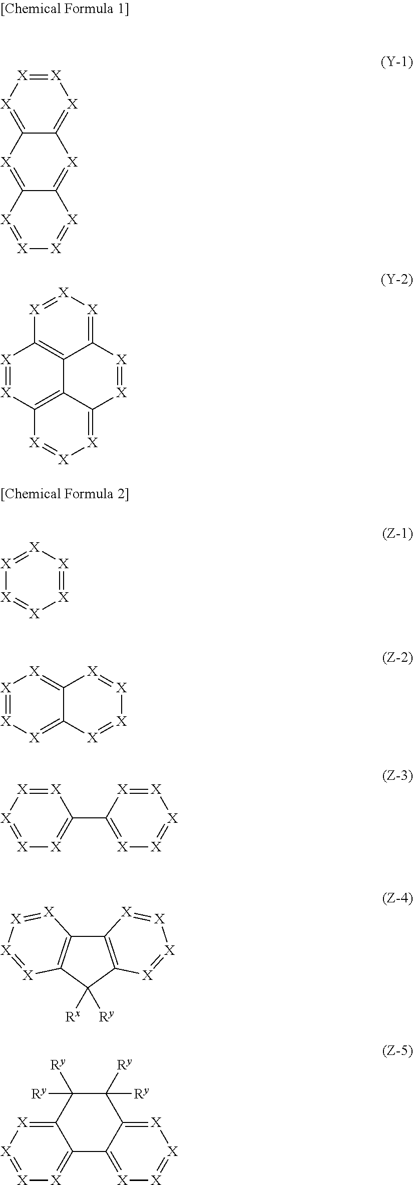 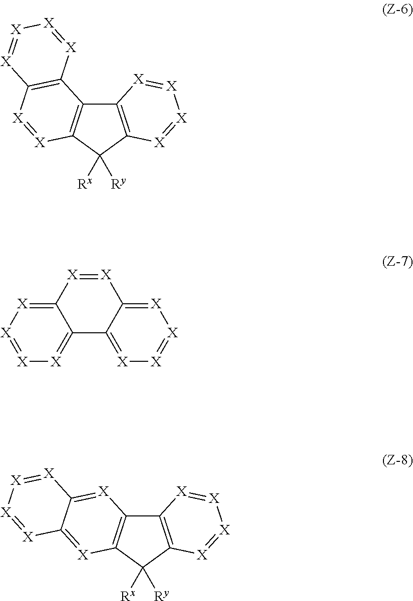
in the formulas,
X represents —CH═ or —N═, and plural X's may be the same or different from each other, with the proviso that the number of —N═ as X is 0 to 2,
R^{x} is an aryl group, and R^{y} represents a functional group selected from a group consisting of an alkyl group, a carboxyl group, a nitro group, a cyano group, an aryl group, an aryloxy group, an arylthio group, an alkenyl group, an alkynyl group, an amino group, a silyl group, an acyl group, an acyloxy group, an imine residue, an amide compound residue, an acid imide residue, a monovalent heterocyclic group, and a monovalent heterocyclic thio group, or a hydrogen atom or a halogen atom, plural R^{y}'s may be the same as or different from each other, and may be bonded to each other to form a ring structure, and the hydrogen atom included in the functional group may be further substituted by a substituent.

2. The polymer compound according to claim 1, wherein the Y is a divalent group represented by the following formula (Y-3), (Y-4), (Y-5), or (Y-6): 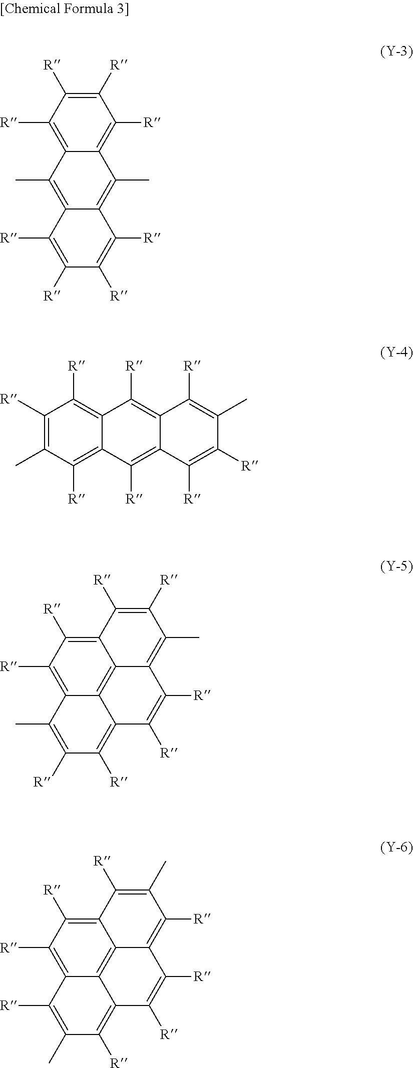
in the formula,
R″ represents a hydrogen atom, an alkyl group, an aryl group, or a monovalent heterocyclic group, and plural R″'s may be the same as or different from each other.

3. The polymer compound according to claim 1, wherein the Z is a divalent group represented by the following formula (Z-9), (Z-10), (Z-11), (Z-12), (Z-13), (Z-14), (Z-15), (Z-16), (Z-17), (Z-18), (Z-19), or (Z-20): 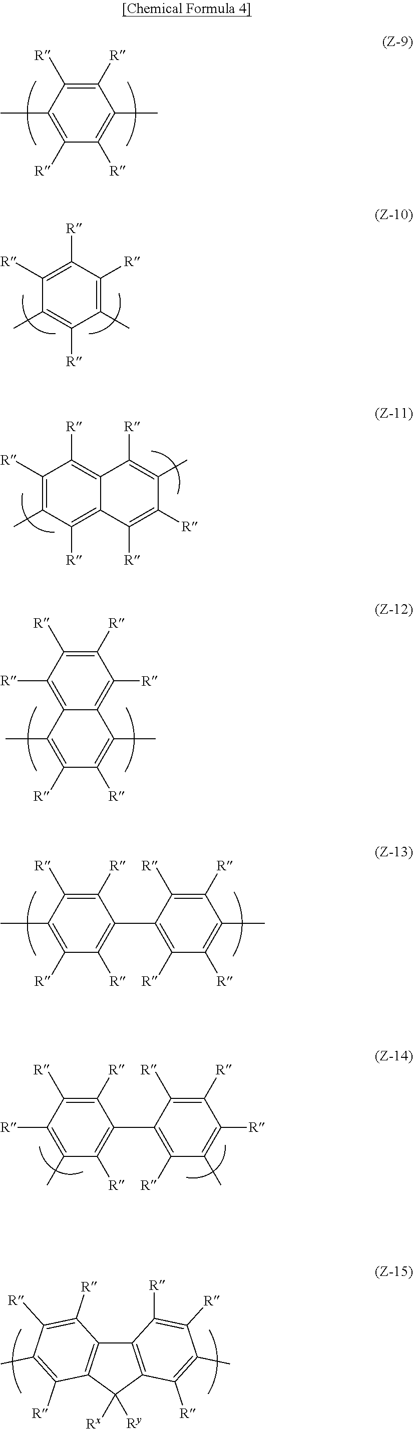 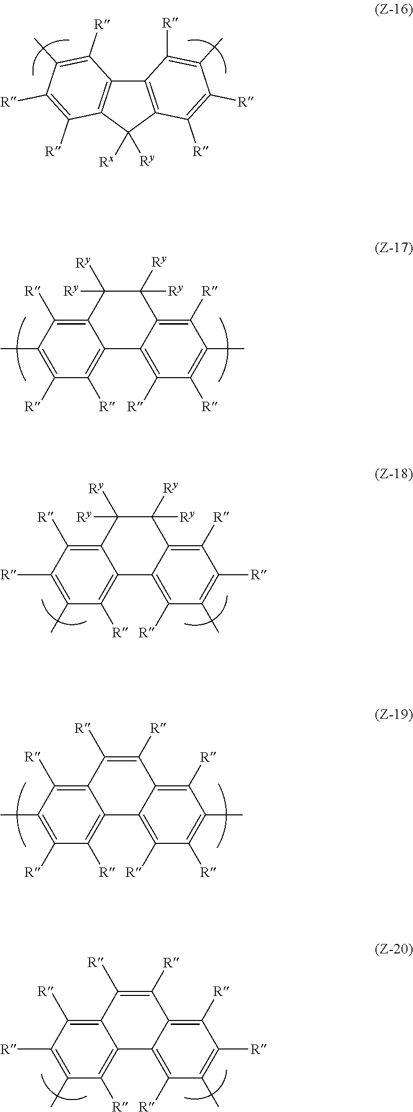
in the formula,
R″ represents a hydrogen atom, an alkyl group, an aryl group, or a monovalent heterocyclic group, plural R's may be the same as or different from each other, and R^{x} and R^{y} has the same meaning as defined above.

4. The polymer compound according to claim 3, wherein the Z is a divalent group represented by the formula (Z-11), (Z-15), or (Z-17).

5. The polymer compound according to claim 1,
wherein, in the polymer compound, the group represented by the Y and the group represented by the Z are introduced by condensation polymerization and an arbitrary additional group which is different from the group represented by Y and the group represented by Z may be introduced by condensation polymerization, and
when mole numbers of Y, Z, and the arbitrary additional group in the polymer compound are N_{Y}, N_{Z} and N_{M}, respectively, N_{Y}, N_{Z} and N_{M} satisfy the following equation (2):
30≦N_{Y}×100/(N_{Y}+N_{Z}+N_{M})≦75 (2)

6. An organic electroluminescence device comprising: a pair of electrodes; and an organic layer provided between a pair of the electrodes, the organic layer comprising the polymer compound according to claim 1.

7. A surface light source device having the organic electroluminescence device according to claim 6.

8. A display device having the organic electroluminescence device according to claim 6.
